(19) United States
(12) Patent Application Publication
(10) Pub. No.: US 2025/0022902 A1
(43) Pub. Date: Jan. 16, 2025

(54) SEMICONDUCTOR DEVICE, MANUFACTURING METHOD THEREFOR, AND ELECTRONIC APPARATUS

(71) Applicant: SONY SEMICONDUCTOR SOLUTIONS CORPORATION, KANAGAWA (JP)

(72) Inventors: KATSUNORI TOZAWA, KANAGAWA (JP); TOSHIAKI SHIRAIWA, KANAGAWA (JP); MASANAGA FUKASAWA, KANAGAWA (JP); SEIYA TANIKAWA, KANAGAWA (JP); TOMOHIRO SUGIYAMA, KANAGAWA (JP); AKIRA MAEHARA, KANAGAWA (JP)

(21) Appl. No.: 18/716,189

(22) PCT Filed: Dec. 1, 2022
(86) PCT No.: PCT/JP2022/044325

§ 371 Date: Jun. 4, 2024

(30) Foreign Application Priority Data
Dec. 13, 2021 (JP) 2021-201894

(51) Int. Cl. H01L 27/146; H01L 21/768

(52) U.S. Cl. CPC H01L 27/14636; H01L 21/76877; H01L 27/14683

(57) ABSTRACT

The present disclosure relates to a semiconductor device, a manufacturing method therefor, and an electronic apparatus by which film stress generated due to heat treatment can be reduced. The semiconductor device includes a through-via on which a connection electrical conductor is formed via an insulation film, the through-via being provided on a side wall of a through-hole formed in a semiconductor substrate, in which the connection electrical conductor includes a thin film portion with a smaller film thickness and a thick film portion with a larger film thickness. The present disclosure can be applied to, for example, a solid-state image pickup apparatus and the like.

### TECHNICAL FIELD

The present disclosure relates to a semiconductor device, a manufacturing method therefor, and an electronic apparatus, and more specifically relates to a semiconductor device, a manufacturing method therefor, and an electronic apparatus by which film stress generated due to heat treatment can be reduced.

### BACKGROUND ART

Conventionally, various technologies have been proposed to cope with various problems associated with through-silicon-via (TSV) that is a via-hole penetrating a silicon substrate.

For example, in a case where a plating wiring is formed by forming a via-hole in a silicon substrate, heat treatment steps after the plating wiring is formed may result in film peeling or deformation of the insulation film in the periphery of the via-hole, which may influence the reliability and the yield. To cope with such film peeling and deformation due to heat treatment, for example, Patent Literature 1 has proposed a technology in which a stepped portion is provided in the periphery of the via-hole for blocking a horizontal film stress change which occurs due to heat treatment with the stepped portion.

Moreover, for example, Patent Literature 2 has proposed a technology in which in a case where stacked semiconductor devices (semiconductor chips) are connected to each other through a through-silicon-via (TSV), the breakdown voltage of TSV insulation films is improved.

### CITATION LIST

### Patent Literature

Patent Literature 1: Japanese Patent Application Laid-open No. 2006-73787
Patent Literature 2: Japanese Patent Application Laid-open No. 2015-61041

### DISCLOSURE OF INVENTION

### Technical Problem

As to the through-silicon-via, film peeling, cracking, deformation, or the like may occur due to film stress generated due to heat treatment as described above, and it is thus desirable to provide further measures.

The present disclosure has been made in the above-mentioned circumstances to be capable of reducing film stress generated due to heat treatment.

### Solution to Problem

A semiconductor device according to a first aspect of the present disclosure includes a through-via on which a connection electrical conductor is formed via an insulation film, the through-via being provided on a side wall of a through-hole formed in a semiconductor substrate, in which the connection electrical conductor includes a thin film portion with a smaller film thickness and a thick film portion with a larger film thickness.

A manufacturing method for a semiconductor device according to a second aspect of the present disclosure includes forming a connection electrical conductor via an insulation film on a side wall of a through-hole formed in a semiconductor substrate to form a through-via, in which the connection electrical conductor is formed including a thin film portion with a smaller film thickness and a thick film portion with a larger film thickness.

An electronic apparatus according to a third aspect of the present disclosure includes a semiconductor device including a through-via on which a connection electrical conductor is formed via an insulation film on a side wall of a through-hole formed in a semiconductor substrate, in which the connection electrical conductor includes a thin film portion with a smaller film thickness and a thick film portion with a larger film thickness.

In the first to third aspects of the present disclosure, the through-via is formed by forming the connection electrical conductor via the insulation film on the side wall of the through-hole formed on the semiconductor substrate, and the connection electrical conductor is formed including the thin film portion with the smaller film thickness and the thick film portion with the larger film thickness.

The semiconductor device and the electronic apparatus may be independent apparatuses or may be modules incorporated in other apparatuses.

### BRIEF DESCRIPTION OF DRAWINGS

FIG. 1 An outer appearance schematic view of a solid-state image pickup apparatus as a semiconductor device according to the present disclosure.

FIG. 2 Diagrams each describing a substrate configuration of the solid-state image pickup apparatus.

FIG. 3 A diagram showing a circuit configuration example of a stack substrate.

FIG. 4 A diagram showing an equivalent circuit of a pixel.

FIG. 5 A view showing a detailed structure of the stack substrate.

FIG. 6 A view showing another example of a detailed structure of the stack substrate.

FIG. 7 Views showing a first structure example of a through-silicon-via.

FIG. 8 A view describing a simulation result obtained by measuring film thickness and thermal stress of a connection electrical conductor.

FIG. 9 Views describing a manufacturing method for a through-silicon-via according to the first structure example.

FIG. 10 Views describing the manufacturing method for the through-silicon-via according to the first structure example.

FIG. 11 Views describing the manufacturing method for the through-silicon-via according to the first structure example.

FIG. 12 Views showing first to tenth modified examples of the first structure example.

FIG. 13 Views showing the first to tenth modified examples of the first structure example.

FIG. 14 Views showing eleventh and twelfth modified examples of the first structure example.

FIG. 15 Views describing a manufacturing method according to the eleventh and twelfth modified examples.

FIG. 16 Views showing thirteenth and fourteenth modified examples of the first structure example.

FIG. 17 Views describing the manufacturing method according to the thirteenth modified example of the first structure example.

FIG. 18 Views describing the manufacturing method according to the thirteenth modified example of the first structure example.

FIG. 19 Views showing a fifteenth modified example of the first structure example.

FIG. 20 Views describing the manufacturing method according to the fifteenth modified example of the first structure example.

FIG. 21 Views showing a second structure example of the through-silicon-via.

FIG. 22 Views describing a manufacturing method for a through-silicon-via according to the second structure example.

FIG. 23 Views describing another manufacturing method for the through-silicon-via according to the second structure example.

FIG. 24 A cross-sectional view showing a modified example of the second structure example.

FIG. 25 Views describing a manufacturing method according to the modified example of the second structure example.

FIG. 26 A view showing a third structure example of the through-silicon-via.

FIG. 27 Plan views of the through-silicon-via according to the third structure example.

FIG. 28 A view describing effects of the through-silicon-via according to the third structure example.

FIG. 29 Views describing a manufacturing method for the through-silicon-via according to the third structure example.

FIG. 30 Views describing the manufacturing method for the through-silicon-via according to the third structure example.

FIG. 31 Cross-sectional views showing modified examples of the third structure example.

FIG. 32 Views describing another manufacturing method for the through-silicon-via according to the third structure example.

FIG. 33 Cross-sectional views showing the modified examples of the third structure example.

FIG. 34 Plan views of the through-silicon-via according to the modified examples of the third structure example.

FIG. 35 Views describing the number of stacks of a buffer layer in the third structure example.

FIG. 36 Views showing a fourth structure example of the through-silicon-via.

FIG. 37 A view describing effects of the through-silicon-via according to the fourth structure example.

FIG. 38 Views describing the effects of the through-silicon-via according to the fourth structure example.

FIG. 39 Views describing a manufacturing method for the through-silicon-via according to the fourth structure example.

FIG. 40 Views describing the manufacturing method for the through-silicon-via according to the fourth structure example.

FIG. 41 Views describing the manufacturing method for the through-silicon-via according to the fourth structure example.

FIG. 42 A cross-sectional view showing a modified example of the fourth structure example.

FIG. 43 A cross-sectional view showing the modified example of the fourth structure example.

FIG. 44 A view describing another problem in a case of forming the through-silicon-via.

FIG. 45 Views showing a fifth structure example of the through-silicon-via.

FIG. 46 A plan view of an entire chip of a wiring layer-forming surface in FIG. 45.

FIG. 47 Views describing a manufacturing method for the through-silicon-via according to the fifth structure example.

FIG. 48 Views describing the manufacturing method for the through-silicon-via according to the fifth structure example.

FIG. 49 Views describing the manufacturing method for the through-silicon-via according to the fifth structure example.

FIG. 50 Views describing the manufacturing method for the through-silicon-via according to the fifth structure example.

FIG. 51 A cross-sectional view showing a sixth structure example of the through-silicon-via.

FIG. 52 A plan view of a part of the through-silicon-via according to the sixth structure example and a wiring layer.

FIG. 53 A plan view of the part of the through-silicon-via according to the sixth structure example and the wiring layer.

FIG. 54 Views describing a manufacturing method for the through-silicon-via according to the sixth structure example.

FIG. 55 Views describing the manufacturing method for the through-silicon-via according to the sixth structure example.

FIG. 56 Views describing the manufacturing method for the through-silicon-via according to the sixth structure example.

FIG. 57 Views showing a first modified example of the sixth structure example.

FIG. 58 Views showing a second modified example of the sixth structure example.

FIG. 59 Views showing a third modified example of the sixth structure example.

FIG. 60 A cross-sectional view showing a seventh structure example of the through-silicon-via.

FIG. 61 A plan view showing arrangement of a first through-silicon-via and a plurality of second through-silicon-vias.

FIG. 62 A cross-sectional view showing the seventh structure example of the through-silicon-via.

FIG. 63 A view describing effects of the through-silicon-via structure according to the seventh structure example.

FIG. 64 A view describing the effects of the through-silicon-via structure according to the seventh structure example.

FIG. 65 Views describing a manufacturing method for the through-silicon-via according to the seventh structure example.

FIG. 66 Views describing the manufacturing method for the through-silicon-via according to the seventh structure example.

FIG. 67 Views describing the manufacturing method for the through-silicon-via according to the seventh structure example.

FIG. 68 Views showing modified examples of the seventh structure example.

FIG. 69 A block diagram showing a configuration example of an image pickup apparatus as an electronic apparatus to which the technology of the present disclosure is applied.

FIG. 70 A diagram describing a use example of an image sensor.

### MODE(S) FOR CARRYING OUT THE INVENTION

Hereinafter, mode(s) for carrying out the technology of the present disclosure (hereinafter, embodiments) will be described with reference to the accompanying drawings. The descriptions will be given in the following order.
1. Schematic Configuration of Solid-State Image Pickup Apparatus
2. Problem of Film Stress due to Heat Treatment of Through-Silicon Via
3. First Structure Example of Through-Silicon Via
4. Manufacturing Method for First Structure Example of Through-Silicon Via
5. Modified Example According to First Structure Example of Through-Silicon Via
6. Summary of First Structure Example of Through-Silicon Via
7. Second Structure Example of Through-Silicon Via
8. Summary of Second Structure Example of Through-Silicon Via
9. Third Structure Example of Through-Silicon Via
10. Summary of Third Structure Example of Through-Silicon Via
11. Fourth Structure Example of Through-Silicon Via
12. Summary of Fourth Structure Example of Through-Silicon Via
13. Problem during High-Voltage Application on Through-Silicon Via
14. Fifth Structure Example of Through-Silicon Via
15. Summary of Fifth Structure Example of Through-Silicon Via
16. Sixth Structure Example of Through-Silicon Via
17. Summary of Sixth Structure Example of Through-Silicon Via
18. Seventh Structure Example of Through-Silicon Via
19. Summary of Seventh Structure Example of Through-Silicon Via
20. Application Example to Electronic Apparatus

It should be noted that in the figures which will be referred to in the following descriptions, duplicate descriptions will be omitted as appropriate by denoting the same or similar portions by the same or similar reference signs. The figures are schematic, and a relationship between a thickness and a plane dimension, a thickness ratio of layers, and the like are different from actual ones. Moreover, the relationship and ratio of dimensions may be partially different between the figures.

Moreover, definitions of directions such as upper and lower directions in the following descriptions are merely definitions for convenience, and they do not limit technical ideas of the present disclosure. For example, the upper and lower directions should be read as left and right directions when an object rotated by 90 degrees is observed and the upper and lower directions should be read as the lower and upper directions when an object rotated by 180 degrees is observed.

### <1. Schematic Configuration of Solid-State Image

### Pickup Apparatus>

### <Outer Appearance Schematic View>

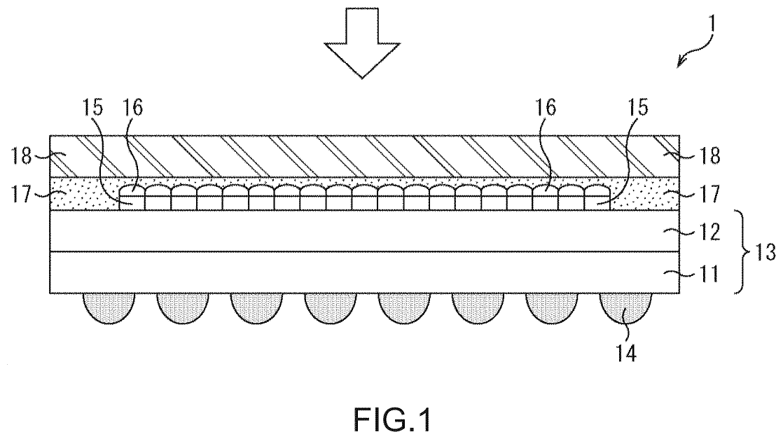

FIG. 1 shows an outer appearance schematic view of a solid-state image pickup apparatus as a semiconductor device according to the present disclosure.

A solid-state image pickup apparatus 1 shown in FIG. 1 is a semiconductor package in which a stack substrate 13 constituted by a lower substrate 11 and an upper substrate 12 stacked on each other is packaged. The solid-state image pickup apparatus 1 converts light entering from a direction shown as the arrow in the figure into electrical signals and outputs the electrical signals.

A plurality of solder balls 14 which is back surface electrodes for electrically connecting to an external substrate (not shown) is formed on the lower substrate 11.

Color filters 15 and ON chip lenses 16 for R (red), G (green), and B (blue) are formed on the upper surface of the upper substrate 12. Moreover, the upper substrate 12 is connected to a glass protection substrate 18 for protecting the ON chip lenses 16 via a glass seal resin 17 as a cavityless structure.

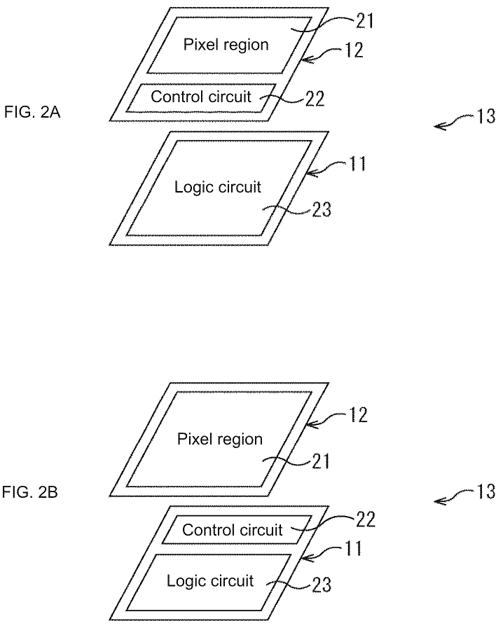

For example, a pixel region 21 in which pixel portions that perform photoelectric conversion are two-dimensionally arranged and a control circuit 22 that controls the pixel portions are formed on the upper substrate 12 as shown in A of FIG. 2. A logic circuit 23 such as a signal processing circuit that processes pixel signals output from the pixel portions is formed on the lower substrate 11.

Alternatively, it is also possible to employ a configuration in which only the pixel region 21 is formed on the upper substrate 12 and the control circuit 22 and the logic circuit 23 are formed on the lower substrate 11 as shown in B of FIG. 2.

By forming and stacking the logic circuit 23 or both the control circuit 22 and the logic circuit 23 on the lower substrate 11 different from the upper substrate 12 for the pixel region 21 as described above, the size as the solid-state image pickup apparatus 1 can be reduced as compared to a case where the pixel region 21, the control circuit 22, and the logic circuit 23 are arranged in a plane direction on a single semiconductor substrate.

Hereinafter, the description will be given while the upper substrate 12 on which at least the pixel region 21 is formed will be referred to as a pixel sensor substrate 12 and the lower substrate 11 on which at least the logic circuit 23 is formed will be referred to as a logic substrate 11.

### <Configuration Example of Stack Substrate>

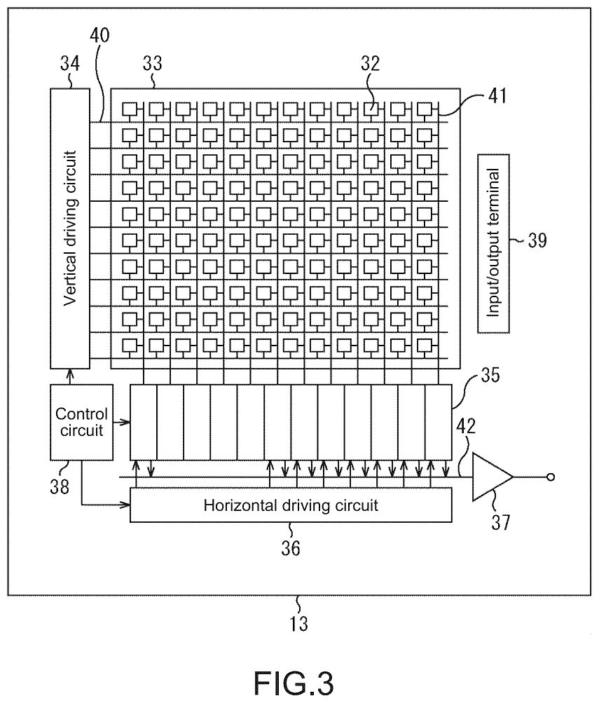

FIG. 3 shows a circuit configuration example of the stack substrate 13.

The stack substrate 13 includes a pixel array unit 33 in which pixels 32 are arranged in a two-dimensional array, a vertical driving circuit 34, column signal processing circuits 35, a horizontal driving circuit 36, an output circuit 37, a control circuit 38, an input/output terminal 39, and the like.

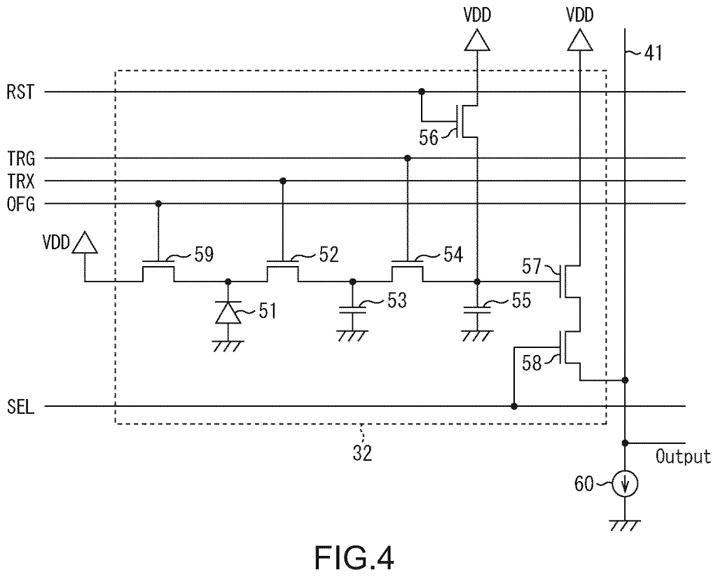

The pixel 32 is constituted by a photodiode as a photoelectric conversion element and a plurality of pixel transistors. A circuit configuration example of the pixel 32 will be described later with reference to FIG. 4.

Moreover, the pixel 32 can also have a shared-pixel structure. This pixel sharing structure is constituted by a plurality of photodiodes, a plurality of transfer transistors, a single floating diffusion (floating diffusion region) to be shared, and one of the other pixel transistors to be shared. That is, in the shared pixel, photodiodes and transfer transistors constituting a plurality of unit pixels share one of the other pixel transistors and are configured.

The control circuit 38 receives an input clock and data to command an operation mode or the like and outputs data about internal information or the like of the stack substrate 13. That is, on the basis of a vertical synchronization signal, a horizontal synchronization signal, and a master clock, the control circuit 38 generates clock signals and control signals as references for operations of the vertical driving circuit 34, the column signal processing circuits 35, the horizontal driving circuit 36, and the like. Then, the control circuit 38 outputs the generated clock signals and control signals to the vertical driving circuit 34, the column signal processing circuits 35, the horizontal driving circuit 36, and the like.

The vertical driving circuit 34 is, for example, constituted by a shift register and selects a predetermined pixel driving wiring 40, supplies the selected pixel driving wiring 40 with pulses for driving the pixels 32, and drives the pixels 32 on a row-by-row basis. That is, the vertical driving circuit 34 selectively scans the respective pixels 32 of the pixel array unit 33 on a row-by-row basis sequentially in a vertical direction and supplies a pixel signal based on a signal electric charge generated in accordance with an amount of light received through a photoelectric conversion unit of each pixel 32 to the column signal processing circuits 35 through the vertical signal line 41.

The column signal processing circuits 35 are arranged for each column of the pixels 32. The column signal processing circuits 35 perform, for each pixel column, signal processing such as noise-cancelling on signals output from the pixels 32 for one row. For example, the column signal processing circuits 35 perform signal processing such as correlated double sampling (CDS) or AD conversion for cancelling pixel-specific fixed-pattern noise.

The horizontal driving circuit 36 is, for example, constituted by a shift register and sequentially outputs horizontal scan pulses, thereby selecting each of the column signal processing circuits 35 in order and outputs pixel signals to a horizontal signal line 42 from each of the column signal processing circuits 35.

The output circuit 37 performs signal processing on signals sequentially supplied from each of the column signal processing circuits 35 through the horizontal signal line 42 and outputs the processed signals. The output circuit 37 may perform, for example, only buffering or may perform black level adjustment, column variation correction, various types of digital signal processing, and the like. The input/output terminal 39 exchanges signals with an external device.

The stack substrate 13 configured in the above-mentioned manner is a CMOS image sensor called column AD method in which the column signal processing circuits 35 that perform CDS processing and AD conversion processing are arranged for each pixel column.

### <Circuit Configuration Example of Pixel>

FIG. 4 shows an equivalent circuit of the pixel 32.

The pixel 32 shown in FIG. 4 represents a configuration to realize an electronic global shutter function.

The pixel 32 includes a photodiode 51 as a photoelectric conversion element, a first transfer transistor 52, a memory unit (MEM) 53, a second transfer transistor 54, a floating diffusion region (FD) 55, a reset transistor 56, an amplification transistor 57, a selection transistor 58, and a discharge transistor 59.

The photodiode 51 is a photoelectric conversion unit that generates and accumulates electric charges (signal electric charges) according to an amount of light received. An anode terminal of the photodiode 51 is grounded and a cathode terminal is connected to the memory unit 53 via the first transfer transistor 52. Moreover, the cathode terminal of the photodiode 51 is also connected to the discharge transistor 59 for discharging unnecessary electric charges.

When the first transfer transistor 52 is turned on in accordance with a transfer signal TRX, the first transfer transistor 52 reads out electric charges generated at the photodiode 51 and transfers the read-out electric charges to the memory unit 53. The memory unit 53 is an electric charge retaining unit that temporarily retains electric charges before transferring electric charges to the FD 55.

When the second transfer transistor 54 is turned on in accordance with a transfer signal TRG, the second transfer transistor 54 reads out electric charges retained in the memory unit 53 and transfers the read-out electric charges to the FD 55.

The FD 55 is an electric charge retaining unit that retains electric charges read out from the memory unit 53 for reading out the electric charges as signals. When the reset transistor 56 is turned on in accordance with a reset signal RST, the reset transistor 56 resets the potential of the FD 55 in such a manner that the electric charges accumulated in the FD 55 are discharged to a constant voltage source VDD.

The amplification transistor 57 outputs pixel signals according to the potential of the FD 55. That is, the amplification transistor 57 constitutes a load MOS 60 and a source follower circuit as a constant current source and a pixel signal indicating a level according to the electric charges accumulated in the FD 55 is output to the column signal processing circuits 35 (FIG. 3) via the selection transistor 58 from the amplification transistor 57. The load MOS 60 is, for example, arranged in the column signal processing circuit 35.

When one pixel 32 is selected in accordance with a selection signal SEL, the selection transistor 58 is turned on and outputs a pixel signal of the pixel 32 to the column signal processing circuit 35 via the vertical signal line 41.

When the discharge transistor 59 is turned on in accordance with a discharge signal OFG, the discharge transistor 59 discharges unnecessary electric charges accumulated in the photodiode 51 to the constant voltage source VDD.

The transfer signals TRX and TRG, the reset signal RST, the discharge signal OFG, and the selection signal SEL are supplied from the vertical driving circuit 34 via the pixel driving wiring 40.

An operation of the pixel 32 will be briefly described.

First of all, the discharge transistor 59 is turned on by supplying a high-level discharge signal OFG to the discharge transistor 59 before light exposure starts, electric charges accumulated in the photodiode 51 are discharged to the constant voltage source VDD, and the photodiodes 51 of all pixels are reset.

When the discharge transistor 59 is turned off in accordance with a low-level discharge signal OFG after the photodiodes 51 are reset, light exposure is started at all pixels of the pixel array unit 33.

When a predetermined exposure time determined in advance has elapsed, the first transfer transistors 52 are turned on in accordance with transfer signals TRX at all pixels of the pixel array unit 33, and electric charges accumulated in the photodiodes 51 are transferred to the memory units 53.

After the first transfer transistor 52 is turned off, the electric charges retained in the memory units 53 of the respective pixels 32 are sequentially read out to the column signal processing circuits 35 on a row-by-row basis. In the reading operation, the second transfer transistors 54 of the pixels 32 in the read-out row are turned on in accordance with transfer signals TRG and electric charges retained in the memory units 53 are transferred to the FDs 55. Then, by the selection transistors 58 being turned on in accordance with selection signals SEL, signals indicating levels according to the electric charges accumulated in the FDs 55 are output to the column signal processing circuits 35 from the amplification transistors 57 via the selection transistors 58.

As described above, the pixels 32 each having the pixel circuit in FIG. 4 can perform an operation (image-pick up) according to a global shutter method of setting the exposure time to be the same in all pixels of the pixel array unit 33, temporarily retaining electric charges in the memory units 53 after light exposure ends, and sequentially reading out the electric charges from the memory units 53 on a row-by-row basis.

It should be noted that the circuit configuration of the pixel 32 is not limited to the configuration shown in FIG. 4, and for example, a circuit configuration to perform an operation according to a so-called rolling shutter method may be employed with no memory units 53.

### <Detailed Structure of Stack Substrate>

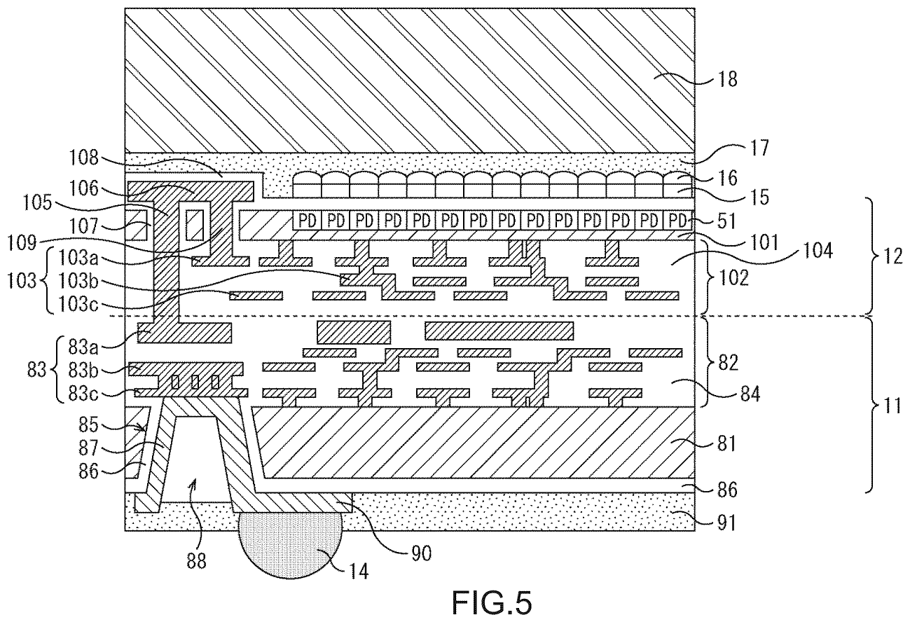

Next, a detailed structure of the stack substrate 13 will be described with reference to FIG. 5. FIG. 5 is a cross-sectional view showing a portion of the solid-state image pickup apparatus 1 in an enlarged state.

On the logic substrate 11, a multi-layer wiring layer 82 is formed on the upper side (pixel sensor substrate 12 side) of a semiconductor substrate 81 (hereinafter, referred to as a silicon substrate 81) constituted by silicon (Si), for example. This multi-layer wiring layer 82 configures the control circuit 22 and the logic circuit 23 in FIG. 2.

The multi-layer wiring layer 82 is constituted by a plurality of wiring layers 83 and interlayer insulation films 84. The plurality of wiring layers 83 is, for example, constituted by an uppermost wiring layer 83a closest to the pixel sensor substrate 12, an intermediate wiring layer 83b, and a lowermost wiring layer 83c closest to the silicon substrate 81. The interlayer insulation film 84 is formed between the respective wiring layers 83.

The plurality of wiring layers 83 is, for example, formed of copper (Cu), aluminum (Al), tungsten (W), or the like. The interlayer insulation film 84 is, for example, formed of an SiO₂ films, an SiN film, an SiON film, or the like. As to each of the plurality of wiring layers 83 and the interlayer insulation films 84, all layers may be formed of the same material or two or more materials may be used depending on the layers.

A silicon through-hole 85 penetrating the silicon substrate 81 is formed at a predetermined position in the silicon substrate 81. By embedding a connection electrical conductor 87 in an inner wall of the silicon through-hole 85 via an insulation film 86, a through-silicon-via (TSV) 88 is formed. The insulation film 86 can be, for example, formed of an SiO₂ film, a SiN film, an SiON film, or the like.

It should be noted that in the through-silicon-via 88 shown in FIG. 5, the insulation film 86 and the connection electrical conductor 87 are deposited along the inner wall surface and the silicon through-hole 85 has a cavity inside. However, depending on an inner diameter, the silicon through-hole 85 may be entirely embedded with the connection electrical conductor 87. In other words, the through-hole may be embedded with the conductor or may be partially hollow. The same applies to a through-chip-via (TCV) 105 and the like to be described later.

The connection electrical conductor 87 of the through-silicon-via 88 is connected to a rewiring 90 formed on a lower surface side of the silicon substrate 81 and the rewiring 90 is connected to the solder ball 14. The connection electrical conductor 87 and the rewiring 90 can be, for example, formed of copper (Cu), tungsten (W), titanium (Ti), tantalum (Ta), titanium tungsten alloy (TiW), nickel (Ni), gold (Au), polysilicon, and the like.

Moreover, on the lower surface side of the silicon substrate 81, a solder mask (solder resist) 91 is formed to cover the rewiring 90 and the insulation film 86, excluding a region where the solder ball 14 has been formed.

On the other hand, on the pixel sensor substrate 12, a multi-layer wiring layer 102 is formed on a lower side (logic substrate 11 side) of a semiconductor substrate 101 (hereinafter, referred to as a silicon substrate 101) constituted by silicon (Si). This multi-layer wiring layer 102 configures the pixel circuit of the pixel region 21 in FIG. 2.

The multi-layer wiring layer 102 is constituted by a plurality of wiring layers 103 and interlayer insulation films 104. The plurality of wiring layers 103 is, for example, constituted by an uppermost wiring layer 103a closest to the silicon substrate 101, an intermediate wiring layer 103b, and a lowermost wiring layer 103c closest to the logic substrate 11. The interlayer insulation films 104 are formed between the respective wiring layers 103.

The same kind of material as the wiring layers 83 and the interlayer insulation films 84 can be employed as a material used for the plurality of wiring layers 103 and the interlayer insulation films 104. Moreover, as in the wiring layers 83 and the interlayer insulation films 84, the plurality of wiring layers 103 and the interlayer insulation films 104 may be formed of one or two or more materials.

It should be noted that in the example in FIG. 5, the multi-layer wiring layer 102 of the pixel sensor substrate 12 is constituted by three wiring layers 103 and the multi-layer wiring layer 82 of the logic substrate 11 is constituted by four wiring layers 83. However, the total number of wiring layers is not limited thereto, and any number of layers can be formed as the wiring layers.

On the silicon substrate 101, photodiodes 51 formed by PN junction are respectively formed for the pixels 32.

Moreover, although not shown in the figure, a plurality of pixel transistors such as first transfer transistors 52 and second transfer transistors 54, memory units (MEMs) 53, and the like are also formed on the multi-layer wiring layer 102 and the silicon substrate 101.

At predetermined positions on the silicon substrate 101 where the color filters 15 and the ON chip lenses 16 are not formed, a through-silicon-via 109 connected to the wiring layer 103a of the pixel sensor substrate 12 and the through-chip-via 105 connected to the wiring layer 83a of the logic substrate 11 are formed.

The through-chip-via 105 and the through-silicon-via 109 are connected to a connection wiring 106 formed on the upper surface of the silicon substrate 101. Moreover, an insulation film 107 is formed between each of the through-silicon-via 109 and the through-chip-via 105 and the silicon substrate 101. In addition, the color filters 15 and the ON chip lenses 16 are formed on the upper surface of the silicon substrate 101 via an insulation film (planarization film) 108.

As described above, the stack substrate 13 of the solid-state image pickup apparatus 1 has a stack structure in which the side of the multi-layer wiring layer 82 of the logic substrate 11 is bonded to the side of the multi-layer wiring layer 102 of the pixel sensor substrate 12. In FIG. 5, a plane on which the multi-layer wiring layer 82 of the logic substrate 11 is bonded to the multi-layer wiring layer 102 of the pixel sensor substrate 12 is denoted by the broken line.

Moreover, on the stack substrate 13 of the solid-state image pickup apparatus 1, the wiring layers 103 of the pixel sensor substrate 12 and the wiring layers 83 of the logic substrate 11 are connected to each other through two through-vias, i.e., the through-silicon-via 109 and the through-chip-via 105. Then, the wiring layers 83 of the logic substrate 11 and the solder ball (back surface electrode) 14 are connected to each other through the through-silicon-via 88 and the rewiring 90. Accordingly, the plane area of the solid-state image pickup apparatus 1 can be minimized.

In addition, the height direction can also be reduced by bonding the stack substrate 13 and the glass protection substrate 18 to each other through the glass seal resin 17 as a cavityless structure.

Therefore, in accordance with the solid-state image pickup apparatus 1 shown in FIG. 1, the semiconductor device (semiconductor package) further downsized can be realized.

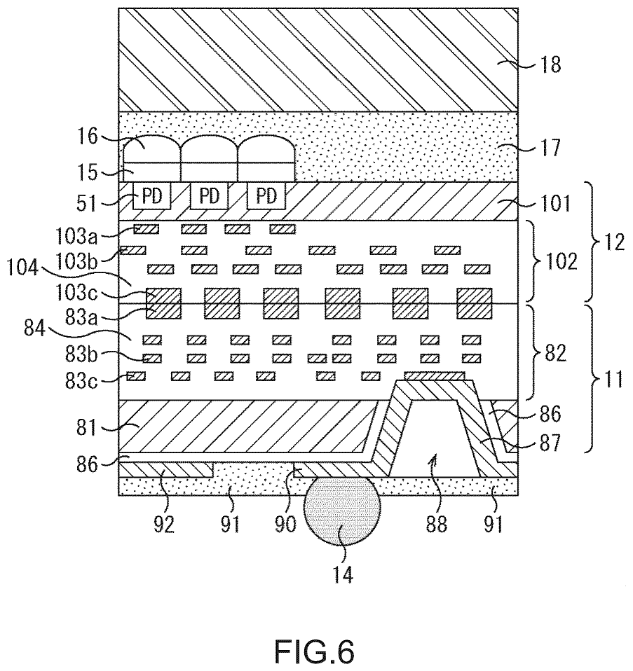

It should be noted that for the electrical connection of the logic substrate 11 and the pixel sensor substrate 12, metal junction of metal wirings, i.e., the wiring layers 83 and the wiring layers 103, as shown in FIG. 6 can also be used instead of the through-vias.

That is, in the detailed structure of the stack substrate 13 shown in FIG. 5, the logic substrate 11 and the pixel sensor substrate 12 are connected to each other through the two through-vias, i.e., the through-chip-via 105 and the through-silicon-via 109, while in the detailed structure of the stack substrate 13 in FIG. 6, the uppermost wiring layer 83a in the multi-layer wiring layer 82 of the logic substrate 11 and the lowermost wiring layer 103c in the multi-layer wiring layer 102 of the pixel sensor substrate 12 are connected to each other by metal junction (Cu—Cu junction).

In the detailed structure example of the stack substrate 13 in FIG. 6, a connection method for the solder ball 14 on the lower side of the solid-state image pickup apparatus 1 is similar to that in the detailed structure in FIG. 5. That is, by connecting the through-silicon-via 88 to the lowermost wiring layer 83c of the logic substrate 11, the solder ball 14 is connected to the wiring layers 83 and the wiring layers 103 in the stack substrate 13.

On the other hand, the detailed structure in FIG. 6 is different from the detailed structure shown in FIG. 5 in that a dummy wiring 92 not electrically connected to anywhere is formed of the same wiring material as the rewiring 90 on the same layer as the rewiring 90 to which the solder ball 14 is connected on the lower surface side of the silicon substrate 81.

This dummy wiring 92 is for reducing an influence of irregularities at the time of metal junction (Cu—Cu junction) of the uppermost wiring layer 83a on the side of the logic substrate 11 and the lowermost wiring layer 103c on the side of the pixel sensor substrate 12. That is, if the rewiring 90 is formed only in a partial region of the lower surface of the silicon substrate 81 when Cu—Cu junction is performed, a difference in thickness due to the presence/absence of the rewiring 90 causes irregularities. Providing the dummy wiring 92 can reduce the influence of the irregularities.

### <2. Problem of Film Stress Due to Heat Treatment of Through-Silicon Via>

By the way, the through-silicon-via 88 formed in the logic substrate 11 of the solid-state image pickup apparatus 1 is, for example, connected to the solder ball 14 as an output terminal and functions as an electrode that outputs a pixel signal generated in the apparatus to the external substrate outside the apparatus.

The through-silicon-via 88 has a structure in which the insulation film 86 is formed by, for example, plasma CVD on a side wall of the silicon through-hole 85 formed in the silicon substrate 81 and, for example, copper (Cu) is formed as the connection electrical conductor 87 by electrolytic plating on an upper surface of the insulation film 86 (inside the silicon through-hole 85).

In the through-silicon-via 88 formed in this manner, film peeling or cracking of the insulation film 86 may occur due to various heat treatment steps performed after the connection electrical conductor 87 is formed by electrolytic plating.

In view of this, a structure of the through-silicon-via in which film stress generated due to heat treatment is reduced so that film peeling or cracking of the insulation film 86 can be suppressed will be described hereinafter.

<3. First Structure Example of Through-Silicon Via>

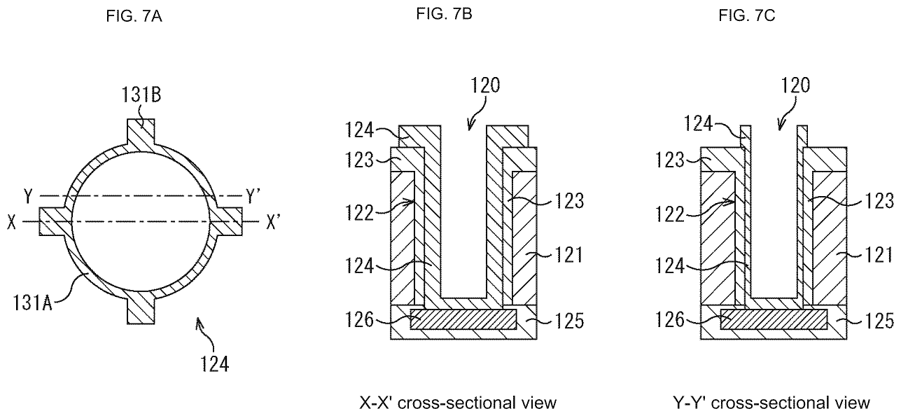

FIG. 7 is views showing a first structure example of the through-silicon-via that enables reduction of the film stress.

B and C of FIG. 7 are cross-sectional views of a through-silicon-via 120 that is the first structure example of the through-silicon-via. B of FIG. 7 is a cross-sectional view taken along the line X-X′ in A of FIG. 7. C of FIG. 7 is a cross-sectional view taken along the line Y-Y′ in A of FIG. 7.

The through-silicon-via 120 is configured by forming a connection electrical conductor 124 on a side wall (inner wall) a silicon through-hole 122 penetrating a silicon substrate 121. The connection electrical conductor 124 is also formed on an upper surface of the silicon substrate 121. An insulation film 123 is formed between the connection electrical conductor 124 and the silicon substrate 121. Therefore, in other words, the through-silicon-via 120 is constituted by the insulation film 123 formed on the upper surface of the silicon substrate 121 and a side wall of the silicon through-hole 122 and the connection electrical conductor 124 formed on its upper surface.

The connection electrical conductor 124 is connected to a wiring layer 126 formed in an interlayer insulation film 125 on a lower surface side of the silicon substrate 121 which is the lower side in B and C of FIG. 7, thereby electrically connecting the lower surface side and an upper surface side of the silicon substrate 121.

A of FIG. 7 is a plan view of the connection electrical conductor 124 at any depth position of the silicon substrate 121 in B and C of FIG. 7.

When the connection electrical conductor 124 is viewed from the upper surface, as shown in A of FIG. 7, the connection electrical conductor 124 includes thin film portions 131A in which the silicon through-hole 122 has a smaller radial thickness and thick film portions 131B in which the silicon through-hole 122 has a larger radial thickness than the thin film portions 131A. The thick film portions 131B are constituted by projection portions radially outside the silicon through-hole 122. The cross-sectional view in B of FIG. 7 is a cross-sectional view showing cross-sections of the thick film portions 131B of the connection electrical conductor 124. The cross-sectional view in C of FIG. 7 is a cross-sectional view showing cross-sections of the thin film portions 131A of the connection electrical conductor 124.

In the example in FIG. 7, the four thick film portions 131B are arranged at intervals of 90 degrees as uniform arrangement. However, the number of thick film portions 131B is not limited to four. It is sufficient that the thick film portions 131B are provided at one or more positions with respect to the thin film portions 131A.

The through-silicon-via 120 in FIG. 7 can be arranged in the solid-state image pickup apparatus 1 in place of the through-silicon-via 88 in FIG. 5 or 6 described above. The silicon substrate 121 corresponds to the silicon substrate 81 in FIG. 5 and the wiring layer 126 corresponds to the wiring layer 83c in FIG. 5. The connection electrical conductor 124 formed on an upper surface side of the silicon substrate 121 which is the upper side in FIG. 7 also serves as the rewiring 90 in FIG. 5 and, for example, the solder ball 14 (FIG. 5 or 6) is formed on the connection electrical conductor 124. The insulation film 123 can be, for example, formed of an SiON film, an SiO₂ film, an SiN film, or the like as in the insulation film 86 in FIG. 5. The connection electrical conductor 124 can be, for example, formed of copper (Cu), tungsten (W), titanium (Ti), tantalum (Ta), titanium tungsten alloy (TiW), nickel (Ni), gold (Au), polysilicon, and the like as in the connection electrical conductor 87 in FIG. 5.

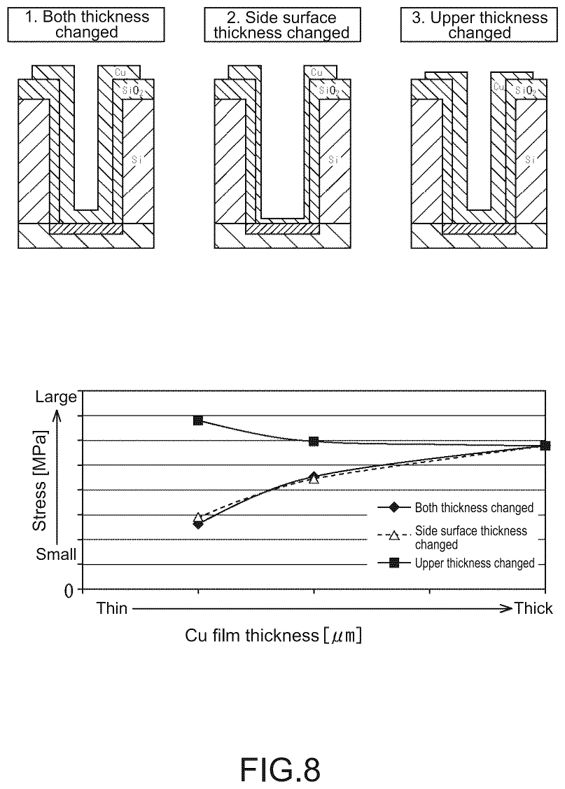

FIG. 8 shows simulation results of measuring thermal stress generated in the insulation film 123 as the side wall by changing the film thickness of the connection electrical conductor 124 of both or one of the upper surface of the silicon substrate 121 and the side wall of the silicon through-hole 122.

The graph on the lower side of FIG. 8 shows changes in thermal stress (1) in a case where the film thickness of the connection electrical conductor 124 both at the upper surface of the silicon substrate 121 and the side wall of the silicon through-hole 122 was changed, (2) in a case where the film thickness of the connection electrical conductor 124 only at the side wall of the silicon through-hole 122 was changed, and (3) in a case where the film thickness of the connection electrical conductor 124 only at the upper surface of the silicon substrate 121 was changed. It should be noted that the material of the connection electrical conductor 124 was copper (Cu) and the insulation film 123 was an SiO₂ film.

According to the graph of the simulation results, (3) in a case where the film thickness of the connection electrical conductor 124 only at the upper surface of the silicon substrate 121 was made smaller, the thermal stress increased, and (1) and (2) in a case where the film thickness at the side wall of the silicon through-hole 122 was made smaller, the thermal stress decreased. It can be seen that as to the thermal stress generated in the insulation film 123 at the side wall of the silicon through-hole 122, the film thickness at the side wall of the connection electrical conductor 124 is dominant and the film thickness at the upper surface of the silicon substrate 121 does not contribute to it.

Based on such simulation results, by forming the film thickness of the connection electrical conductor 124 at the side wall of the silicon through-hole 122 to be as small as possible, film stress generated due to heat treatment is reduced so that film peeling or cracking of the insulation film 123 can be suppressed.

However, forming the film thickness of the connection electrical conductor 124 at the side wall of the silicon through-hole 122 to be smaller entirely may result in an increase in resistance of the through-silicon-via 120, lower reliability of connection with the wiring layer 126, and the like.

In view of this, as to the through-silicon-via 120 shown in FIG. 7, parts of the connection electrical conductor 124 are set as the thin film portions 131A for reducing the film stress while the other parts are set as the thick film portions 131B for reducing the resistance and improving the connection reliability with the thick film portions 131B having the larger film thickness.

### <4. Manufacturing Method for First Structure Example of Through-Silicon Via>

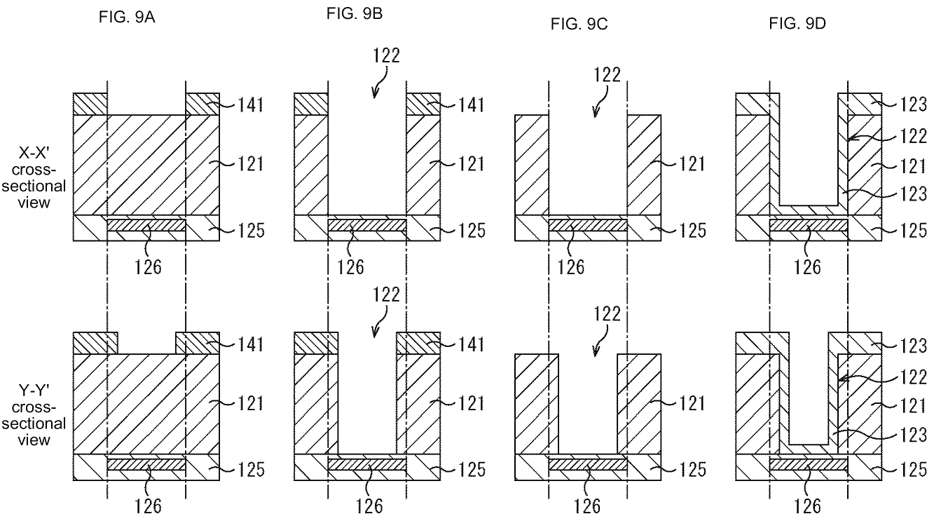

A manufacturing method for the through-silicon-via 120 according to the first structure example shown in FIG. 7 will be described with reference to FIGS. 9 to 11. Also in FIGS. 9 to 11, both the cross-section taken along the line X-X′ and the cross-section taken along the line Y-Y′ in A of FIG. 7 will be shown and described.

First of all, as shown in A of FIG. 9, the multi-layer wiring layer (multi-layer wiring layer 82 in FIG. 5) including the interlayer insulation film 125 and the wiring layer 126 is formed on the side of the pixel sensor substrate 12 (FIG. 5) of the silicon substrate 121. Then, a photoresist 141 is patterned on the silicon substrate 121 on a side opposite to a surface on the side on which the multi-layer wiring layer of the silicon substrate 121 is formed. The photoresist 141 is patterned so that the position where the through-silicon-via 120 (not shown) is arranged is opened. This opening region of the photoresist 141 is formed corresponding to the plane region of the connection electrical conductor 124 in A of FIG. 7. The thickness of the silicon substrate 121 is set to, for example, approximately 60 to 80 μm, the film thickness of the photoresist 141 is set to, for example, about 20 μm, the diameter of the opening region of the photoresist 141 is set to, for example, approximately 60 to 80 μm. On the lower surface side of the silicon substrate 121, the interlayer insulation film 125 and the wiring layer 126 are already formed.

Next, as shown in B of FIG. 9, the silicon substrate 121 corresponding to the opening region of the photoresist 141 is removed by dry etching. As a result, the silicon through-hole 122 is formed.

Next, as shown in C of FIG. 9, the photoresist 141 is removed by wet treatment or ashing treatment, and then the insulation film 123 is deposited on the entire upper surface of the silicon substrate 121 by, for example, plasma CVD as shown in D of FIG. 9. The insulation film 123 is also deposited on a bottom surface and a side wall of the silicon through-hole 122. The insulation film 123 can be, for example, an SiON film, an SiO₂ film, an SiN film, or the like. The film thickness of the insulation film 123 on the upper surface of the silicon substrate 121 is set to, for example, approximately 8 to 10 μm.

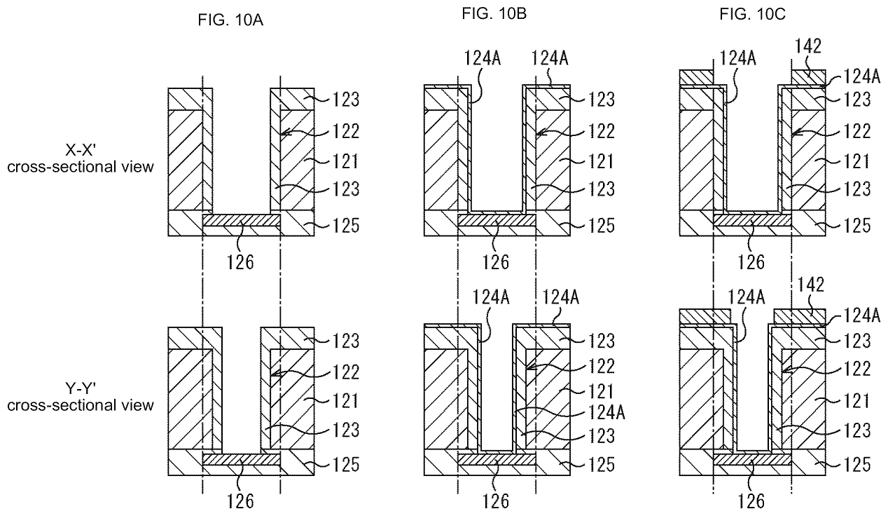

Next, as shown in A of FIG. 10, the insulation film 123 on the bottom surface of the silicon through-hole 122 is removed by etching back. As a result, the wiring layer 126 closest to the silicon substrate 121 is exposed.

Next, as shown in B of FIG. 10, a barrier metal film (not shown) and a Cu seed layer 124A are formed by physical vapor deposition (PVD). The barrier metal film is a film for preventing diffusion of the connection electrical conductor 124 (Cu). The Cu seed layer 124A is an electrode when embedding the connection electrical conductor 124 by electrolytic plating. For the material of the barrier metal film, tantalum (Ta), titanium (Ti), tungsten (W), zirconium (Zr), a nitride film or carbon film thereof, or the like can be used. In the first structure example, titanium is used as the barrier metal film. The film thickness of the barrier metal film is set to, for example, about 0.3 μm and the film thickness of the Cu seed layer 124A is set to, for example, about 0.5 μm.

Next, as shown in C of FIG. 10, a photoresist 142 is formed in a desired region on the Cu seed layer 124A. The diameter of an opening region of the photoresist 142 in the cross-section along the line X-X′ is set to, for example, be larger than the diameter of the Cu seed layer 124A in the silicon through-hole 122 by about 15 μm.

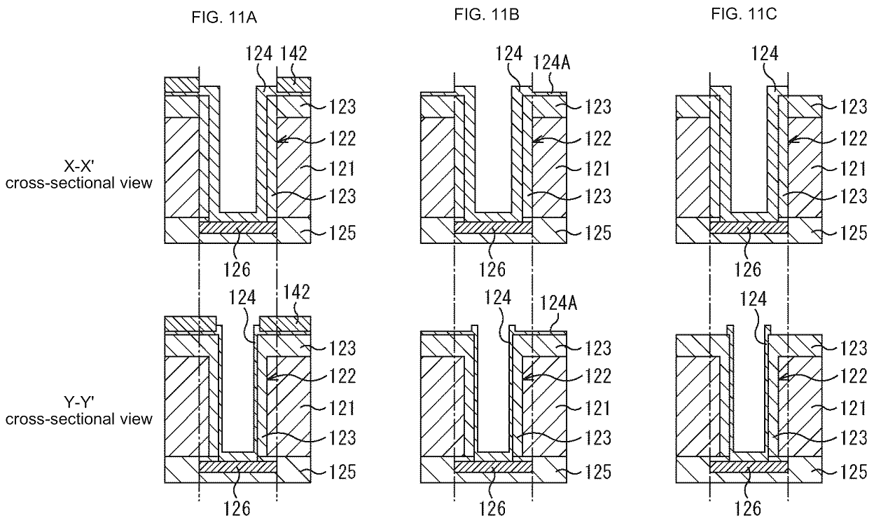

Next, copper (Cu) is formed by electrolytic plating using the Cu seed layer 124A as an electrode as shown in A of FIG. 11. As a result, the connection electrical conductor 124 is formed. The film thickness of the connection electrical conductor 124 in the cross-section along the line X-X′ is, for example, about 7.5 μm.

Next, as shown in B of FIG. 11, the photoresist 142 is removed by wet treatment or ashing treatment, and then the barrier metal film (not shown) and the Cu seed layer 124A under the photoresist 142 is removed by wet etching as shown in C of FIG. 11.

In the above-mentioned manner, the through-silicon-via 120 shown in FIG. 7 is completed. Then, the solder mask 91 and the solder ball 14 in FIG. 5 are formed.

In accordance with the above-mentioned manufacturing method, the through-silicon-via 120 can be produced only by changing the patterning of the photoresist 141 for forming the silicon through-hole 122 and the patterning of the photoresist 142 for performing electroplating. Therefore, the steps do not increase, for example, so the realization is easy.

### <5. Modified Example According to First Structure Example of Through-Silicon Via>

### <First to Tenth Modified Examples of First Structure Example>

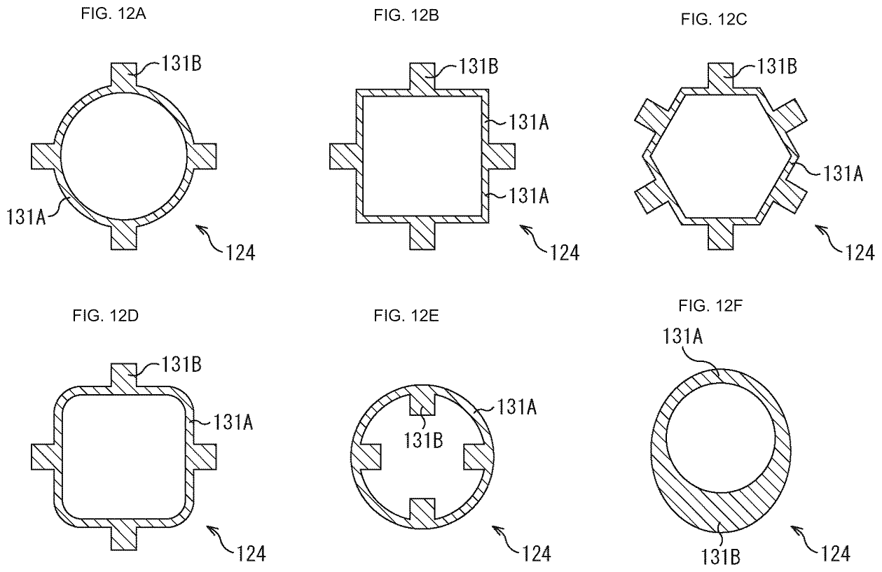

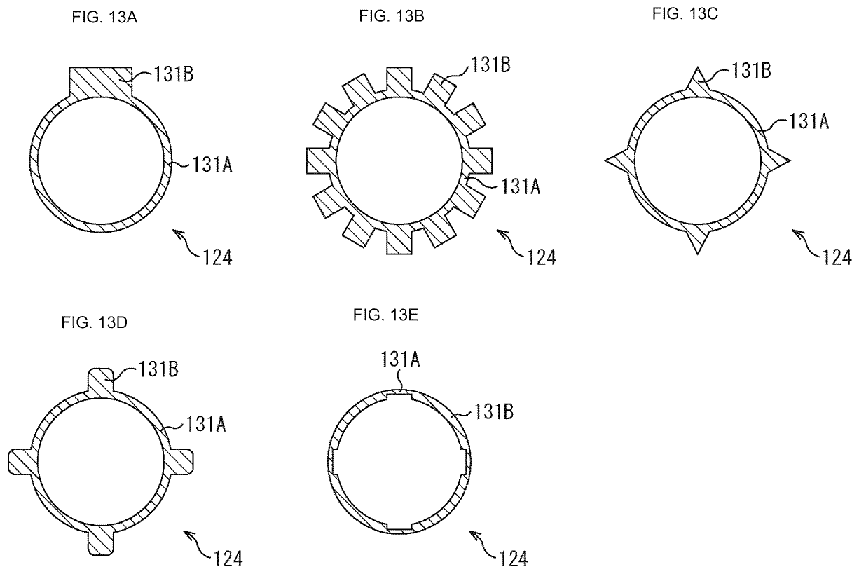

Modified examples of the through-silicon-via 120 as the first structure example of the through-silicon-via will be described with reference to FIGS. 12 and 13.

FIGS. 12 and 13 are plan views of the connection electrical conductor 124 at any depth position of the silicon substrate 121 as in A of FIG. 7. It should be noted that since the connection electrical conductor 124 is formed on the side wall of the opened silicon through-hole 122, the plane shape of the silicon through-hole 122 is also substantially shown.

A of FIG. 12 is the same figure as the first structure example shown in A of FIG. 7. Hereinafter, this shape will be referred to as a basic shape according to the first structure example. The connection electrical conductor 124 shown in A of FIG. 7 includes the thin film portions 131A and the four thick film portions 131B and the plane shape of the thin film portions 131A is a circular shape.

B of FIG. 12 is a top view showing a first modified example of the first structure example. In the first modified example, the plane shape of the thin film portions 131A is changed into a rectangular shape (square). Moreover, thick film portions 131B are arranged at the central portions of the respective sides of the rectangular thin film portions 131A. A total of four thick film portions 131B are arranged where one thick film portion 131B is provided at each side of the rectangular thin film portions 131A.

C of FIG. 12 is a top view showing a second modified example of the first structure example. In the second modified example, the plane shape of the thin film portions 131A is changed into a hexagonal shape. Moreover, thick film portions 131B are arranged at the central portions of the respective sides of the thin film portions 131A in the hexagonal shape. A total of six thick film portions 131B are arranged where one thick film portion 131B is provided at each side of the thin film portions 131A in the hexagonal shape.

D of FIG. 12 is a top view showing a third modified example of the first structure example. Although the third modified example is the same as the first modified example in that the plane shape of the thin film portions 131A is a rectangular shape, the third modified example is different from the first modified example in that the corner portions are set to have a round shape. A total of four thick film portions 131B are arranged where one thick film portion 131B is provided at each side of the rectangular thin film portions 131A.

E of FIG. 12 is a top view showing a fourth modified example of the first structure example. The fourth modified example is the same as the basic shape in A of FIG. 7 in that the plane shape of the thin film portions 131A is a circular shape. On the other hand, the fourth modified example is different from the basic shape where the thick film portions 131B are formed to be projections extending outwards from the circular shape in that the thick film portions 131B are formed to be projections extending inwards from the circular shape. A total of four thick film portions 131B are arranged where the thick film portions 131B are arranged at intervals of 90 degrees.

F of FIG. 12 is a top view showing a fifth modified example of the first structure example. In the fifth modified example, the boundary between the thin film portion 131A and the thick film portion 131B is unclear, and the connection electrical conductor 124 has a plane shape in which the film thickness at the side wall continuously changes in a circumferential direction. A portion at which the film thickness of the connection electrical conductor 124 whose film thickness continuously changes in the circumferential direction is the thinnest corresponds to at least the thin film portion 131A and a portion at which the film thickness of the connection electrical conductor 124 is the thickest corresponds to at least the thick film portion 131B. In the example in F of FIG. 12, the plane shape of the inner peripheral portion of the connection electrical conductor 124 is a circular shape and the plane shape of the outer peripheral portion is an elliptical shape. However, on the contrary, the plane shape of the inner peripheral portion of the connection electrical conductor 124 may be an elliptical shape and the plane shape of the outer peripheral portion may be a circular shape.

A of FIG. 13 is a top view showing a sixth modified example of the first structure example. The sixth modified example is the same as the basic shape in A of FIG. 7 in that the plane shape of the thin film portion 131A is a circular shape. On the other hand, the sixth modified example is different from the basic shape in that the position where the thick film portion 131B is arranged is set to a single predetermined position on the circular shape. It should be noted that the plane area of the single thick film portion 131B according to the sixth modified example is set to be larger than the plane area of one of the thick film portions 131B in the basic shape.

B of FIG. 13 is a top view showing a seventh modified example of the first structure example. The seventh modified example is the same as the basic shape in A of FIG. 7 in that the plane shape of the thin film portions 131A is a circular shape. On the other hand, the seventh modified example is different from the basic shape in A of FIG. 7 in that a total of twelve thick film portions 131B are arranged and projection portions more than four projection portions in the basic shape are provided. The twelve thick film portions 131B are arranged at equal intervals on the outer peripheral portion of the thin film portions 131A in the circular shape.

C of FIG. 13 is a top view showing an eighth modified example of the first structure example. The eighth modified example is the same as the basic shape in A of FIG. 7 in that the plane shape of the thin film portions 131A is a circular shape. On the other hand, the eighth modified example is different from the basic shape in A of FIG. 7 in that the plane shape of the thick film portion 131B is not a rectangular shape, but a triangular shape. A total of four thick film portions 131B are arranged where the thick film portions 131B are arranged at intervals of 90 degrees.

D of FIG. 13 is a top view showing a ninth modified example of the first structure example. The ninth modified example is the same as the basic shape in A of FIG. 7 in that the plane shape of the thin film portions 131A is a circular shape. On the other hand, the ninth modified example is different from the basic shape in A of FIG. 7 in that the plane shape of the thick film portion 131B is a rectangular shape, but its corner portions are rounded. A total of four thick film portions 131B are arranged where the thick film portions 131B are arranged at intervals of 90 degrees.

E of FIG. 13 is a top view showing a tenth modified example of the first structure example. Although the thick film portions 131B are formed by providing the projection portions in the above-mentioned basic shape and first to ninth modified examples, depression portions are provided in the tenth modified example. In the connection electrical conductor 124 according to the tenth modified example, portions where the film thickness of the depression portions provided at predetermined positions on the circular shape is smaller constitute the thin film portions 131A and circular portions other than the depression portions constitute the thick film portions 131B. That is, since the projection portions are changed into the depression portions, in the tenth modified example, the relationship between the thin film portions 131A and the thick film portions 131B is opposite to that in the basic shape in A of FIG. 7. As in E of FIG. 13, in a case where the number of thin film portions 131A as depression portions are four, the constituent area (volume) of the thick film portions 131B is larger than that of the thin film portions 131A. Therefore, it is actually favorable that many thin film portions 131A as depression portions are provided.

The shapes of the respective modified examples shown in FIGS. 12 and 13 may be combined as appropriate. For example, the toothed wheel-type seventh modified example where many thick film portions 131B as projection portions are provided in B of FIG. 13 may be combined with the ninth modified example in D of FIG. 13 where the corner portions of the projection portions are rounded, and the corner portions of the thick film portions 131B which are the toothed wheel-type projection portions may be rounded.

### <Eleventh and Twelfth Modified Examples of First Structure Example>

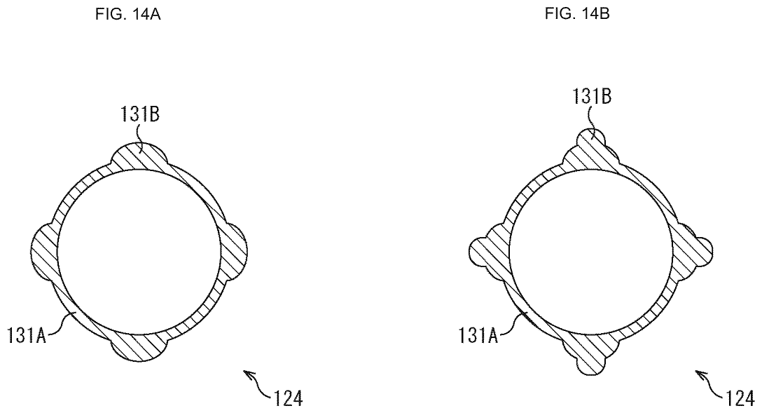

A of FIG. 14 is a plan view showing an eleventh modified example of the first structure example. The eleventh modified example is the same as the basic shape in A of FIG. 7 in that the plane shape of the thin film portions 131A is a circular shape. On the other hand, the eleventh modified example is different from the basic shape in A of FIG. 7 in that the plane shape of the thick film portion 131B is set to be not a rectangular shape, but a semi-circular or semi-elliptical shape. A total of four thick film portions 131B are arranged where the thick film portions 131B are arranged at intervals of 90 degrees.

B of FIG. 14 is a plan view showing a twelfth modified example of the first structure example. The twelfth modified example is the same as the basic shape in A of FIG. 7 in that the plane shape of the thin film portions 131A is a circular shape. On the other hand, the twelfth modified example is different from the basic shape in A of FIG. 7 in that the plane shape of the thick film portion 131B is not a rectangular shape, but a double shape in which a rectangular shape with rounded corner portions is arranged on a semi-circular or semi-elliptical shape. A total of four thick film portions 131B are arranged where the thick film portions 131B are arranged at intervals of 90 degrees.

The eleventh modified example in A of FIG. 14 and the twelfth modified example in B of FIG. 14 can also be produced only by changing the patterning of the photoresist 141 described in A of FIG. 9.

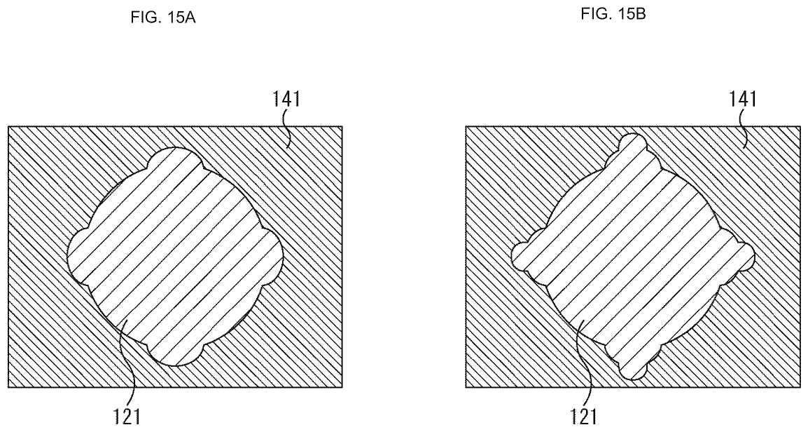

A of FIG. 15 is a plan view showing a formation region of the photoresist 141 in the step in A of FIG. 9 in a case where the eleventh modified example in A of FIG. 14 is produced.

B of FIG. 15 is a plan view showing a formation region of the photoresist 141 in the step in A of FIG. 9 in a case where the twelfth modified example in B of FIG. 14 is produced.

By setting the plane shape of the thick film portion 131B to be not a rectangular shape, but a semi-circular or semi-elliptical shape, and eliminating corner portions as in the eleventh modified example, stress concentration at the corner portions can be alleviated.

By setting the plane shape of the thick film portion 131B to be a double shape in which a rectangular shape with no corner portions are arranged on a semi-circular or semi-elliptical shape as in the twelfth modified example, stress concentration at the corner portions can be alleviated and the amount of connection electrical conductor 124 (copper) of the thick film portions 131B increases, which can achieve further reduction of resistance of the thick film portions 131B.

### <Thirteenth and Fourteenth Modified Examples of First Structure Example>

Next, a thirteenth modified example and a fourteenth modified example of the first structure example of the through-silicon-via will be described.

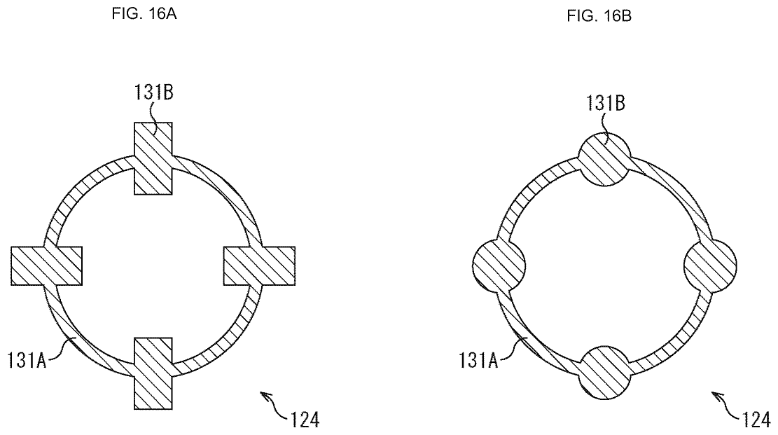

A of FIG. 16 is a plan view of the connection electrical conductor 124 of the through-silicon-via 120 according to the thirteenth modified example when viewed at any depth position of the silicon substrate 121 as in A of FIG. 7.

B of FIG. 16 is a plan view of the connection electrical conductor 124 of the through-silicon-via 120 according to the fourteenth modified example as in A of FIG. 7 when viewed at any depth position of the silicon substrate 121.

It should be noted that the cross-sectional views of the thirteenth modified example and the fourteenth modified example are similar to B and C of FIG. 7, and thus they will be omitted.

The connection electrical conductor 124 in the basic shape shown in A of FIG. 12 has a structure in which the plane shape of the thin film portions 131A is a circular shape and the projection portions are formed outside the circular shape as the thick film portions 131B. Meanwhile, in the thirteenth modified example and the fourteenth modified example in A and B of FIG. 16, the thick film portions 131B are configured as projection portions provided both outside and inside the thin film portions 131A in the circular shape.

The thirteenth modified example in A of FIG. 16 is an example in which the entire shape of each of the projection portions provided as the thick film portions 131B both outside and inside the thin film portions 131A in the circular shape is a rectangular shape. In contrast, the fourteenth modified example in B of FIG. 16 is an example in which the entire shape of each of the projection portions provided as the thick film portions 131B both outside and inside the thin film portions 131A in the circular shape is a semi-circular or semi-elliptical shape.

Moreover, it is also possible to employ a shape obtained by combining the thirteenth modified example in A of FIG. 16 or the fourteenth modified example in B of FIG. 16 with the shape according to each modified example shown in FIGS. 12 and 13 as appropriate. For example, by combining the thirteenth modified example in A of FIG. 16 with the projection portion shapes of the thick film portions 131B in D of FIG. 13, the corner portions of the projection portions provided both outside and inside may be rounded. Alternatively, by applying the eighth modified example shown in C of FIG. 13, the plane shape of each of the thick film portions 131B as the projection portions provided both outside and inside may be a triangular shape.

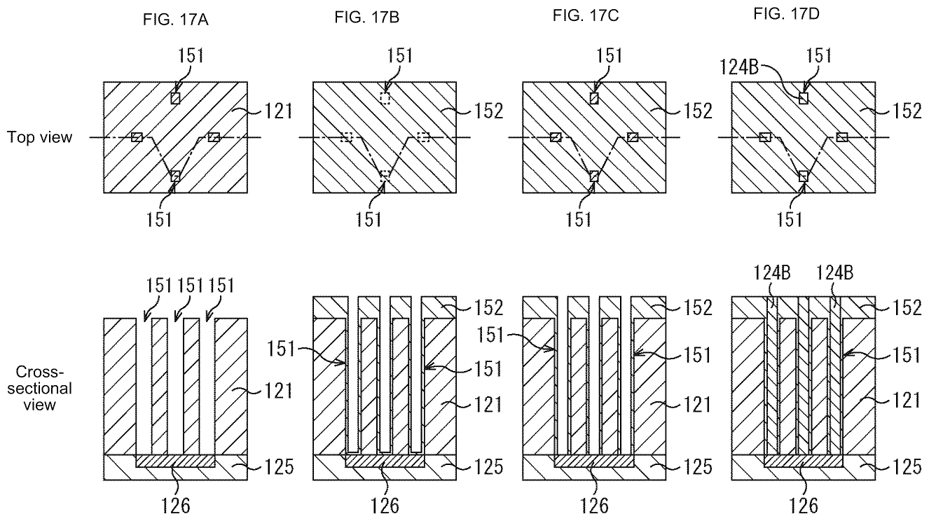

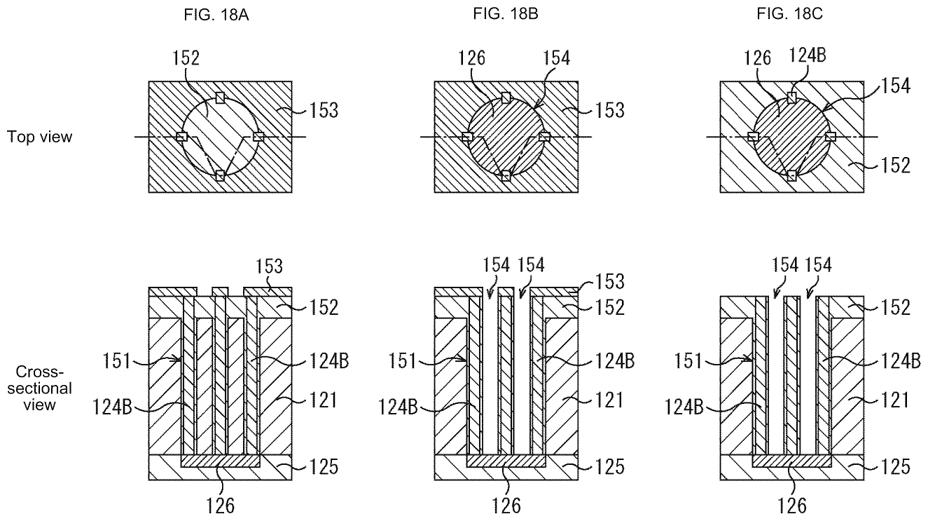

A manufacturing method for the thirteenth modified example in A of FIG. 16 will be described with reference to FIGS. 17 and 18. The upper parts of FIGS. 17 and 18 show top views when viewed from the side of the upper surface of the silicon substrate 121 and the lower parts show cross-sectional views taken along the line shown as a long dashed short dashed line in the top views in the upper part.

First of all, a photoresist (not shown) is patterned and dry etching is performed on the silicon substrate 121 so that positions for forming the rectangular thick film portions 131B are opened. In this manner, as shown in A of FIG. 17, silicon through-holes 151 are formed at the positions for forming the rectangular thick film portions 131B. A of FIG. 17 shows a state in which the photoresist has been removed after the completion of processing corresponding to the three steps in A to C of FIG. 9.

Next, as shown in B of FIG. 17, an insulation film 152 is deposited on the entire upper surface of the silicon substrate 121 by, for example, plasma CVD. The insulation film 152 is also deposited on the bottom surfaces and side walls of the silicon through-holes 151. The insulation film 152 can be, for example, an SiON film, an SiO₂ film, an SiN film, or the like.

Next, as shown in C of FIG. 17, the insulation film 152 on the bottom surfaces of the silicon through-holes 151 is removed by etching back. As a result, the wiring layer 126 closest to the silicon substrate 121 is exposed.

Next, as shown in D of FIG. 17, the upper surface is planarized by CMP after copper 124B which becomes the thick film portions 131B of the connection electrical conductor 124 is embedded in the silicon through-holes 151.

Next, as shown in A of FIG. 18, a photoresist 153 is patterned in a circular shape according to the plane shape of the thin film portions 131A on a further upper surface on the insulation film 152 and the copper 124B on the upper surface of the silicon substrate 121. The photoresist 153 is also formed on upper surfaces of the copper 124B portions which become the thick film portions 131B. Since the copper 124B portions which become the thick film portions 131B are formed at four positions at intervals of 90 degrees, even if the photoresist 153 patterned in a circular shape is deviated in either the vertical direction or the horizontal direction, at least one position of the copper 124B portions at the four positions is always covered. Therefore, it can be left as the thick film portion 131B. That is, it can be said that the structure in which the thick film portions 131B are arranged at the four positions at intervals of 90 degrees is arrangement advantageous to cope with the deviation of the patterning of the photoresist 153.

Next, as shown in B of FIG. 18, the silicon substrate 121 corresponding to an opening region of the photoresist 153 is removed by dry etching. As a result, a silicon through-hole 154 is formed. Then, as shown in C of FIG. 18, the photoresist 153 formed on the uppermost surface is removed.

After C of FIG. 18, the manufacturing method for the basic shape of the first structure described above with reference to D of FIG. 9 to C of FIG. 11 is performed. Briefly describing the steps in D of FIG. 9 to C of FIG. 11, the insulation film 123 is deposited on a bottom surface and a side wall of the silicon through-hole 154 as described in D of FIG. 9. Then, the barrier metal film and the Cu seed layer 124A are formed, copper (Cu) is formed by electrolytic plating, and the connection electrical conductor 124 is obtained. Last of all, the barrier metal film and the Cu seed layer 124A in an unnecessary region are removed.

In accordance with the above-mentioned manufacturing method, the through-silicon-via 120 having the connection electrical conductor 124 shown in A of FIG. 16 can be formed.

It should be noted that the fourteenth modified example in B of FIG. 16, i.e., the manufacturing method for the through-silicon-via 120 including the connection electrical conductor 124 in which the entire shape of each of the projection portions provided both outside and inside is a circular or elliptical shape, is basically similar to the thirteenth modified example described with reference to FIGS. 17 and 18. The fourteenth modified example in B of FIG. 16 is different from the thirteenth modified example described with reference to FIGS. 17 and 18 in that the pattern shape of the silicon through-hole 151 in A of FIG. 17 and the pattern shape of the photoresist 153 in A of FIG. 18 are a circular or elliptical shape.

### <Fifteenth Modified Example of First Structure Example>

Next, a fifteenth modified example of the first structure example of the through-silicon-via will be described.

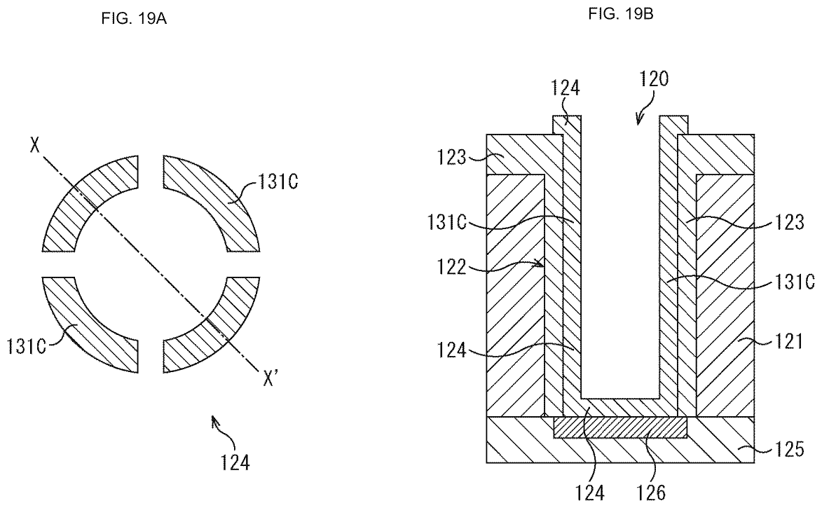

B of FIG. 19 is a cross-sectional view of the through-silicon-via 120 according to the fifteenth modified example. B of FIG. 19 is a cross-sectional view taken along the line X-X′ in A of FIG. 19.

A of FIG. 19 is a plan view of the connection electrical conductor 124 of the through-silicon-via 120 according to the fifteenth modified example when viewed at a predetermined depth position of the silicon substrate 121 in B of FIG. 19.

The connection electrical conductor 124 of the through-silicon-via 120 according to the fifteenth modified example is configured in such a manner that the portions at the four positions where the thick film portions 131B are formed in A of FIG. 7 are divided and separated into four circular arc-shaped electrical conductors 131C as shown in A of FIG. 19. It should be noted that the four circular arc-shaped electrical conductors 131C are integrated, connecting to each other at a bottom surface portion connecting the wiring layer 126 in the interlayer insulation film 125 as shown in B of FIG. 19.

Configurations other than the connection electrical conductor 124 are similar to the basic shape according to the first structure example.

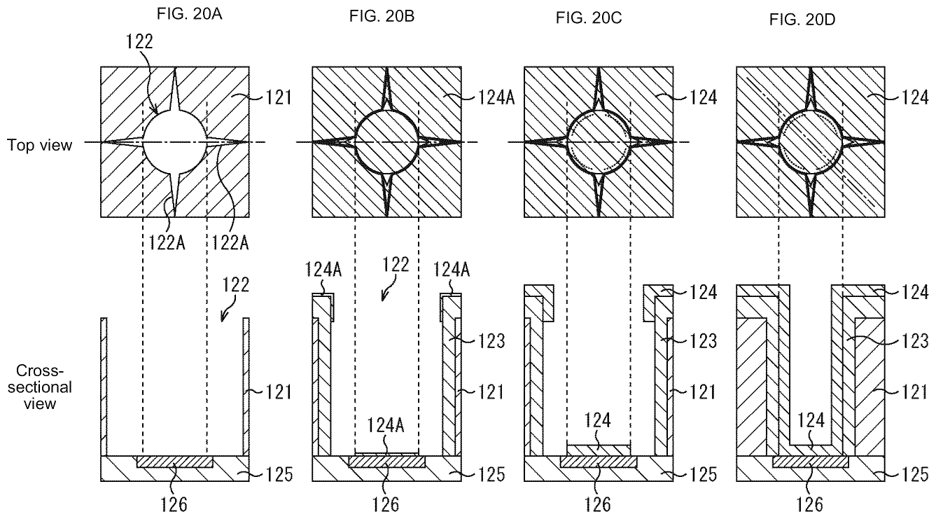

A manufacturing method for the fifteenth modified example in FIG. 19 will be described with reference to FIG. 20. The upper part of FIG. 20 shows top views when viewed from the side of the upper surface of the silicon substrate 121 and the lower part shows cross-sectional views taken along the line shown as a long dashed short dashed line in the top views in the upper part.

First of all, a photoresist (not shown) is patterned and dry etching is performed on the silicon substrate 121. In this manner, the silicon through-hole 122 is formed as shown in A of FIG. 20. A of FIG. 20 shows a state in which the photoresist has been removed after the completion of processing corresponding to the three steps in A to C of FIG. 9.

Here, as a difference from the basic shape in FIG. 7, as shown in the top view in A of FIG. 20, groove patterns 122A at the four positions are formed in the silicon through-hole 122. The groove patterns 122A are triangular shape patterns each having a peripheral portion of the circle as a bottom side and a width which become smaller toward an angle (vertex) outside the circular shape.

Next, the film deposition step for the insulation film 123 described in D of FIG. 9 and the etch back step described in A of FIG. 10 are performed, and then the step of forming the barrier metal film (not shown) and the Cu seed layer 124A described in B of FIG. 10 is performed. B of FIG. 20 shows a state in which the Cu seed layer 124A is formed. Here, although the barrier metal film and the Cu seed layer 124A are formed by sputtering, the barrier metal film and the Cu seed layer 124A are not deposited in the regions of the groove patterns 122A at the four positions because the coverage of the sputtering is bad. Moreover, in an area where the aspect ratio is equal to or higher than a predetermined value (e.g., the aspect ratio is 2 or more), the barrier metal film and the Cu seed layer 124A are not deposited. Therefore, as in B of FIG. 20, the barrier metal film and the Cu seed layer 124A are deposited only on the bottom surface of the silicon through-hole 122 excluding the groove patterns 122A, the upper surface of the insulation film 123, and parts of the groove patterns 122A near it.

Next, as in the step described in A of FIG. 11, the photoresist 142 (not shown) is formed in a desired region on the Cu seed layer 124A, and then copper (Cu) is formed by electrolytic plating using the Cu seed layer 124A as an electrode as the connection electrical conductor 124.

C of FIG. 20 shows the cross-sectional view including the regions of the groove patterns 122A and D of FIG. 20 shows the cross-sectional view without the regions of the groove patterns 122A. In the regions of the groove patterns 122A where the Cu seed layer 124A is not deposited, plating copper (Cu) does not grow. Therefore, as a result, a structure in which the copper as the connection electrical conductor 124 is divided at the regions at the four positions where the groove patterns 122A are present is formed as shown in A of FIG. 19.

The steps following C and D of FIG. 20, specifically, the steps of removing the photoresist 142 and removing the barrier metal film and the Cu seed layer 124A which are unnecessary are similar to those of the manufacturing method for the basic shape described in FIG. 11.

In accordance with the structure of the through-silicon-via 120 according to the fifteenth modified example and the manufacturing method therefor, the groove patterns 122A are provided in formation of the connection electrical conductor 124 by electrolytic plating, such that the connection electrical conductor 124 is always divided at the portions of the groove patterns 122A irrespective of the film thickness of the connection electrical conductor 124 (copper) formed on the side wall of the silicon through-hole 122.

The through-silicon-via 120 according to the fifteenth modified example is advantageous when forming the connection electrical conductor 124 (copper) formed on the side wall of the silicon through-hole 122 with a relatively large film thickness. Reduction in the resistance of the connection electrical conductor 124 and alleviation of the film stress can be achieved.

### <6. Summary of First Structure Example of Through-Silicon Via>

As described above, the through-silicon-via 120 according to the first structure example includes the connection electrical conductor 124 via the insulation film 123 on the side wall of the silicon through-hole 122 formed in the silicon substrate 121. In the cross-section at any depth of the silicon through-hole 122, the connection electrical conductor 124 has a plurality of thicknesses including a thin film portion 131A with a smaller film thickness and a thick film portion 131B with a larger film thickness. Either the thin film portion 131A or the thick film portion 131B is arranged by forming a projection portion or depression portion at a predetermined position on the plane shape of the silicon through-hole 122. It is sufficient that the thin film portion 131A or the thick film portion 131B formed as the projection portion or depression portion is provided at one or more positions. Moreover, the projection portions may be both outside and inside on the plane shape of the silicon through-hole 122. The plane shape of the silicon through-hole 122 can be any one of a circular shape, an elliptical shape, a polygonal shape, or the like. The polygonal shape also includes a polygonal shape with rounded corner portions.

In accordance with the through-silicon-via 120 as the first structure example of the through-silicon-via, the film stress is reduced by the connection electrical conductor 124 including the thin film portions 131A while the resistance is reduced by including the thick film portions 131B. As a result, the connection reliability is improved.

From a perspective of the manufacturing method, the through-silicon-via 120 can be formed without increasing the number of processes, and thus the realization is easy. Since no stepped portion as in the structure according to Patent Literature 1 described above as the prior-art document is made, no planarization step for eliminating the stepped portion is needed.

### <7. Second Structure Example of Through-Silicon Via>

Next, a second structure example of the through-silicon-via that enables reduction of the film stress will be described.

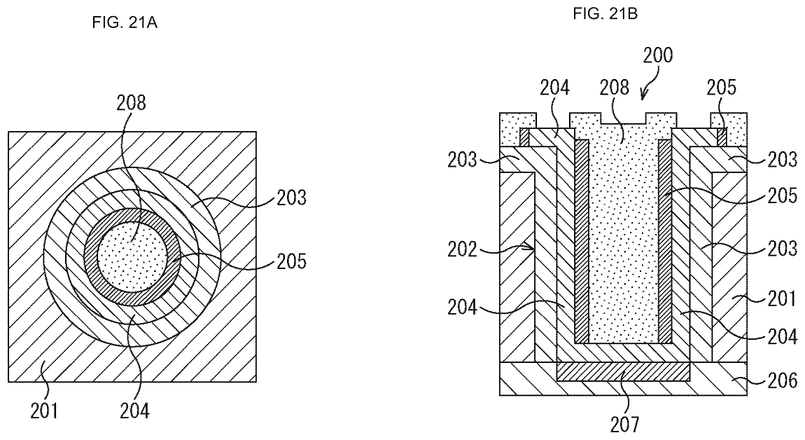

FIG. 21 is views showing the second structure example of the through-silicon-via.

B of FIG. 21 is a cross-sectional view of a through-silicon-via 200 which is the second structure example of the through-silicon-via.

A of FIG. 21 is a plan view of the through-silicon-via 200 in B of FIG. 21 when viewed at any depth position of the silicon substrate 121.

The through-silicon-via 200 includes a connection electrical conductor 204 penetrating a silicon substrate 201. The connection electrical conductor 204 is formed on a side wall (inner wall) of a silicon through-hole 202 formed on the silicon substrate 201 and an upper surface of the silicon substrate 201 via an insulation film 203. A stress suppression film 205 that reduces the stress of the connection electrical conductor 204 is formed further inside the connection electrical conductor 204 formed on the side wall of the silicon through-hole 202. Therefore, the through-silicon-via 200 is constituted by the insulation film 203 formed on the upper surface of the silicon substrate 201 and the side wall of the silicon through-hole 202, the connection electrical conductor 204 formed on its upper surface, and the stress suppression film 205. The stress suppression film 205 is formed also on the side wall at the outer peripheral portion of the connection electrical conductor 204 on the upper surface of the silicon substrate 201. A solder mask 208 is embedded further inside the stress suppression film 205. The solder mask 208 is also formed on the insulation film 203 on the upper surface of the silicon substrate 201 to protect the upper surface of the silicon substrate 201.

The connection electrical conductor 204 is connected to a wiring layer 207 formed in an interlayer insulation film 206 on a lower surface side of the silicon substrate 201 which is the lower side in FIG. 21. In this manner, the lower surface side and an upper surface side of the silicon substrate 201 are electrically connected to each other.

The through-silicon-via 200 in FIG. 21 can be arranged in the solid-state image pickup apparatus 1 in place of the through-silicon-via 88 in FIG. 5 or 6 described above. The silicon substrate 201 corresponds to the silicon substrate 81 in FIG. 5 and the wiring layer 207 corresponds to the wiring layer 83c in FIG. 5. The connection electrical conductor 204 formed on the upper surface side of the silicon substrate 201 which is the upper side in FIG. 21 also serves as the rewiring 90 in FIG. 5 and, for example, the solder ball 14 (FIG. 5 or 6) is formed on the connection electrical conductor 204 where the solder mask 208 is not formed.

The connection electrical conductor 204 can be, for example, formed of copper (Cu), tungsten (W), titanium (Ti), tantalum (Ta), titanium tungsten alloy (TiW), nickel (Ni), gold (Au), polysilicon, and the like as in the connection electrical conductor 87 in FIG. 5. For example, as in the above-mentioned example, in a case where the connection electrical conductor 204 is formed with copper, the connection electrical conductor 204 has tensile stress of approximately 250 to 700 Mpa.

In view of this, for example, a film with compressive stress opposite to tensile stress, i.e., an opposite-stress film is employed as the stress suppression film 205 that reduces the tensile stress. For example, an insulation film such as an SiN film, an SiO₂ film, or an SiON film can be employed as the opposite-stress film with the compressive stress. Among them, the SiN film is favorable because it is also easy to control the process. Moreover, an insulation film such as an SiN film, an SiO₂ film, or an SiON film is generally also low in thermal expansion coefficient.

Moreover, the stress suppression film 205 may be a metal film with compressive stress opposite to tensile stress or a low-stress metal film with tensile stress lower than that of the material of the connection electrical conductor 204. The copper as the connection electrical conductor 204 has tensile stress of approximately 250 to 700 Mpa, and thus it is sufficient that the metal film may be a film with tensile stress (0<σ(tensile)<250) ranging from 0 to 250 Mpa (not including 250 Mpa) or a film with compressive stress (0<σ(compression)=<700) in a range of 0 to 700 Mpa. Such a metal film can be, for example, TaN. Since TaN is a material also used as barrier metal, TaN has an advantage that it can also be used for the barrier metal.

### <Manufacturing Method for Second Structure Example of Through-Silicon Via>

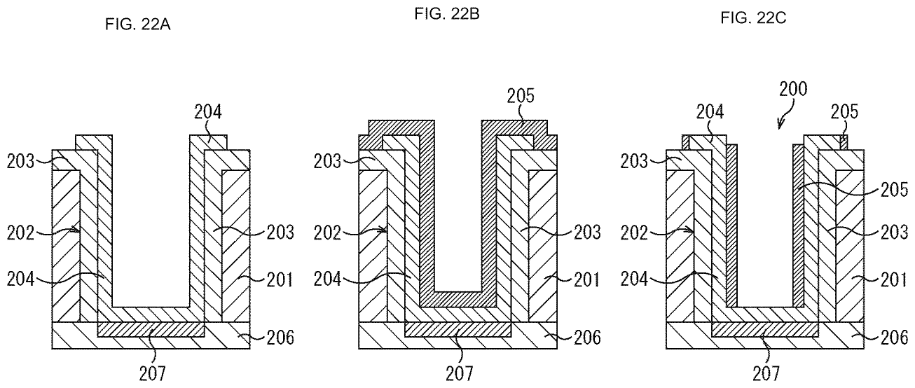

A manufacturing method for the through-silicon-via 200 according to the second structure example shown in FIG. 21 will be described with reference to FIG. 22.

First of all, as shown in A of FIG. 22, the silicon through-hole 202 is formed on the silicon substrate 201, and then the insulation film 203 and the connection electrical conductor 204 are formed. Manufacturing processes up to A of FIG. 22 are similar to those of the above-mentioned first structure example.

Next, as shown in B of FIG. 22, a stress suppression film 205 is formed on the upper surface (inner wall) of the connection electrical conductor 204 in the silicon through-hole 202 and the upper surface of the silicon substrate 201. The stress suppression film 205 is, for example, an SiN film with compressive stress opposite to tensile stress.

Then, the stress suppression film 205 is entirely removed in a direction perpendicular to a plane direction of the silicon substrate 201 by an entire-surface etch back step. As a result, as shown in C of FIG. 22, the stress suppression film 205 of the upper surface of the connection electrical conductor 204 on the silicon substrate 201 is removed and the through-silicon-via 200 shown in B of FIG. 21 is completed. Last of all, although not shown in the figure, the solder mask 208 is embedded inside the through-silicon-via 200 and is also formed on the insulation film 203 on the upper surface of the silicon substrate 201.

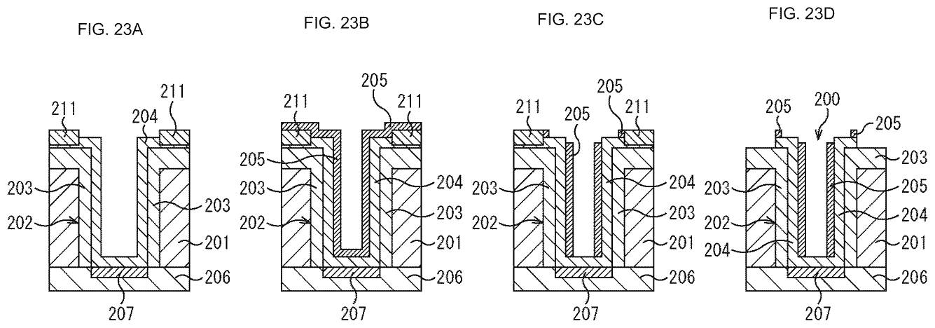

In a case where the stress suppression film 205 is formed of a metal film, the manufacturing method shown in FIG. 23 can also be employed.

That is, FIG. 23 is views showing another manufacturing method for the through-silicon-via 200 shown in FIG. 21.

Specifically, as shown in A of FIG. 23, copper (Cu) is made to grow by electrolytic plating using a Cu seed layer as an electrode and the connection electrical conductor 204 is formed, and then a metal film as the stress suppression film 205 is deposited as shown in B of FIG. 23 without removing a photoresist 211. The deposition method for the metal film is favorably sputtering. However, the film deposition can be performed also by low-temperature CVD.

Then, the stress suppression film 205 is entirely removed in the direction perpendicular to the plane direction of the silicon substrate 201 by an entire-surface etch back step. As a result, as shown in C of FIG. 23, the stress suppression film 205 on an upper surface of the photoresist 211 is removed. Although the stress suppression film 205 on the connection electrical conductor 204 on the upper surface of the silicon substrate 201 is removed by anisotropic dry etching, a part of the stress suppression film 205 whose film thickness is larger remains.

Last of all, as shown in D of FIG. 23, the photoresist 211 is removed by wet treatment or ashing treatment, and then the Cu seed layer below the photoresist 211 is removed.

In accordance with the manufacturing method in FIG. 23, as shown in D of FIG. 23, the part of the stress suppression film 205 remains on the connection electrical conductor 204 of the upper surface of the silicon substrate 201. However, since the stress suppression film 205 is the metal film, it remains with no problem. Then, the point that the solder mask 208 is formed is similar.

### <Modified Example of Second Structure Example of Through-Silicon Via>

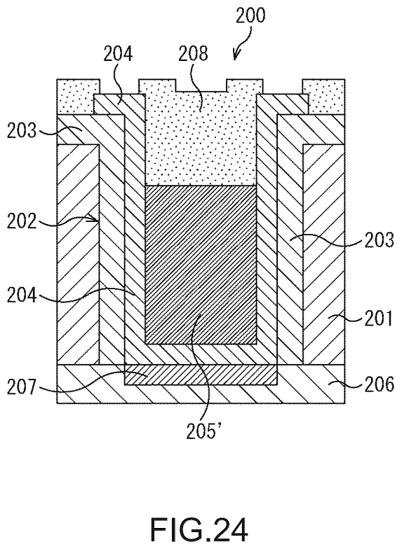

FIG. 24 is a cross-sectional view showing a modified example of the second structure example of the through-silicon-via.

In FIG. 24, portions corresponding to the through-silicon-via 200 in FIG. 21 shown as the second structure example of the through-silicon-via will be denoted by the same reference signs and descriptions thereof will be omitted as appropriate.

In the above description of the second structure example, an insulation film such as an SiN film, an SiO₂ film, or an SiON film or a metal film as TaN can be used as the stress suppression film 205. In addition, an organic film including at least C and H can be used as the stress suppression film 205. Such an organic film can be, for example, amorphous carbon film (α-C film) or poly(aryl ethers).

FIG. 24 is a cross-sectional view of the through-silicon-via 200 in a case of using an organic film 205′ as the stress suppression film 205.

In a case where the organic film 205′ is used as the stress suppression film 205, a structure in which the organic film 205′ is embedded inside the connection electrical conductor 204 in the silicon through-hole 202 as shown in FIG. 24 can be employed. The solder mask 208 is formed on an upper surface of the organic film 205′ embedded inside the through-silicon-via 200 and the insulation film 203 on the upper surface of the silicon substrate 201.

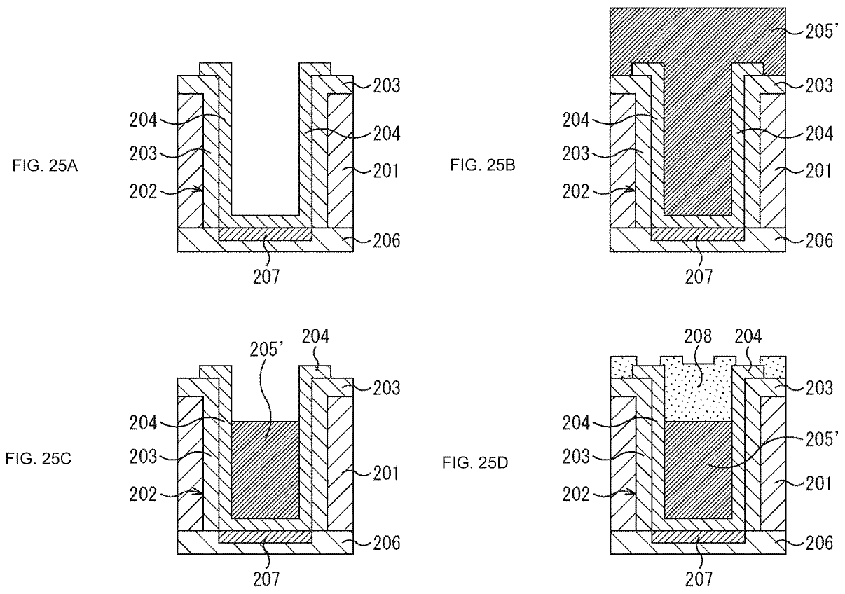

FIG. 25 is views showing a manufacturing method for the through-silicon-via 200 shown in FIG. 24.

First of all, as shown in A of FIG. 25, the silicon through-hole 202 is formed the silicon substrate 201, and then the insulation film 203 and the connection electrical conductor 204 are formed. Manufacturing processes up to A of FIG. 25 are similar to those of A of FIG. 22.

Next, as shown in B of FIG. 25, the organic film 205′ is embedded in the entire inside of the connection electrical conductor 204 in the silicon through-hole 202 by coating or CVD. In a case of embedding the organic film 205′ by the coating, the organic film 205′ often has tensile stress, and thus the stress is adjusted to change into compressive stress by heat treatment. In a case of embedding the organic film 205′ by the CVD, the organic film 205′ with compressive stress can be deposited under film deposition conditions. For example, poly(aryl ethers) heat-resistant up to 400° C. can be employed as the material of the organic film 205′.

Next, as shown in C of FIG. 25, the organic film 205′ is entirely removed in the direction perpendicular to the plane direction of the silicon substrate 201 by an entire-surface etch back step. As a result, the organic film 205′ on the silicon substrate 201 is removed.

Last of all, the solder mask 208 is applied on the entire upper surface of the silicon substrate 201, and then predetermined regions in the connection electrical conductor 204 of the upper surface of the silicon substrate 201 are opened as shown in D of FIG. 25. The openings in the connection electrical conductor 204 serve as external connection terminal portions associated with the solder ball 14 (FIG. 5 or 6) and wire bonding.

### <8. Summary of Second Structure Example of Through-Silicon Via>

As described above, the through-silicon-via 200 according to the second structure example includes the connection electrical conductor 204 via the insulation film 203 on the side wall of the silicon through-hole 202 formed on the silicon substrate 201. The through-silicon-via 200 further includes the stress suppression film 205 that reduces the stress of the connection electrical conductor 204. The stress suppression film 205 can be an opposite-stress film with compressive stress opposite to tensile stress of the connection electrical conductor 204, and is, for example, constituted by an insulation film such as an SiN film, an SiO₂ film, or an SiON film. Alternatively, the stress suppression film 205 may be a metal film with compressive stress opposite to tensile stress of the connection electrical conductor 204 or a metal film with tensile stress lower than that of the material of the connection electrical conductor 204, and is, for example, constituted by a metal film such as TaN.

In accordance with the through-silicon-via 200 which is the second structure example of the through-silicon-via, due to the provision of the stress suppression film 205, the film stress can be reduced and film peeling or cracking can be suppressed. As a result, the yield of the wiring layer 207 and the connection reliability with the wiring layer 207 can be improved. Since no stepped portion as in the structure according to Patent Literature 1 described above as the prior-art document is made, no planarization step for eliminating the stepped portion is needed.

### (Combination of First Structure Example and Second Structure Example)

The stress suppression film 205 of the through-silicon-via 200 according to the above-mentioned second structure example may be further added to the structure of the through-silicon-via 120 according to the above-mentioned first structure example. For example, the stress suppression film 205 may be further formed on a side wall upper surface of the connection electrical conductor 124 with the plurality of thicknesses including the thin film portions 131A and the thick film portions 131B, which have been formed on the side wall of the silicon through-hole 122 in FIG. 7.

### <9. Third Structure Example of Through-Silicon Via>

Next, a third structure example of the through-silicon-via that enables reduction of the film stress will be described.

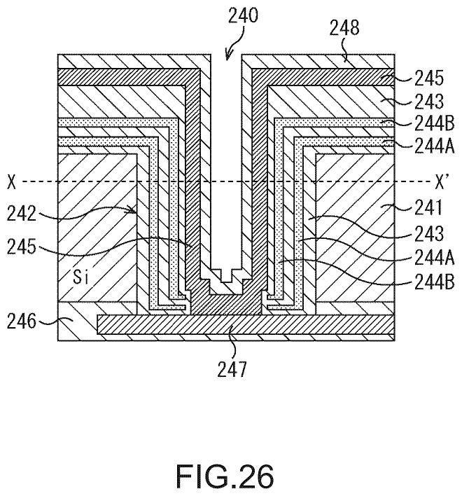

FIG. 26 is a cross-sectional view of a through-silicon-via 240 which is the third structure example of the through-silicon-via.

The through-silicon-via 240 includes a connection electrical conductor 245 inside a silicon through-hole 242 penetrating a silicon substrate 241. The connection electrical conductor 245 is connected to a wiring layer 247 formed in an interlayer insulation film 246 on a lower surface side of the silicon substrate 241 which is the lower side in FIG. 26, thereby electrically connecting the lower surface side and an upper surface side of the silicon substrate 241. The connection electrical conductor 245 is formed on a side wall (inner wall) of the silicon through-hole 242 and the upper surface of the silicon substrate 241. As in the above-mentioned first structure example and the like, the connection electrical conductor 245 can be, for example, formed of copper (Cu), tungsten (W), titanium (Ti), tantalum (Ta), titanium tungsten alloy (TiW), nickel (Ni), gold (Au), polysilicon, and the like. Here, copper is used in the third structure example.

The through-silicon-via 240 in FIG. 26 can be arranged in the solid-state image pickup apparatus 1 in place of the through-silicon-via 88 in FIG. 5 or 6 described above. The silicon substrate 241 corresponds to the silicon substrate 81 in FIG. 5 and the wiring layer 247 corresponds to the wiring layer 83c in FIG. 5. A part of the connection electrical conductor 245 formed on the upper surface side of the silicon substrate 241 which is the upper side in FIG. 26 is exposed and also serves as the rewiring 90 in FIG. 5. For example, the solder ball 14 (FIG. 5 or 6) is formed on the exposed connection electrical conductor 245.

Two buffer layers 244A and 244B are arranged via insulation films 243 between the connection electrical conductor 245 and the silicon substrate 241 in the silicon through-hole 242. In FIG. 26, the buffer layer 244A is an outside buffer layer 244 closer to the silicon substrate 241 and the buffer layer 244B is an inside buffer layer 244 closer to the connection electrical conductor 245. When the two buffer layers 244A and 244B are not particularly distinguished from each other, they will be simply referred to as buffer layers 244. The insulation film 243 is inserted between the buffer layer 244A and the buffer layer 244B and the insulation films 243 are also inserted between the buffer layer 244A and the silicon substrate 241 and between and the buffer layer 244B and the connection electrical conductor 245. An insulation film 248 is formed further inside the connection electrical conductor 245 so that the insulation film 248 covers the connection electrical conductor 245.

When the stress (film stress) of the insulation films 243 becomes a certain value or more, cracking occurs in the insulation films 243. In the through-silicon-via 240 in FIG. 26, the two buffer layers 244A and 244B are inserted between the connection electrical conductor 245 and the silicon substrate 241 in the silicon through-hole 242 to reduce the stress of the insulation films 243. Since the Hooke's law σ=Eε is established between the stress σ and the distortion ε, a material with a Young's modulus E lower than that of the insulation films 243 is employed as the material of the buffer layer 244.

In the third structure example, for example, an SiO₂ film or an SiN film is employed as the insulation films 243. The Young's modulus E of the SiO₂ film is about 65 GPa and the Young's modulus E of the SiN film is about 240 GPa.

In contrast, for example, a metal film including a predetermined metal material can be used as the buffer layer 244. Specifically, a metal film including Ti, Al, Mg, Sn, Al—Mg alloy can be formed as the buffer layer 244. For example, the Young's modulus E of Ti, Al, Mg, and Al—Mg alloy is Ti=130 GPa, Al=45 GPa, Mg=44 GPa, and Al—Mg alloy=about 45 GPa.

Alternatively, an organic film including a predetermined resin material may be used the buffer layer 244. For example, an organic film including an epoxy resin and a benzocyclobutene resin (BCB resin) can be formed as the buffer layer 244. For example, regarding the Young's modulus E of the epoxy resin and the BCB resin, the epoxy resin=3.8 GPa and the BCB resin=about 3 GPa.

Moreover, the distortion ε to influence the Young's modulus E and the stress σ in accordance with Hooke's law is associated with the thermal expansion coefficient. Therefore, the material of the buffer layer 244 is desirably a material whose the thermal expansion coefficient (CTE) takes a value between the connection electrical conductor 245 and the silicon substrate 241. For example, the thermal expansion coefficient of the silicon substrate 241 is 3.2 μm/m·K and the thermal expansion coefficient of the copper as the connection electrical conductor 245 is 16.5 μm/m·K, and thus a material whose thermal expansion coefficient is within a range of from 3.2 μm/m·K to 16.5 μm/m·K (3.2 μm/m·K<CTE <16.5 μm/m·K) as the buffer layer 244 is desirably used.

For example, thermal expansion coefficients of the above-mentioned Ti, Al, Mg, and Al—Mg alloy and epoxy resin and BCB resin are Ti=8 μm/m·K, Al=26 μm/m·K, Mg=27 μm/m·K, Al—Mg alloy=27 μm/m·K, epoxy resin=73 μm/m·K, and BCB resin=52 μm/m·K. Therefore, Ti is desirably employed also in view of the thermal expansion coefficient.

Also on the upper surface of the silicon substrate 241 which is the upper side in FIG. 26, which serves as a connection surface electrically connected to the external substrate, as in the formation layer in the silicon through-hole 242, the two buffer layers 244A and 244B are arranged via the insulation films 243 and the insulation film 248 is further formed on the upper side of the connection electrical conductor 245. The insulation film 248 can be formed of an SiO₂ film or an SiN film like the insulation films 243.

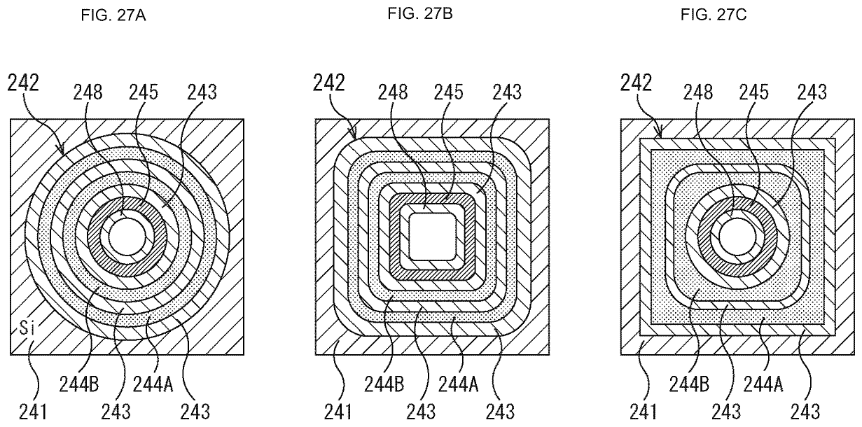

A to C of FIG. 27 show plan views along the line X-X′ in FIG. 26.

A and B of FIG. 27 show examples in which shape of each of the insulation films 243, the buffer layer 244, and the connection electrical conductor 245 has been formed conforming to the plane shape of the silicon through-hole 242.

The silicon through-hole 242 can be formed in a circular plane shape as shown in A of FIG. 27. The insulation film 243, the buffer layer 244A, the insulation film 243, the buffer layer 244B, and the insulation film 243 are formed in the stated order toward the inside connection electrical conductor 245 from the side of the silicon substrate 241. In addition, the insulation film 248 is formed inside the connection electrical conductor 245.

Moreover, the silicon through-hole 242 may be formed in a rectangular plane shape as shown in B of FIG. 27. It should be noted that since each corner portion of the rectangular shape is not neatly etched at a right angle, it typically has a rectangular plane shape with rounded corner portions as shown in B of FIG. 27.

Still alternatively, the silicon through-hole 242 may be formed in a plane shape combining the circular plane shape with the rectangular plane shape as shown in C of FIG. 27. In the example in C of FIG. 27, the insulation film 243, the buffer layer 244A, the insulation film 243, and the buffer layer 244B are each formed in a rectangular plane shape from the side of the silicon substrate 241 and the insulation films 243 inside and outside the connection electrical conductor 245 are each formed in a circular plane shape. By employing the plane shape combining the rectangular shape with the circular shape in this manner, the buffer layer 244 at the corner portions which are stress concentration points can be formed to be thicker, and thus the film stress can be alleviated.

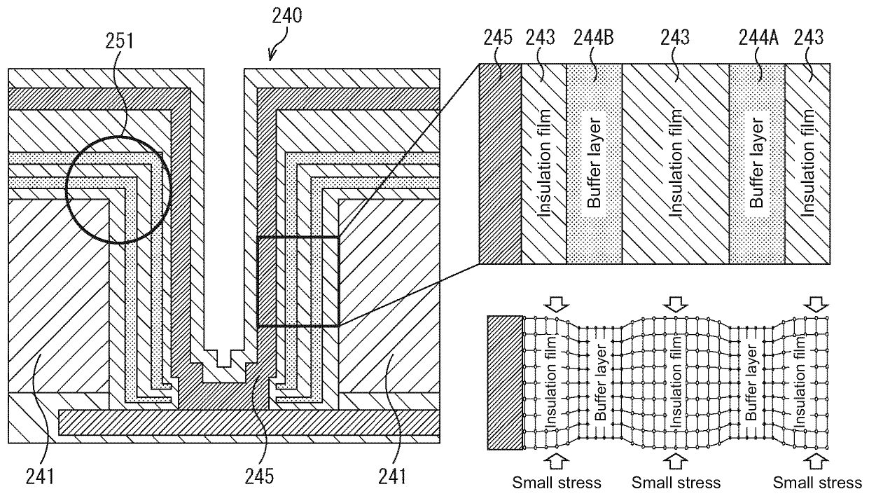

FIG. 28 is a view describing effects of the through-silicon-via 240.

In the through-silicon-via 240, as described above, not only the insulation films 243, but also the two buffer layers 244A and 244B are inserted between the connection electrical conductor 245 in the silicon through-hole 242 and the silicon substrate 241. The two buffer layers 244A and 244B are formed of a material with a Young's modulus E lower than that of the insulation films 243, and thus as shown in the lower right image in FIG. 28, when upward and downward stress to the insulation films 243 is generated, the buffer layers 244A and 244B with a much lower Young's modulus E absorbs the stress, and thus the stress applied to the insulation films 243 can be decreased. Accordingly, the film stress of the insulation films 243 in the silicon through-hole 242 can be reduced and cracking and film peeling of the insulation films 243 can be prevented.

Moreover, the two buffer layers 244A and 244B are formed not only in the silicon through-hole 242, but also on the upper surface of the silicon substrate 241. Therefore, the two buffer layers 244A and 244B cover the corner portions of the silicon substrate 241 as in a region 251 shown as the circle in the cross-sectional view.

In general, it is known that large stress easily concentrates at the corner portions of the silicon substrate 241, and cracking of the insulation films 243 easily occurs from the corner portions of the silicon substrate 241. By employing the structure in which the two buffer layers 244A and 244B cover the corner portions of the silicon substrate 241 with the both surfaces of the side wall and the upper surface, stress concentration points at the corner portions of the silicon substrate 241 can be covered, and cracking that occurs at the corner portions of the silicon substrate 241 can be suppressed.

### <Manufacturing Method for Third Structure Example of Through-Silicon Via>

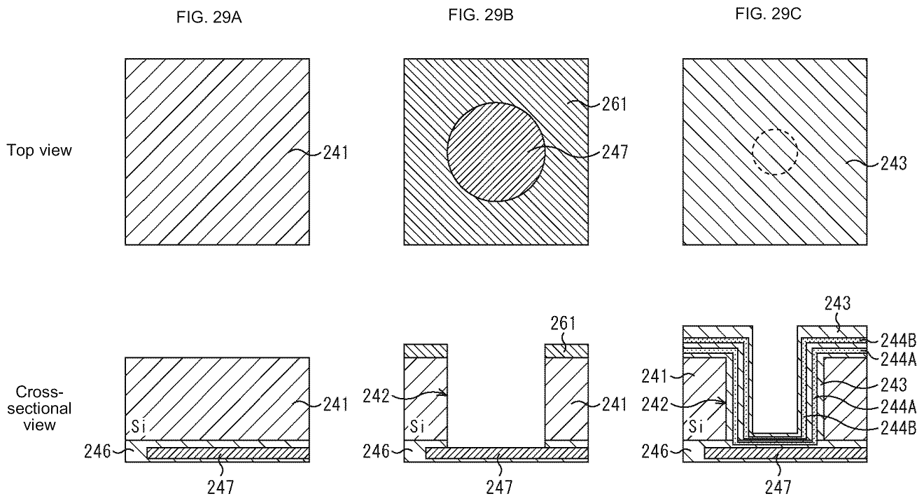

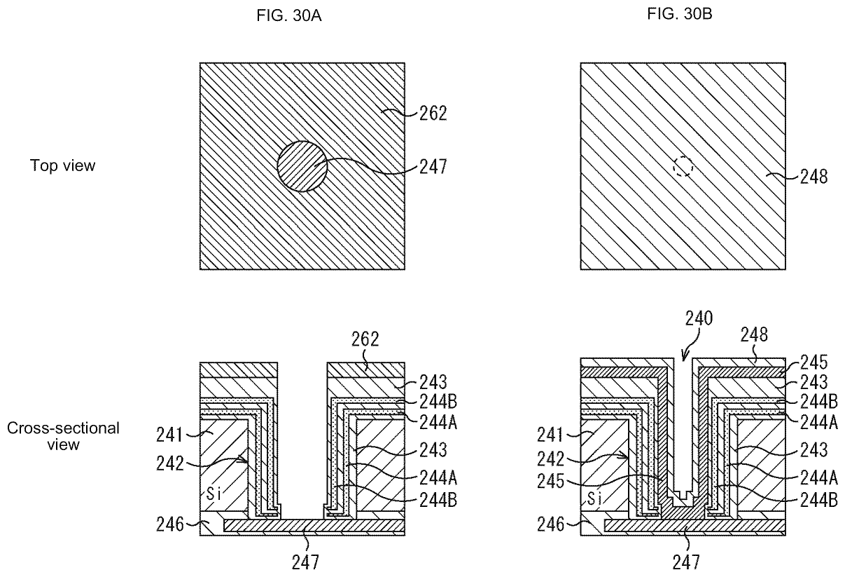

A manufacturing method for the through-silicon-via 240 according to the third structure example shown in FIG. 26 will be described with reference to FIGS. 29 and 30. The description will be given showing, in FIGS. 29 and 30, plan views on the upper surface side of the silicon substrate 241 which is the connection surface with the external substrate and cross-sectional views when cut perpendicular to the plane direction of the silicon substrate 241.

First of all, as shown in A of FIG. 29, the multi-layer wiring layer (multi-layer wiring layer 82 in FIG. 5) including the interlayer insulation film 246 and the wiring layer 247 is formed on the side of the pixel sensor substrate 12 (FIG. 5) of the silicon substrate 241.

Next, as shown in B of FIG. 29, a photoresist 261 is patterned on the silicon substrate 241 which is a surface on a side opposite to the side on which the multi-layer wiring layer of the silicon substrate 241 is formed. The photoresist 261 is patterned so that the position for forming the silicon through-hole 242 is opened. Then, the silicon substrate 241 corresponding to an opening region of the photoresist 261 is removed by dry etching. As a result, the silicon through-hole 242 is formed.

Next, the photoresist 261 is removed by wet treatment or ashing treatment, and then as shown in C of FIG. 29, the insulation film 243, the buffer layer 244A, the insulation film 243, the buffer layer 244B, and the insulation film 243 are formed in the stated order on the entire upper surface of the silicon substrate 241 including a bottom surface and a side wall of the silicon through-hole 242. The insulation films 243 can be, for example, an SiO₂ film, an SiN film, an SiON film, or the like as described above. The buffer layers 244A and 244B are formed of a material with a Young's modulus E lower than that of the insulation films 243, such as Ti, Al, Mg, Sn, Al alloy, or Mg alloy. Moreover, the buffer layers 244A and 244B may be formed of an organic material including an epoxy resin and BCB resin.

Next, as shown in A of FIG. 30, a photoresist 262 is patterned on the insulation films 243 on the upper surface of the silicon substrate 241, the insulation films 243 and the buffer layers 244 on the bottom surface of the silicon through-hole 242 are etched, corresponding to an opening region of the photoresist 262, and the wiring layer 247 closest to the silicon substrate 241 is exposed. Then, the photoresist 262 is removed.

Next, the connection electrical conductor 245 is formed of copper (Cu) as shown in B of FIG. 30 by the formation step for the barrier metal film and the Cu seed layer, the formation step for the connection electrical conductor 245 by electroplating, and the removal step for the barrier metal film and the Cu seed layer in an unnecessary portion as described in B of FIG. 10 to C of FIG. 11. Then, the insulation film 248 is further formed on an upper surface of the connection electrical conductor 245. The through-silicon-via 240 shown in FIG. 26 is thus completed.

It should be noted that in the above-mentioned configuration of the through-silicon-via 240, the insulation film 243, the buffer layer 244, the connection electrical conductor 245, and the insulation film 248 are formed in order on the side wall of the silicon through-hole 242, and no predetermined material is embedded in the central portion of the silicon through-hole 242, such that the silicon through-hole 242 has a cavity.

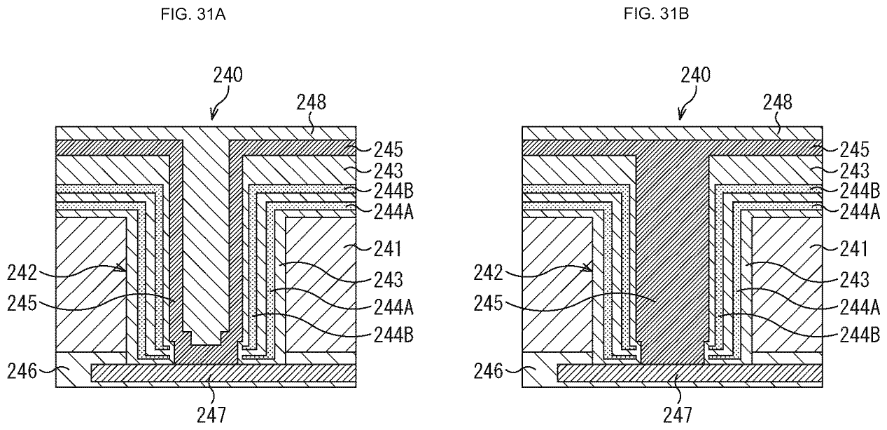

However, for example, a structure in which the insulation film 248 is embedded in the central portion of the silicon through-hole 242 as in A of FIG. 31 or a structure in which the connection electrical conductor 245 is embedded in the central portion of the silicon through-hole 242 as in B of FIG. 31 may be employed. The cavity structure shown in FIG. 26, the structure in which the insulation film 248 is embedded in A of FIG. 31 and the structure in which the connection electrical conductor 245 is embedded in B of FIG. 31 may be selected and employed as appropriate, for example, depending on the inner diameter of the silicon through-hole 242.

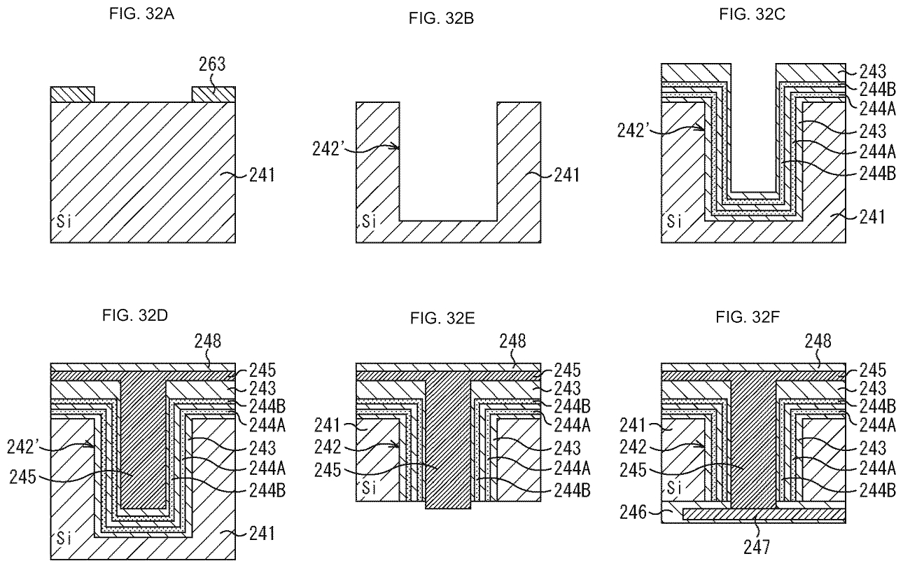

Next, another manufacturing method for the through-silicon-via 240 according to the third structure example shown in FIG. 26 will be described with reference to FIG. 32.

First of all, a photoresist 263 is patterned on one surface of the silicon substrate 241 in A of FIG. 32.

Next, as shown in B of FIG. 32, the silicon substrate 241 is etched at a predetermined depth, corresponding to an opening region of the photoresist 263. As a result, a trench 242′ which becomes the silicon through-hole 242 thereafter is formed. Then, the photoresist 263 is removed by wet treatment or ashing treatment.

Next, as shown in C of FIG. 32, the insulation film 243, the buffer layer 244A, the insulation film 243, the buffer layer 244B, and the insulation film 243 are formed in the stated order on the entire upper surface of the silicon substrate 241 including a bottom surface and a side wall of the trench 242′. The insulation films 243 can be, for example, an SiO₂ film, an SiN film, an SiON film, or the like as described above. The buffer layers 244A and 244B are formed of a material with a Young's modulus E lower than that of the insulation films 243, such as Ti, Al, Mg, Sn, Al alloy, or Mg alloy. Moreover, the buffer layers 244A and 244B may be formed of an organic material including an epoxy resin and BCB resin.

Next, as shown in D of FIG. 32, for example, using a damascene process and the like, copper (Cu) is embedded in the opening portion of the trench 242′ to be the connection electrical conductor 245 and the connection electrical conductor 245 is also formed on the insulation films 243 on the upper surface of the silicon substrate 241. The connection electrical conductor 245 is formed, and then the insulation film 248 is formed and the upper surface of the connection electrical conductor 245 is covered with the insulation film 248.

Next, as shown in E of FIG. 32, the silicon substrate 241 is thinned from a side opposite to the surface on which the insulation film 248 is formed. The silicon substrate 241 is thinned until the connection electrical conductor 245 embedded in the trench 242′ is exposed at a predetermined height (thickness). Moreover, due to the thinning, the trench 242′ becomes the silicon through-hole 242 penetrating the silicon substrate 241.

Last of all, as shown in F of FIG. 32, the interlayer insulation film 246 and the wiring layer 247 are formed on a lower surface of the silicon substrate 241 where the connection electrical conductor 245 is exposed. The through-silicon-via 240 is thus completed.

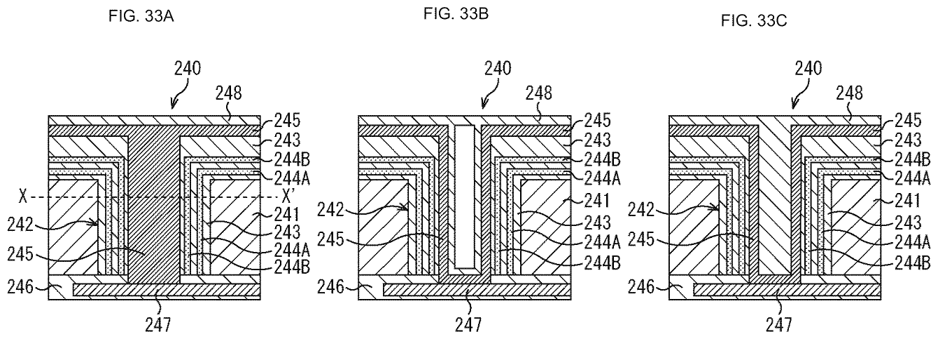

In accordance with the manufacturing method described above with reference to FIG. 32, as in A of FIG. 33, a structure in which the central portion of the silicon through-hole 242 is embedded with the connection electrical conductor 245. However, a structure in which the central portion of the silicon through-hole 242 has a cavity as in B of FIG. 31 or embedded with the insulation film 248 as in C of FIG. 31 may be employed. In a case where the central portion of the silicon through-hole 242 is hollow, the upper portion may be closed with the insulation film 248 as in B of FIG. 33 or the upper portion does not need to be closed as in the through-silicon-via 240 according to the third structure example first shown in FIG. 26.

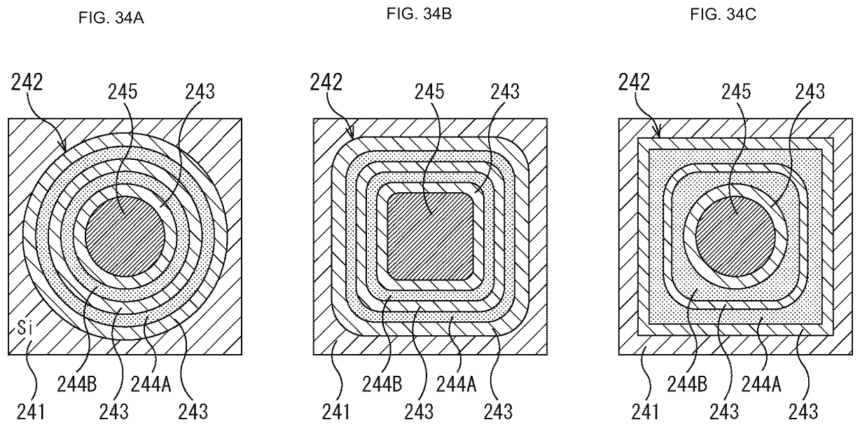

The plan view of the through-silicon-via 240 when viewed at the line X-X′ in A of FIG. 33 can take a shape in A to C of FIG. 34.

In the plan view in A of FIG. 34, the silicon through-hole 242 of the through-silicon-via 240 is formed in a circular plane shape and the insulation film 243, the buffer layer 244A, the insulation film 243, the buffer layer 244B, the insulation film 243, and the connection electrical conductor 245 formed in order inside it are also formed in a circular plane shape.

In the plan view in B of FIG. 34, the silicon through-hole 242 of the through-silicon-via 240 is formed in a rectangular plane shape with rounded corner portions and each layer formed inside it is also formed in a rectangular plane shape with rounded corner portions.

In the plan view in C of FIG. 34, the insulation film 243, the buffer layer 244, and the connection electrical conductor 245 are formed in the plane shape combining the circular plane shape with the rectangular plane shape. Specifically, the insulation film 243, the buffer layer 244A, the insulation film 243, and the buffer layer 244B are formed in a rectangular plane shape from the side of the silicon substrate 241 and the insulation film 243 inside the buffer layer 244B and the connection electrical conductor 245 are formed in a circular plane shape.

### <Number of Stacks of Buffer Layer 244>

In the above-mentioned example, as to the through-silicon-via 240 according to the third structure example, the configuration in which the two buffer layers 244 including the buffer layer 244A and the buffer layer 244B are stacked via the insulation films 243 has been described.

However, the number of buffer layers 244 included in the through-silicon-via 240 according to the third structure example is not limited to two, and it is sufficient that the through-silicon-via 240 includes at least one buffer layer 244 between the silicon substrate 241 and the connection electrical conductor 245 on the side wall of the silicon through-hole 242.

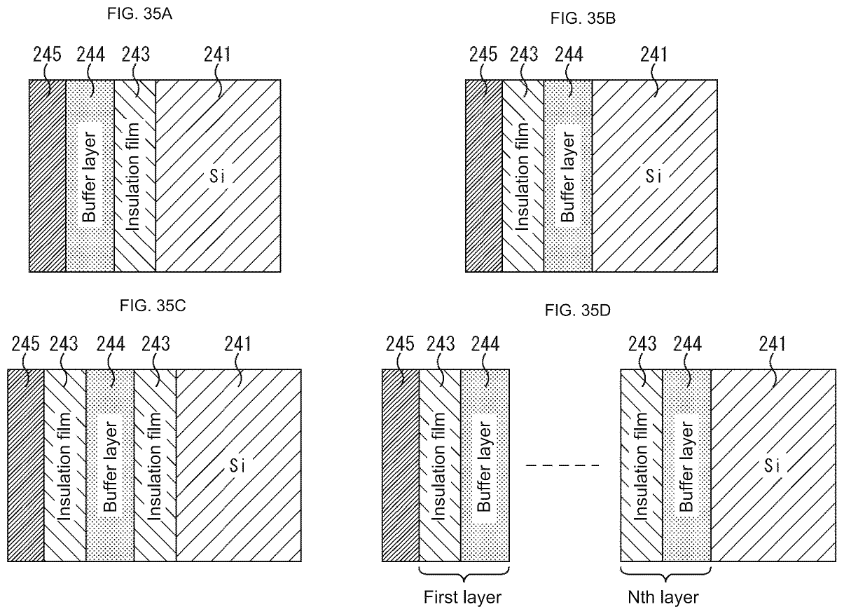

FIG. 35 is cross-sectional views showing a configuration example between the silicon substrate 241 and the connection electrical conductor 245 in the same position of the line X-X′ shown in FIG. 26.

In a case where the number of buffer layers 244 included in the through-silicon-via 240 is one and the buffer layer 244 is insulative as in the above-mentioned organic film, the area between the silicon substrate 241 and the connection electrical conductor 245 can be constituted by one buffer layer 244 and one insulation film 243 as in A or B of FIG. 35. The stacking order of the one buffer layer 244 and the one insulation film 243 may be as in either A or B of FIG. 35.

On the other hand, in a case where the number of buffer layers 244 included in the through-silicon-via 240 is one and the buffer layer 244 is constituted by a metal film, the one buffer layer 244 is arranged between the silicon substrate 241 and the connection electrical conductor 245 so that the insulation films 243 sandwich both sides of the one buffer layer 244 as in C of FIG. 35.

In a case where the number of buffer layers 244 included in the through-silicon-via 240 is N (N>1), N-pairs of the insulation film 243 and the buffer layer 244 are repeatedly arranged between the silicon substrate 241 and the connection electrical conductor 245 as shown in D of FIG. 35.

### <10. Summary of Third Structure Example of Through-Silicon Via>

As described above, the through-silicon-via 240 according to the third structure example includes, on the side wall of the silicon through-hole 202 formed on the silicon substrate 201, at least one insulation film 243 and the buffer layer 244 formed of a material with a Young's modulus E lower than that of the insulation films 243. Accordingly, the stress applied to the insulation films 243 can be reduced. Moreover, by reducing the film stress of the insulation films 243 in the silicon through-hole 242, cracking and film peeling of the insulation films 243 can be prevented.

### (Combinations According to First to Third Structure Examples)

One or more buffer layers 244 of the through-silicon-via 240 according to the above-mentioned third structure example may be further added to the structure of the through-silicon-via 120 according to the above-mentioned first structure example or the structure of the through-silicon-via 200 according to the above-mentioned second structure example. For example, it is possible to employ a configuration in which one or more buffer layers 244 are further added between the connection electrical conductor 124 and the silicon substrate 121 with a plurality of thicknesses formed on the side wall of the silicon through-hole 122 in FIG. 7. Alternatively, it is possible to employ a configuration in which one or more buffer layers 244 are further added between the connection electrical conductor 204 of the through-silicon-via 200 in FIG. 21 on which the stress suppression film 205 is formed and the silicon substrate 201.

### <11. Fourth Structure Example of Through-Silicon Via>

Next, a fourth structure example of the through-silicon-via that enables reduction of the film stress will be described.

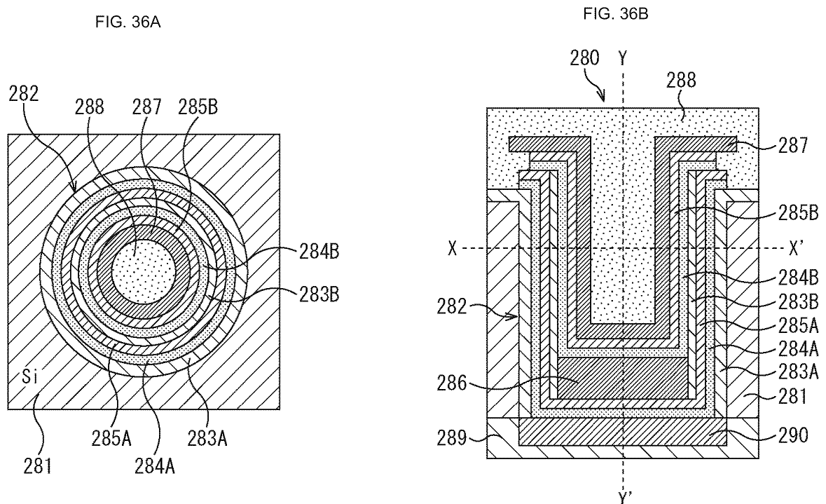

FIG. 36 is views showing the fourth structure example of the through-silicon-via.

B of FIG. 36 shows a cross-sectional view of a through-silicon-via 280 which is the fourth structure example of the through-silicon-via and A of FIG. 36 shows a plan view of the through-silicon-via 280 along the line X-X′ in B of FIG. 36.

This through-silicon-via 280 has a configuration in which double stacks of an insulation film 283, a barrier metal film 284, and a Cu seed layer 285 are arranged between a connection electrical conductor 287 on a side wall of a silicon through-hole 282 formed on a silicon substrate 281 and the silicon substrate 281. Hereinafter, it will be described specifically.

The through-silicon-via 280 includes the silicon through-hole 282 penetrating the silicon substrate 281 and an insulation film 283A, a barrier metal film 284A, a Cu seed layer 285A, an insulation film 283B, a barrier metal film 284B, a Cu seed layer 285B, and the connection electrical conductor 287 are formed in the stated order toward an inside central portion from a side wall of the silicon through-hole 282 along the line X-X′. Moreover, filling with a solder mask 288 is performed so that the cavity inside the silicon through-hole 282 in which the barrier metal films 284, the Cu seed layers 285, the connection electrical conductor 287, are the like are formed is embedded. The insulation film 283 is, for example, constituted by an SiN film, an SiO₂ film, an SiON film, or the like. Tantalum (Ta), titanium (Ti), tungsten (W), zirconium (Zr), a nitride film or carbon film thereof, or the like can be used as the barrier metal film 284. In the fourth structure example, titanium is used as the barrier metal film. The Cu seed layer 285 and the connection electrical conductor 287 are, for example, formed with copper (Cu).

On the other hand, the barrier metal film 284A, the Cu seed layer 285A, an electrical conductor 286, the barrier metal film 284B, the Cu seed layer 285B, the connection electrical conductor 287, and the solder mask 288 are formed in the stated order when the stack in the substrate thickness direction in the silicon through-hole 282 is viewed in order from the side of a wiring layer 290 along the line Y-Y′ which is the plane center of the silicon through-hole 282. The barrier metal film 284A on a bottom portion of the silicon through-hole 282 is connected to the wiring layer 290 in an interlayer insulation film 289 formed on a lower surface of the silicon substrate 281 which is the lower side in B of FIG. 36. The connection electrical conductor 287 formed on the uppermost surface of the silicon substrate 281 is connected to the wiring layer 290 via the Cu seed layer 285B, the barrier metal film 284B, the electrical conductor 286, the Cu seed layer 285A, and the barrier metal film 284A, thereby electrically connecting a lower surface side and an upper surface side of the silicon substrate 281. Copper (Cu) which is the same material as the connection electrical conductor 287 is also formed on the electrical conductor 286.

The electrical conductor 286 is formed to be thicker than all other films formed inside the silicon through-hole 282. For example, the film thickness of the barrier metal film 284 is, for example, approximately 250 to 400 nm and the film thickness of the Cu seed layer 285 is nm order, for example, approximately 500 to 800 nm. Meanwhile, the film thickness of the electrical conductor 286 is μm order, for example, approximately 10 to 20 μm.

In the fourth structure example, the plane shape of the silicon through-hole 282 is a circular shape as in the plan view in A of FIG. 36. However, as described above with reference to A to C of FIG. 27 in the third structure example, the plane shape combining the rectangular shape (including the rectangular shape with rounded corner portions) or the rectangular shape with the circular shape may be employed.

The through-silicon-via 280 in FIG. 36 can be arranged in the solid-state image pickup apparatus 1 in place of the through-silicon-via 88 in FIG. 5 or 6 described above. The silicon substrate 281 corresponds to the silicon substrate 81 in FIG. 5 and the wiring layer 290 corresponds to the wiring layer 83c in FIG. 5. The connection electrical conductor 287 formed on the upper surface side of the silicon substrate 281 which is the upper side in FIG. 36 also serves as the rewiring 90 in FIG. 5 and, for example, the solder ball 14 (FIG. 5 or 6) is formed on the connection electrical conductor 287 on which the solder mask 288 is not formed.

As to the through-silicon-via 280 according to the fourth structure example configured in the above-mentioned manner, two sets of the three layers including the insulation film 283, the barrier metal film 284, and the Cu seed layer 285 are arranged on a side wall surface of the silicon through-hole 282 and it includes the electrical conductor 286 between the barrier metal film 284A and the Cu seed layer 285A and the barrier metal film 284B and the Cu seed layer 285B on the bottom portion of the silicon through-hole 282. This electrical conductor 286 is arranged, formed to be thicker than all other films formed in the silicon through-hole 282.

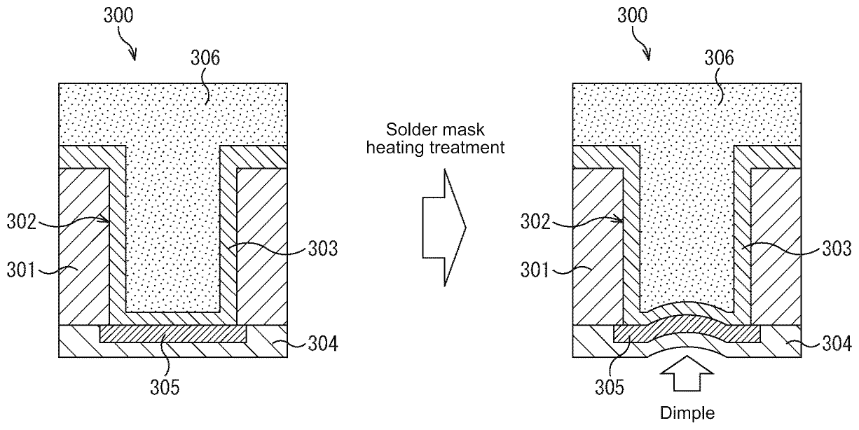

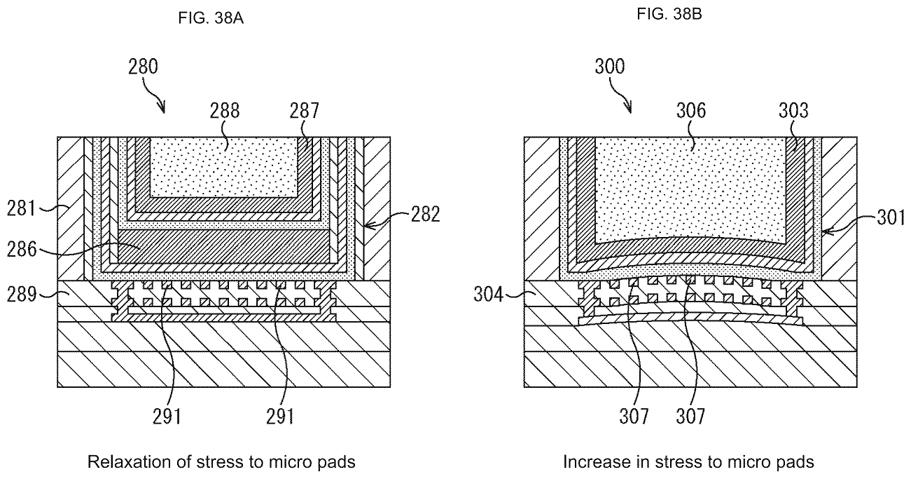

Effects of the through-silicon-via 280 according to the fourth structure example will be described with reference to FIGS. 37 and 38.

FIG. 37 is a view showing by simplifying a cross-sectional structure of a generally-used through-silicon-via 300.

The through-silicon-via 300 often takes a mode on which a connection electrical conductor 303 is formed on a side wall and a bottom portion of a silicon through-hole 302 formed on a silicon substrate 301, and then the cavity inside the silicon through-hole 302 is embedded with a solder mask 306. The solder mask 306 is constituted by a thermo-setting resist material, embedded in the cavity inside the through-hole, and then heated. After the heating treatment of the solder mask 306, due to the stress of the solder mask 306, a local distortion (dimple) may be generated in the connection electrical conductor 303 on the bottom portion of the silicon through-hole 302 as shown on the right side in FIG. 37. Such a local distortion causes a spot defect.

In contrast, as described above with reference to FIG. 36, in the through-silicon-via 280 according to the fourth structure example, the electrical conductor 286 is arranged, formed to be thicker than all other films on the bottom portion of the silicon through-hole 282. This electrical conductor 286 corresponds to one obtained by thickening a bottom portion of the connection electrical conductor 303 formed on the side wall and a bottom portion of the silicon through-hole 302 in FIG. 37. By providing the thickened electrical conductor 286, deformation of the electrical conductor 286 itself is suppressed. Moreover, by disposing the thickened electrical conductor 286 on the bottom portion of the silicon through-hole 282, the capacity inside the silicon through-hole 282 is reduced, and thus the volume of the solder mask 288 that enters it decreases. As a result, the stress of the solder mask 288 applied to the bottom portion of the silicon through-hole 282 decreases, and deformation (dimple) of the wiring layer 290 in the interlayer insulation film 289 formed on the lower surface of the silicon substrate 281 can be suppressed.

Moreover, it can be considered that configuring the insulation film to have the double structure of the insulation film 283A and the insulation film 283B enables the inside insulation film 283B to serve to reduce the stress applied to the outside insulation film 283A. A film capable of reducing the stress may be used as the inside insulation film 283B in consideration of the thermal expansion coefficient.

The through-silicon-via 280 can also take a structure in which it is connected to a plurality of micro pads 291 as shown in A of FIG. 38, not the mode on which it is directly connected to the single wiring layer 290 in the interlayer insulation film 289 as shown in B of FIG. 36. In such a case, in the structure of the through-silicon-via 300 shown in FIG. 37, the stress to a plurality of micro pads 307 also increases in accordance with deformation of the bottom portion of the connection electrical conductor 303 as shown in B of FIG. 38.

In contrast, in accordance with the through-silicon-via 280 according to the fourth structure example, by providing the thickened electrical conductor 286, deformation of the electrical conductor 286 is suppressed, and thus the stress to the plurality of micro pads 291 in the interlayer insulation film 289 can be alleviated.

### <Manufacturing Method for Fourth Structure Example of Through-Silicon Via>

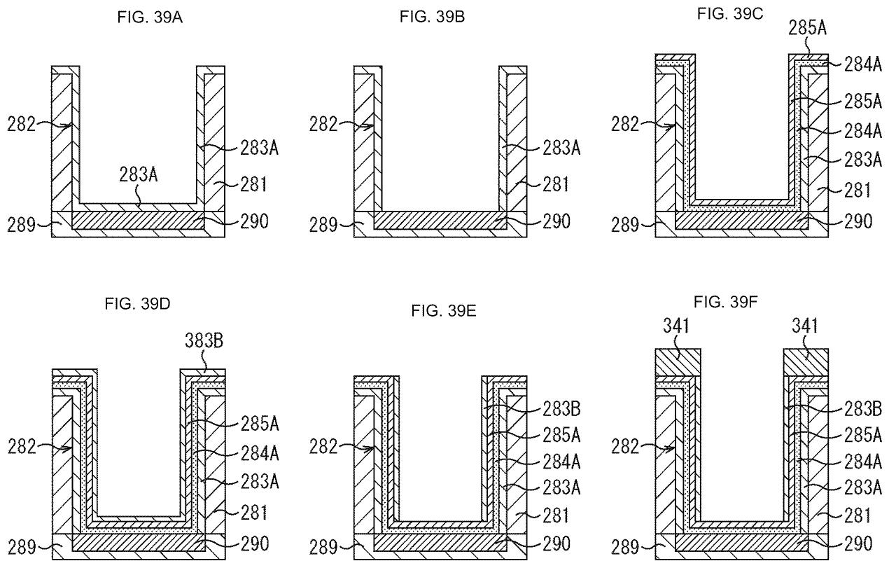

A manufacturing method for the through-silicon-via 280 according to the fourth structure example will be described with reference to FIGS. 39 to 41.

First of all, as shown in A of FIG. 39, the silicon through-hole 282 is formed at a position of the silicon substrate 281, which corresponds to the wiring layer 290, and the insulation film 283A is deposited by, for example, plasma CVD on an entire upper surface of the silicon substrate 281 including the bottom portion and the side wall of the silicon through-hole 282. The insulation film 283A can be, for example, formed of an SiON film, an SiO₂ film, an SiN film, or the like. The thickness of the silicon substrate 281 (depth of the silicon through-hole 282) is, for example, approximately 70 to 100 μm. The film thickness of an insulation film 293A on the upper surface of the silicon substrate 281 is desirably approximately 5 to 10 μm.

Next, as shown in B of FIG. 39, the insulation film 283A on a bottom surface of the silicon through-hole 282 is removed by etching back. As a result, the wiring layer 290 closest to the silicon substrate 281 is exposed.

Next, as shown in C of FIG. 39, the barrier metal film 284A and the Cu seed layer 285A are sequentially formed on the bottom portion and the side wall of the silicon through-hole 282 and the upper surface of the silicon substrate 281. The film thickness of the barrier metal film 284A is, for example, approximately 250 to 400 nm and the film thickness of the Cu seed layer 285A is controlled to be approximately 500 to 800 nm.

Next, as shown in D of FIG. 39, the insulation film 283B is deposited by, for example, plasma CVD on a further upper surface of the barrier metal film 284A and the Cu seed layer 285A. This insulation film 283B is partially removed in the next step. Therefore, the insulation film 283B may be formed to be thinner than the insulation film 283A deposited in A of FIG. 39 and is, for example, approximately 3 to 5 μm.

Next, the insulation film 283B is removed by an entire-surface etch back step. As shown in E of FIG. 39, the insulation film 283B on a bottom surface portion of the silicon through-hole 282 and an upper surface portion of the silicon substrate 281 is removed by anisotropic dry etching. However, the insulation film 283B on the side wall portion of the silicon through-hole 282 remains.

Next, as shown in F of FIG. 39, a photoresist 341 is patterned on a further upper surface of the Cu seed layer 285A on the upper surface of the silicon substrate 281.

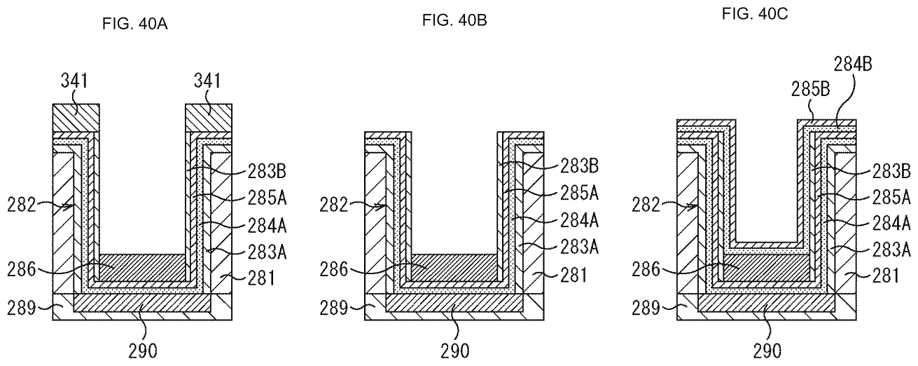

Next, copper (Cu) is plated by electrolytic plating using the Cu seed layer 285A as an electrode as shown in A of FIG. 40. As a result, the electrical conductor 286 is formed in a predetermined thickness. The film thickness of the electrical conductor 286 is, for example, approximately 10 to 20 μm. The electrical conductor 286 is formed by plating, and then the photoresist 341 is removed by wet treatment or ashing treatment as shown in B of FIG. 40.

Next, as shown in C of FIG. 40, the barrier metal film 284B and the Cu seed layer 285B are sequentially formed on the bottom portion and the side wall of the silicon through-hole 282 and the upper surface of the silicon substrate 281. The film thickness of the barrier metal film 284B and the Cu seed layer 285B may be similar to the barrier metal film 284A and the Cu seed layer 285A.

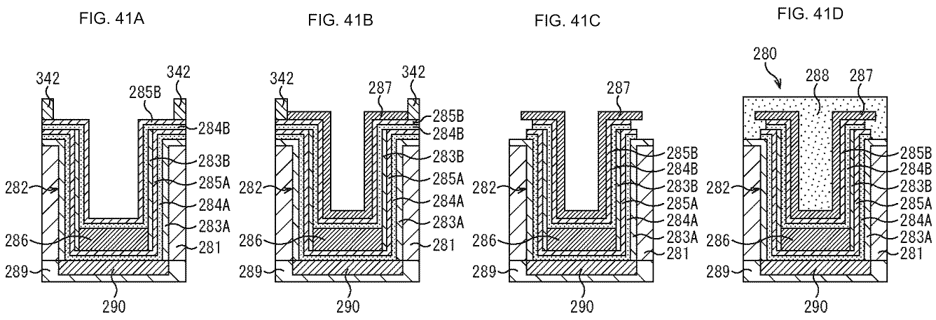

Next, as shown in A of FIG. 41, a photoresist 342 is formed in a desired region on the Cu seed layer 285B, and as shown in B of FIG. 41, copper (Cu) is plated by electrolytic plating using the Cu seed layer 285B as an electrode. As a result, the connection electrical conductor 287 is obtained. The film thickness of the connection electrical conductor 287 is, for example, approximately 1.5 to 3.5 μm in consideration of electric resistance.

Next, as shown in C of FIG. 41, the photoresist 342 is removed by wet treatment or ashing treatment, and then the Cu seed layer 285B, the barrier metal film 284B, the Cu seed layer 285A, and the barrier metal film 284A below the photoresist 342 are sequentially removed. Last of all, as shown in D of FIG. 41, the solder mask 288 is applied on the upper surface of the silicon substrate 281 and is also embedded in the cavity inside the silicon through-hole 282. The solder mask 288 is cured by the heating step and the through-silicon-via 280 in FIG. 36 is completed.

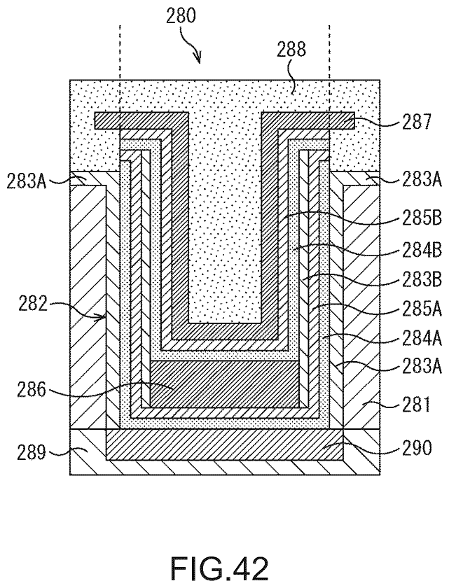

It should be noted that two sets of the barrier metal film 284A, the Cu seed layer 285A, the barrier metal film 284B, and the Cu seed layer 285B formed may be configured to not be formed on the insulation film 283A on the upper surface of the silicon substrate 281 as shown in FIG. 42. By configuring the double barrier metal films 284 and Cu seed layers 285 to not be formed on the upper surface of the silicon substrate 281, the stress of the Cu seed layers 285 and the connection electrical conductor 287, which is applied to the corner portions of the silicon substrate 281, can be suppressed.

In accordance with the through-silicon-via 280, even if cracking or film peeling occurs in the insulation film 283B due to the stress of the insulation film 283B, the structure in which it is joined with the barrier metal film 284A and the Cu seed layer 285A below it and the barrier metal film 284B and the Cu seed layer 285B above it. Therefore, cracking or film peeling in the insulation films 283 causes no problem.

### <Modified Example of Fourth Structure Example of Through-Silicon Via>

The through-silicon-via 280 according to the above-mentioned fourth structure example is configured in such a manner that the electrical conductor 286 formed to be thicker is arranged on the bottom portion of the silicon through-hole 282 and two sets of the insulation film 283, the barrier metal film 284, and the Cu seed layer 285 are formed.

As a premise, the through-silicon-via 280 includes the connection electrical conductor 287 that electrically connects the upper surface and the lower surface of the silicon substrate 281 to each other. Therefore, the barrier metal films 284 and the Cu seed layers 285 are deposited in the nm order as described above.

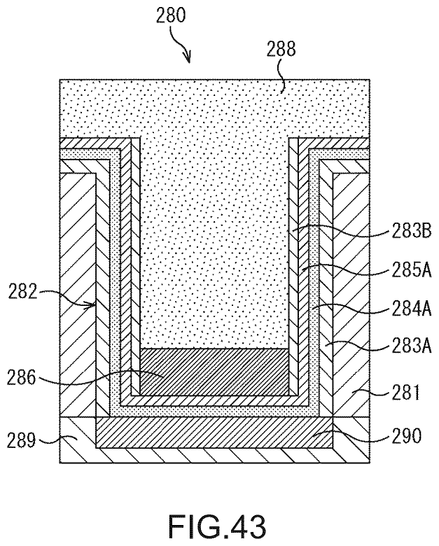

However, in a case where the first barrier metal film 284A and the first Cu seed layer 285A are formed to be thicker, a configuration in which the second barrier metal film 284B and the second Cu seed layer 285B are omitted may be employed as shown in FIG. 43. Also in this case, the structure in which the thickened electrical conductor 286 is arranged on the bottom portion of the silicon through-hole 282, and thus deformation (dimple) of the wiring layer 290 in the interlayer insulation film 289 formed on the lower surface of the silicon substrate 281 can be suppressed.

### <12. Summary of Fourth Structure Example of Through-Silicon Via>

As described above, the through-silicon-via 280 according to the fourth structure example includes the double stacks of the insulation film 283, the barrier metal film 284, and the Cu seed layer 285 on the side wall of the silicon through-hole 282 formed on the silicon substrate 281 and includes the electrical conductor 286 formed to be thickened on the bottom portion of the silicon through-hole 282. The electrical conductor 286 is formed to be thicker than all other films formed in the silicon through-hole 282. The electrical conductor 286 formed to be thicker can reduce the film stress of the solder mask 288 embedded in the silicon through-hole 242, and deformation (dimple) of the connection electrical conductor 287 and the wiring layer 290 in the interlayer insulation film 289 can be suppressed.

### (Combination of First to Fourth Structure Examples)

The thickened electrical conductor 286 of the through-silicon-via 280 according to the above-mentioned fourth structure example may be combined with at least one of the through-silicon-vias 120, 200, and 240 which are the above-mentioned first to third structure examples. Moreover, the structure in which two sets of the insulation film 283, the barrier metal film 284, and the Cu seed layer 285 stacked are formed on the side wall of the silicon through-hole 282 may be combined with at least one of the through-silicon-vias 120, 200, and 240 which are the first to third structure examples. Accordingly, the effect of suppressing deformation of the wiring layer 290 can also be provided in addition to the effects of the first to third structure examples.

<13. Problem during High-Voltage Application on Through-Silicon Via>

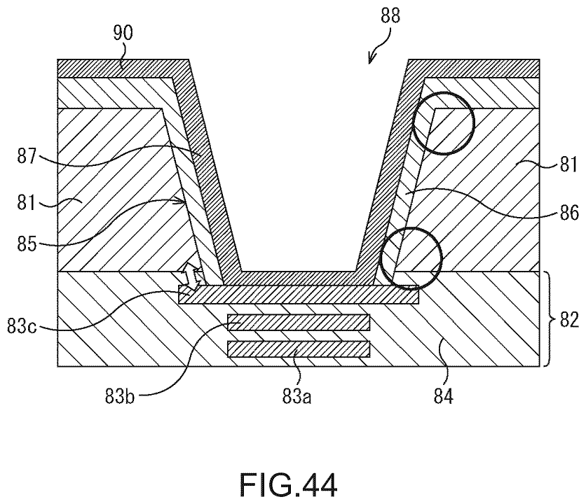

Next, another problem in a case of forming the through-silicon-via will be described with reference to FIG. 44.

FIG. 44 is a cross-sectional view of the portion of the through-silicon-via 88 in FIG. 5 or 6.

The through-silicon-via 88 formed on the logic substrate 11 of the solid-state image pickup apparatus 1, for example, functions as an electrode which is connected to the solder ball 14 as an input terminal and takes an externally supplied predetermined power supply voltage in the apparatus.

To give the through-silicon-via 88 a margin in position deviation when forming the through-via, the plane area of the wiring layer 83c in the multi-layer wiring layer 82 may be formed to be larger than the plane area of the silicon through-hole 85. When the region of the wiring layer 83c departing from the silicon through-hole 85 is referred to as an extension region, as shown in the double-sided thick arrow in FIG. 44, the distance between the extension region of the wiring layer 83c and the silicon substrate 81 is short, and a leak path may be formed between the wiring layer 83c and the silicon substrate 81 and the insulation may lower.

Moreover, for example, in a case where a predetermined voltage, in particular, a high voltage is applied on the through-silicon-via 88, the electric field concentrates at the corner portions of the upper portion and the lower portion of the silicon substrate 81 shown in the circle marks in FIG. 44, and thus a significantly higher voltage than an actual application voltage is applied. As a result, the corner portions are easily broken.

Hereinafter, a structure of the through-silicon-via with a withstand voltage improved by suppressing the leak between the wiring layer 83c and the silicon substrate 81 and the concentration of the electric field at the corner portions of the silicon substrate 81 will be described.

### <14. Fifth Structure Example of Through-Silicon Via>

Next, the fifth structure example of the through-silicon-via with the withstand voltage improved will be described.

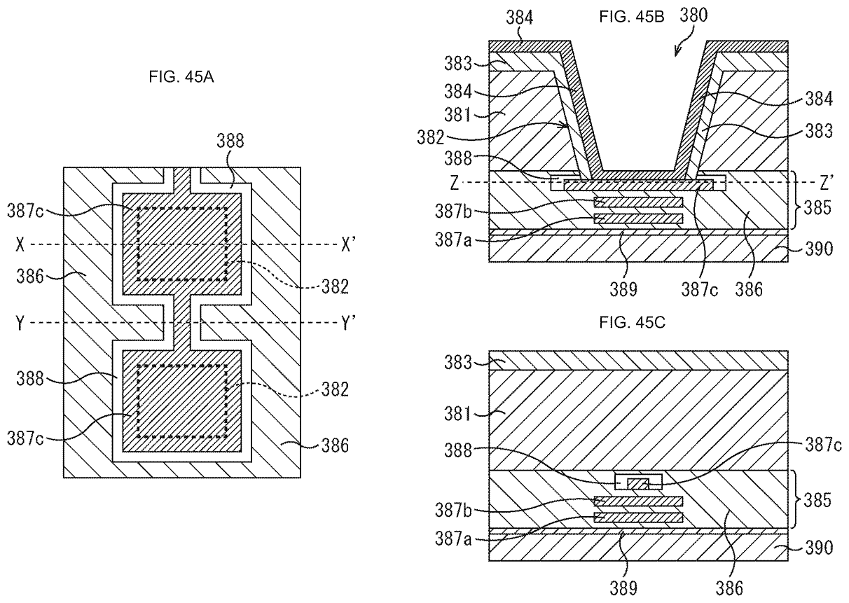

FIG. 45 is views showing the fifth structure example of the through-silicon-via.

B of FIG. 45 is a cross-sectional view of a through-silicon-via 380 which is the fifth structure example of the through-silicon-via. C of FIG. 45 is a cross-sectional view of the region in which the through-silicon-via 380 is not formed.

A of FIG. 45 is a plan view of a wiring layer 387c to which the through-silicon-via 380 is electrically connected.

The cross-sectional view in B of FIG. 45 is a cross-sectional view taken along the line X-X′ in A of FIG. 45. The cross-sectional view in C of FIG. 45 is a cross-sectional view taken along the line Y-Y′ in A of FIG. 45. The plan view in A of FIG. 45 is a plan view taken along the Z-Z′ in B of FIG. 45.

As shown in B of FIG. 45, the through-silicon-via 380 includes a connection electrical conductor 384 penetrating a silicon substrate 381. The connection electrical conductor 384 is formed on a side wall (inner wall) of a silicon through-hole 382 formed on the silicon substrate 381 via an insulation film 383 and an upper surface of the silicon substrate 381. In other words, the through-silicon-via 380 is constituted by the insulation film 383 formed on the upper surface of the silicon substrate 381 and a side wall of the silicon through-hole 382 and the connection electrical conductor 384 formed on its upper surface.

The connection electrical conductor 384 is connected to the wiring layer 387c formed in a multi-layer wiring layer 385 on a lower surface side of the silicon substrate 381 which is the lower side in B of FIG. 45. In this manner, the lower surface side and an upper surface side of the silicon substrate 381 are electrically connected to each other.

The multi-layer wiring layer 385 includes three wiring layers 387 including wiring layers 387a to 387c and an interlayer insulation film 386 formed therebetween. The interlayer insulation film 386 can be, for example, formed of an SiON film, an SiO₂ film, an SiN film, an SiCN film, or the like. The three wiring layers 387 are, for example, formed with copper (Cu), aluminum (Al), tungsten (W), or the like. The wiring layer 387c closest to the silicon substrate 381 out of the three wiring layers 387 is connected to the connection electrical conductor 384 on the upper surface on the side of the silicon substrate 381. Moreover, an air gap 388 is formed on side surfaces of the wiring layer 387c at end portions in the plane direction and an upper surface of the wiring layer 387c on the side of the silicon substrate 381, which are outside the connection surface with the connection electrical conductor 384 inside the multi-layer wiring layer 385.

The multi-layer wiring layer 385 is connected to the silicon substrate 381 on the upper side in B of FIG. 45 and is connected to a second silicon substrate 390 via an insulation film 389 on the lower side in FIG. 45. The second silicon substrate 390 is a substrate corresponding to the silicon substrate 101 in the stack structure in FIG. 5 or 6 of the solid-state image pickup apparatus 1, and for example, the photodiode 51 or the like is formed. The insulation film 389 can be, for example, formed of an SiON film, an SiO₂ film, an SiN film, an SiCN film, or the like and may be formed of the same material as the interlayer insulation film 386 or may be formed of a different material from that of the interlayer insulation film 386.

As shown as the broken line in the plan view in A of FIG. 45, the silicon through-hole 382 is formed for example in a rectangular plane shape and the wiring layer 387c is formed in a rectangular plane shape with a plane area larger than a plane size of the silicon through-hole 382. It should be noted that the plane shape of the silicon through-hole 382 is not limited to the rectangular shape, and may be a circular or elliptical shape, a rectangular shape with rounded corner portions, or the like as in A to C of FIG. 27 shown in the third structure example.

As also shown in the plan view in A of FIG. 45, the air gap 388 is also arranged in the periphery of the wiring layer 387c.

The plan view in A of FIG. 45 shows a state in which a plurality of through-silicon-vias 380 is arranged side by side in the plane direction and the wiring layer 387c connected to the connection electrical conductor 384 of the through-silicon-via 380 is arranged corresponding to each through-silicon-via 380. The plurality of through-silicon-vias 380 arranged is, for example, electrodes for taking an externally supplied predetermined power supply voltage in the apparatus, and the wiring layers 387c respectively connected to the through-silicon-vias 380 are connected to each other through the wiring layer 387c with a smaller wire width. The cross-sectional view in C of FIG. 45 is a cross-sectional view of the smaller wire width portion of the wiring layer 387c, corresponding to the line Y-Y′ in A of FIG. 45.

The through-silicon-via 380 in FIG. 45 can be arranged in the solid-state image pickup apparatus 1 in place of the through-silicon-via 88 in FIG. 5 or 6 described above. The silicon substrate 381 in B of FIG. 45 corresponds to the silicon substrate 81 in FIG. 5 and the wiring layer 387c corresponds to the wiring layer 83c in FIG. 5. The connection electrical conductor 384 formed on the upper surface side of the silicon substrate 381 which is the upper side in B of FIG. 45 also serves as the rewiring 90 in FIG. 5 and, for example, the solder ball 14 (FIG. 5 or 6) is formed on the connection electrical conductor 384. As in the insulation film 86 in FIG. 5, the insulation film 383 can be, for example, formed of an SiON film, an SiO₂ film, an SiN film, or the like. The connection electrical conductor 384 can be, for example, formed of copper (Cu), tungsten (W), titanium (Ti), tantalum (Ta), titanium tungsten alloy (TiW), nickel (Ni), gold (Au), polysilicon, and the like as in the connection electrical conductor 87 in FIG. 5.

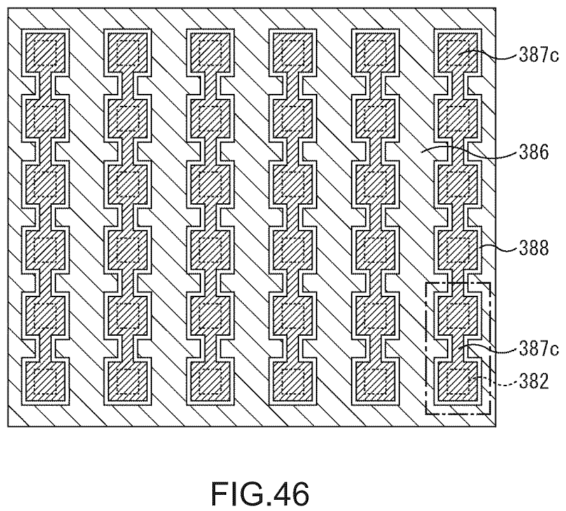

For example, in the solid-state image pickup apparatus 1 in FIG. 1, a plurality of solder balls 14 as input terminals for receiving the supply of a predetermined power supply voltage is arranged side by side in a matrix form at predetermined intervals on the back surface of the solid-state image pickup apparatus 1. In this case, the plurality of through-silicon-vias 380 is also arranged side by side in a matrix form at predetermined intervals on the back surface of the solid-state image pickup apparatus 1. Then, the wiring layer 387c which is the connection surface with the through-silicon-via 380 is arranged as shown in FIG. 46. That is, the wiring layer 387c is configured to have a wiring shape in which connection pads connected to the through-silicon-vias 380 connected to the solder balls 14 are arranged at the predetermined intervals and those connection pads are connected to each other through wirings with a smaller wire width. The region shown as the long dashed short dashed line in FIG. 46 corresponds to the plan view in A of FIG. 45.

It should be noted that although in the example in FIG. 46, an example of the wiring pattern in which one column in the vertical direction is connected is shown as the wiring pattern of the wiring layer 387c, the wiring layer 387c does not necessarily need to be connected to the through-silicon-via 380 next to it, and may be independently arranged for each through-silicon-via 380 or may be connected for each unit of any number of through-silicon-vias 380.

In accordance with the through-silicon-via 380 according to the fifth structure example configured in the above-mentioned manner, the air gap 388 is arranged on upper and lateral sides in vicinity of end surfaces of the wiring layer 387c, which are outside the connection surface between the wiring layer 387c and the connection electrical conductor 384. Since the air gap is generally higher in resistance than an insulation film including an oxide film and a nitride film, the air gap can improve the insulation. By covering the extension region of the wiring layer 387c with the air gap 388, the leak between the silicon substrate 381 and the wiring layer 387c, which is shown in the both thick arrows in FIG. 44, can be suppressed.

### <Manufacturing Method for Fifth Structure Example of Through-Silicon Via>

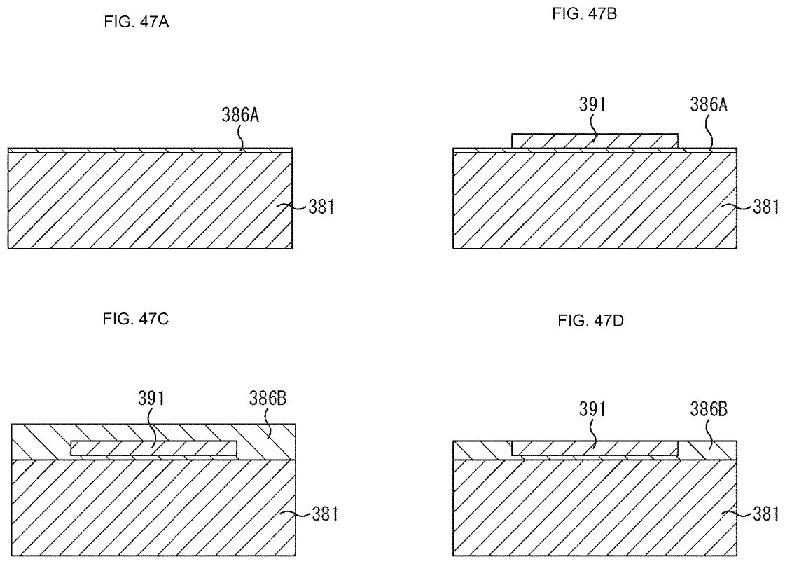

A manufacturing method for the through-silicon-via 380 according to the fifth structure example will be described with reference to FIGS. 47 to 50.

First of all, as shown in A of FIG. 47, an interlayer insulation film 386A is deposited by, for example, plasma CVD on entire one surface of the silicon substrate 381. The interlayer insulation film 386A can be, for example, formed of an SiON film, an SiO₂ film, an SiN film, an SiCN film, or the like.

Next, as shown in B of FIG. 47, a temporarily embedded layer 391 is formed in a predetermined region of an upper surface of the interlayer insulation film 386A. The temporarily embedded layer 391 can be formed of a film different from the interlayer insulation film 386A out of an SiON film, an SiO₂ film, an SiN film, an SiCN film, or the like. Alternatively, the temporarily embedded layer 391 may be formed of a resin film including an applicator. The region in which the temporarily embedded layer 391 is formed corresponds to a portion which becomes the wiring layer 387c and the air gap 388 thereafter.

Next, as shown in C of FIG. 47, an additional interlayer insulation film 386B is formed on the temporarily embedded layer 391 and the upper surface of the interlayer insulation film 386A other than it. The interlayer insulation film 386B in C of FIG. 47 is a layer corresponding to both the interlayer insulation film 386A on a lower surface of the temporarily embedded layer 391 and an interlayer insulation film additionally deposited.

Next, as shown in D of FIG. 47, the interlayer insulation film 386B above the temporarily embedded layer 391 is polished by CMP. As a result, the interlayer insulation film 386B and the temporarily embedded layer 391 are planarized to be the same surface.

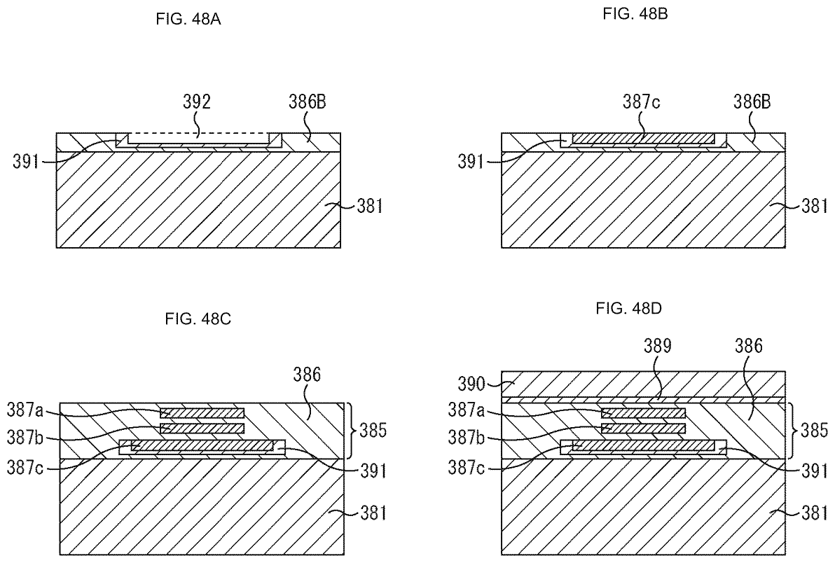

Next, as shown in A of FIG. 48, a depression portion 392 is formed in a partial region of the temporarily embedded layer 391. Specifically, a resist is patterned and etched in a plane region other than a portion which becomes the wiring layer 387c thereafter. As a result, the depression portion 392 is formed. Then, by embedding a predetermined metal material, for example, copper (Cu), aluminum (Al), tungsten (W), or the like, in the formed depression portion 392, the wiring layer 387c is formed as shown in B of FIG. 48. Here, it is assumed that copper which is the same material as the connection electrical conductor 384 is embedded as the wiring layer 387c. The copper can be embedded by, for example, formation of the Cu seed layer by vacuum vapor deposition, sputtering, ion plating, or the like and copper plating using electrolytic plating.

Hereinafter, similarly, by repeating additional film deposition of the interlayer insulation film 386 and formation of the metal film as the wiring layer, the multi-layer wiring layer 385 including the three wiring layers 387 including the wiring layers 387a to 387c and the interlayer insulation film 386 formed therebetween is formed as shown in C of FIG. 48.

Next, as shown in D of FIG. 48, the insulation film 389 is formed on an upper surface of the formed multi-layer wiring layer 385, and then the second silicon substrate 390 is joined by, for example, plasma junction.

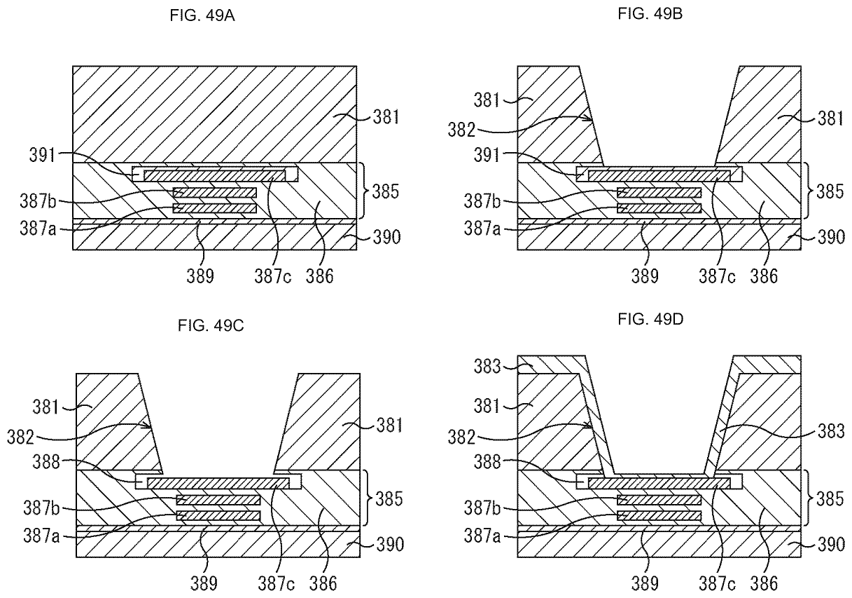

After the junction of the second silicon substrate 390, as in A of FIG. 49, the junction substrate is inverted up and down. Then, as shown in B of FIG. 49, the silicon through-hole 382 is formed from the side of a back surface (in FIG. 49, an upper surface) of the silicon substrate 381. As in the step described above with reference to A to C of FIG. 9, a photoresist is patterned and dry etching is performed, such that the silicon through-hole 382 can be formed.

Next, as shown in C of FIG. 49, the temporarily embedded layer 391 is removed. In a case where the temporarily embedded layer 391 is an insulation film such as an SiON film, an SiO₂ film, an SiN film, an SiCN film, or the like, it can be removed by wet treatment, and in a case where the temporarily embedded layer 391 is a resin film, it can be removed by ashing treatment.

Next, as shown in D of FIG. 49, the insulation film 383 is deposited by, for example, plasma CVD on the entire upper surface of the silicon substrate 381. The insulation film 383 is also deposited on a bottom surface and a side wall of the silicon through-hole 382. The insulation film 383 can be, for example, formed of an SiON film, an SiO₂ film, an SiN film, an SiCN film, or the like.

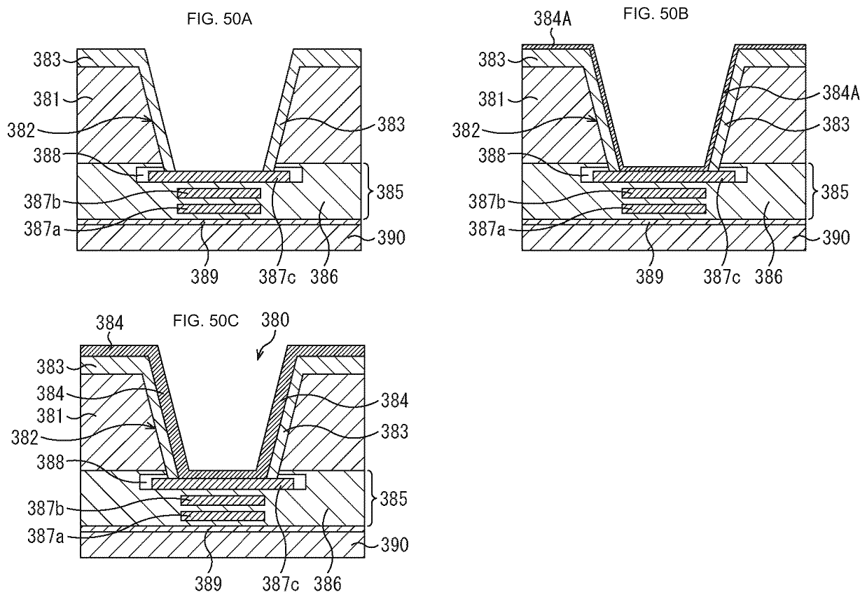

Next, as shown in A of FIG. 50, the insulation film 383 on the bottom surface of the silicon through-hole 382 is removed by etching back. As a result, the wiring layer 387c closest to the silicon substrate 381 is exposed.

Next, the barrier metal film (not shown) and a Cu seed layer 384A are formed by PVD as shown in B of FIG. 50, and then copper (Cu) is plated by electrolytic plating using the Cu seed layer 384A as an electrode as shown in C of FIG. 50. As a result, the connection electrical conductor 384 is obtained.

This step is similar to the step described above with reference to B of FIG. 10 to C of FIG. 11 in the first structure example. For the material of the barrier metal film, tantalum (Ta), titanium (Ti), tungsten (W), zirconium (Zr), a nitride film or carbon film thereof, or the like can be used. In the fifth structure example, titanium is used as the barrier metal film. In the above-mentioned manner, the through-silicon-via 380 shown in FIG. 45 is completed. Then, the solder mask 91 and the solder ball 14 in FIG. 5 are formed.

### <15. Summary of Fifth Structure Example of Through-Silicon Via>

As described above, the through-silicon-via 380 according to the fifth structure example includes the connection electrical conductor 384 via the insulation film 383 on the side wall of the silicon through-hole 382 formed on the silicon substrate 381. The connection electrical conductor 384 is connected to the wiring layer 387c closest to the silicon substrate 381 inside the multi-layer wiring layer 385. Moreover, the air gap 388 is formed on upper and lateral sides in vicinity of end surfaces of the wiring layer 387c, which are, in the plane direction, outside the connection surface between the wiring layer 387c and the connection electrical conductor 384, inside the multi-layer wiring layer 385. Since the air gap 388 is arranged on the lateral sides in vicinity of the end surfaces of the wiring layer 387c and an upper side of the silicon substrate 381 and the extension region of the wiring layer 387c is covered with the air gap 388, the leak between the silicon substrate 381 and the wiring layer 387c can be suppressed. Therefore, the withstand voltage of the through-silicon-via can be improved.

### (Combination of First to Fifth Structure Examples)

The air gap 388 of the through-silicon-via 380 according to the above-mentioned fifth structure example can be combined with at least one of the through-silicon-vias 120, 200, 240, and 280 which are the first to fourth structure examples. Accordingly, the effect of suppressing the leak between the silicon substrate on which the through-silicon-via is formed and the wiring layer closest to the silicon substrate can also be provided in addition to the effects of the first to fifth structure examples.

### <16. Sixth Structure Example of Through-Silicon Via>

Next, a sixth structure example of the through-silicon-via with the withstand voltage improved will be described.

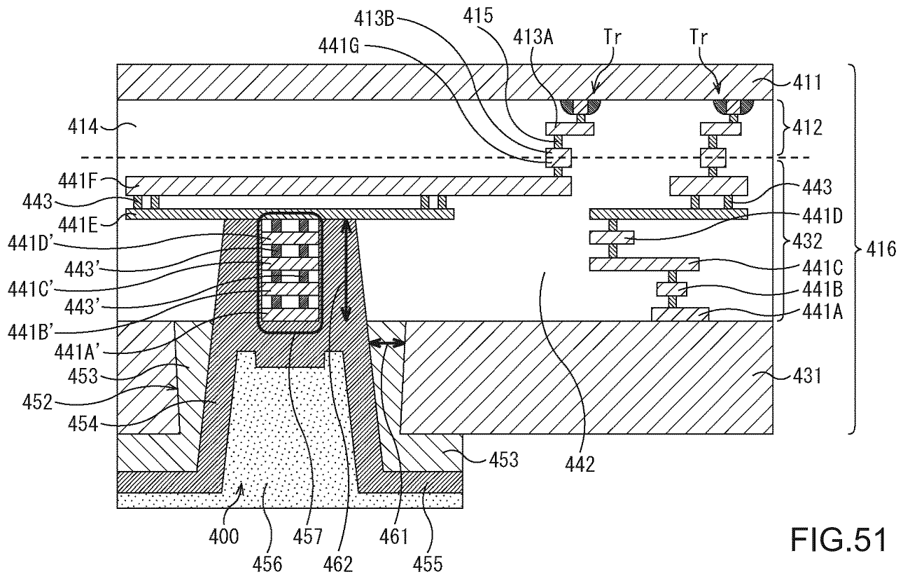

FIG. 51 is a cross-sectional view showing a sixth structure example of the through-silicon-via.

A through-silicon-via 400 which is the sixth structure example of the through-silicon-via is configured to penetrate a semiconductor substrate 431 out of a stack structure 416 in which a semiconductor substrate 411 and the semiconductor substrate 431 are stacked. Here, each of the semiconductor substrate 411 and the semiconductor substrate 431 is, for example, constituted by silicon (Si). In the following description, the semiconductor substrate 411 and the semiconductor substrate 431 will be referred to as a silicon substrate 411 and a silicon substrate 431, respectively.

The silicon substrate 411 on the upper side in FIG. 51 corresponds to the silicon substrate 101 of the pixel sensor substrate 12 in FIGS. 5 and 6. The silicon substrate 431 on the lower side in FIG. 51 corresponds to the silicon substrate 101 of the logic substrate 11 in FIGS. 5 and 6. Therefore, although not shown in the figure, photodiodes as photoelectric conversion elements are provided on the silicon substrate 411 on the upper side, the photodiodes respectively corresponding to pixels arranged in a two-dimensional array as in FIG. 5.

On a surface on a side opposite to a light incident surface of the silicon substrate 411 which is the upper side in FIG. 51, a multi-layer wiring layer 412 is formed. This multi-layer wiring layer 412 is joined with a multi-layer wiring layer 432 formed on the one silicon substrate 431. The broken line in FIG. 51 shows a junction surface between the multi-layer wiring layer 412 and the multi-layer wiring layer 432.

The multi-layer wiring layer 412 includes a plurality of wiring layers 413 including a wiring layer 413A and a wiring layer 413B and an interlayer insulation film 414. The upper and lower wiring layers 413 stacked are electrically connected to each other through a via-hole 415 at a predetermined position depending on needs. A plurality of transistors Tr is also formed at the interface with the silicon substrate 411 of the multi-layer wiring layer 412. The wiring layer 413B formed on the junction surface with the multi-layer wiring layer 432 out of the plurality of wiring layers 413 is electrically and physically connected to a wiring layer 441G on the side of the multi-layer wiring layer 432 by metal junction (Cu—Cu junction).

On the other hand, the multi-layer wiring layer 432 on the side of the silicon substrate 431 includes seven wiring layers 441 of wiring layers 441A to 441G and an interlayer insulation film 442 therebetween. The upper and lower wiring layers 441 stacked are electrically connected to a via-hole 443 at a predetermined position depending on needs.

The plurality of wiring layers 441 is, for example, formed with copper (Cu), aluminum (Al), tungsten (W), or the like and the interlayer insulation film 442 is formed of, for example, an SiO₂ film, an SiN film, an SiON film, or the like. The plurality of wiring layers 441 and the interlayer insulation film 442 may be formed of the same material in all layers or two of the above-mentioned materials may be used depending on the layers. The same applies to the material and configuration of the wiring layers 413 and the interlayer insulation film 414 on the side of the multi-layer wiring layer 412.

It should be noted that the number of layers of the wiring layers 441 in the multi-layer wiring layer 432 and the number of layers of the wiring layers 413 in the multi-layer wiring layer 412 are not limited to the example in FIG. 51, and can be any number of layers.

The through-silicon-via 400 is formed by embedding a connection electrical conductor 454 in an inner wall of a silicon through-hole 452 formed at a predetermined position of the silicon substrate 431 via an insulation film 453. The insulation film 453 is formed of, for example, an SiO₂ film, an SiN film, an SiON film, or the like.

It should be noted that although in the through-silicon-via 400 shown in FIG. 51, the insulation film 453 and the connection electrical conductor 454 are deposited along the inner wall surface, a solder mask 456 is embedded in an inner space surrounded by the connection electrical conductor 454 formed on the side wall, the entire opening of the silicon substrate 431 is embedded with the connection electrical conductor 454 depending on the inner diameter of the silicon through-hole 452. Moreover, the inner space surrounded by the connection electrical conductor 454 in which the solder mask 456 is embedded may be hollow.

The connection electrical conductor 454 is partially formed on an upper surface (in FIG. 51, the surface on the lower side) of the silicon substrate 431 which is a junction portion with the external substrate and functions as a rewiring 455. The inner space surrounded by the connection electrical conductor 454 of the through-silicon-via 400 and an upper portion of the rewiring 455 formed on the upper surface of the silicon substrate 431 are protected by the solder mask 456.

The connection electrical conductor 454 is also formed, embedded in the multi-layer wiring layer 432 so as to reach the fifth wiring layer 441E from the side of the silicon substrate 431 in the multi-layer wiring layer 432.

In addition, a stack via-hole 457 constituted by four wiring layers 441′ including wiring layers 441A′ to 441D′ and via-holes 443′ for connecting the upper and lower wiring layers 441′ is formed in the inside in the plane direction of the connection electrical conductor 454 formed in the multi-layer wiring layer 432. The wiring layers 441A′ to 441D′ are respectively formed in the same layer as the wiring layers 441A to 441D formed in other regions other than the through-silicon-via 400. The respective wiring layers 441′ in the stack via-hole 457 are formed at the same time as the wiring layers 441 in the same layer, which are formed in other regions other than the through-silicon-via 400.

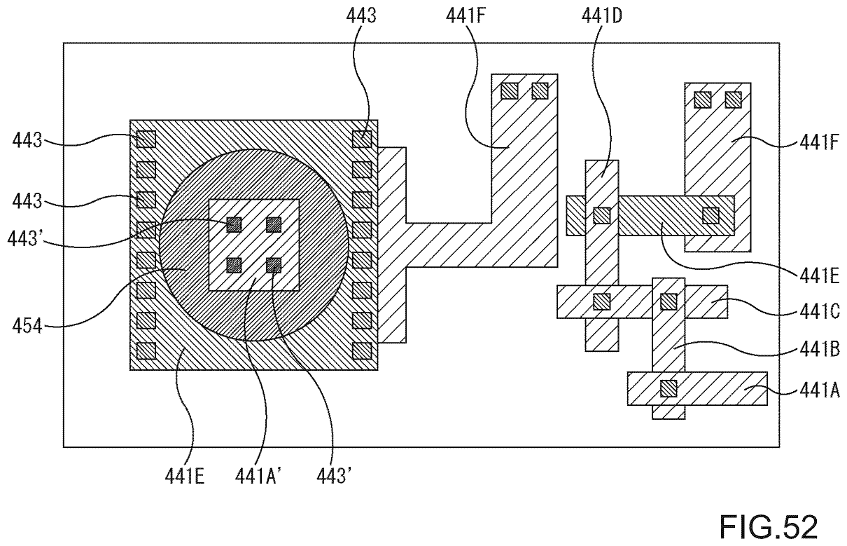

FIG. 52 is a plan view showing arrangement in the plane direction of the connection electrical conductor 454 and the stack via-hole 457 of the through-silicon-via 400 in the multi-layer wiring layer 432 and the plurality of wiring layers 441.

The connection electrical conductor 454 of the through-silicon-via 400 is formed in a circular plane shape in accordance with the circular plane shape of the silicon through-hole 452. Four wiring layers 441A′ to 441D′ constituting the stack via-hole 457 and the plurality of via-holes 443′ are arranged inside the circular shape of the connection electrical conductor 454. Although the four via-holes 443′ connecting the four wiring layers 441A′ to 441D′ to each other in upper and lower directions are formed in the example of FIG. 52, the number of via-holes 443′ and arrangement of the via-holes 443′ can be determined as appropriate.

The wiring layer 441E to which the connection electrical conductor 454 of the through-silicon-via 400 connects at its bottom portion includes an extension region. That is, to give the wiring layer 441E a margin for position deviation of the through-silicon-via 400 (silicon through-hole 452), the wiring layer 441E is formed to be wider in the plane direction than the circular connection electrical conductor 454. On the contrary, the stack via-hole 457 is formed inside the circular connection electrical conductor 454, and thus the stack via-hole 457 is arranged to be smaller than the area of the circular connection electrical conductor 454. The outer peripheries (side walls) of a plurality of wiring layers 441′ are connected to the connection electrical conductor 454.

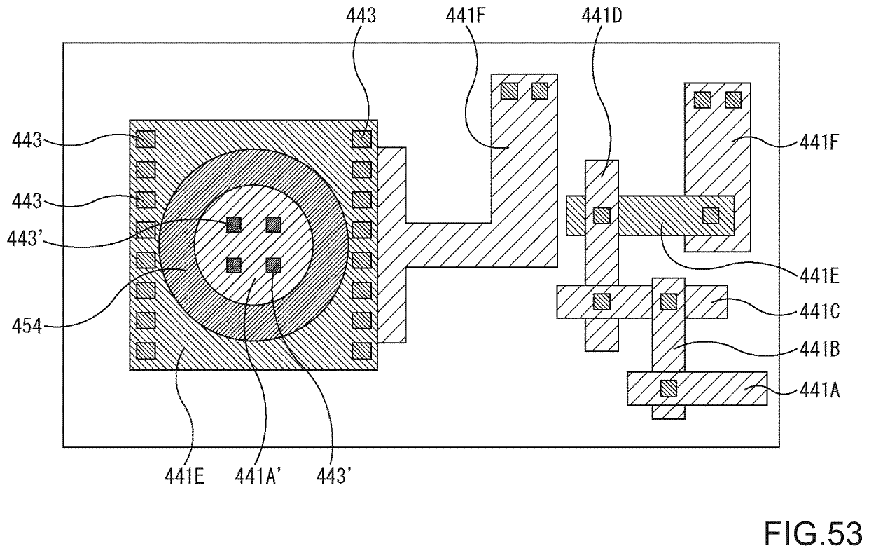

The plane shape of each of the four wiring layers 441A′ to 441D′ of the stack via-hole 457 can be a rectangular shape as shown in the wiring layer 441A′ in FIG. 52. Alternatively, as shown in the wiring layer 441A′ in FIG. 53, the plane shape of each of the four wiring layers 441A′ to 441D′ of the stack via-hole 457 may be a circular shape like a circular plane shape of the connection electrical conductor 454. FIG. 53 is a plan view showing an example in which the plane shape of each of the four wiring layers 441A′ to 441D′ is different from that in the example of FIG. 52.

The through-silicon-via 400 in FIG. 51 can be arranged in the solid-state image pickup apparatus 1 in place of the through-silicon-via 88 in FIG. 5 or 6 described above. The silicon substrate 431 corresponds to the silicon substrate 81 in FIG. 5 and the wiring layer 441E corresponds to the wiring layer 83c in FIG. 5.

Effects of the through-silicon-via 400 will be described with reference to FIG. 51.

The through-silicon-via 400 includes the insulation film 453 and the connection electrical conductor 454 on the side wall of the silicon through-hole 452 formed in the silicon substrate 431. The connection electrical conductor 454 formed on the side wall of the silicon through-hole 452 is formed, embedded also in the multi-layer wiring layer 432 at a depth reaching the fifth wiring layer 441E in the multi-layer wiring layer 432.

Moreover, the through-silicon-via 400 includes the stack via-hole 457 inside the connection electrical conductor 454 in the multi-layer wiring layer 432 (inside in the plane direction). The stack via-hole 457 is constituted by the plurality of wiring layers 441′ and the via-holes 443′ electrically connecting the upper and lower wiring layers 441′. The stack via-hole 457 is formed so that its plane area is smaller than the plane area of the outer shape of the connection electrical conductor 454 and is arranged inside the connection electrical conductor 454. As a result, the side walls of the plurality of wiring layers 441′ are connected to the connection electrical conductor 454. By also using the side wall surface of each wiring layer 441′ of the stack via-hole 457 for electrical connection between the through-silicon-via 400 and the wiring layer 441E, the connection area largely increases, and thus the connection reliability of the wirings is improved. Moreover, the through-silicon-via 400 does not need to be electrically connected to any one of the wiring layers 441′ constituting the stack via-hole 457. Therefore, the connection reliability of the wirings is improved.

Since the connection electrical conductor 454 of the through-silicon-via 400 is formed to extend to a depth reaching the fifth wiring layer 441E closer to the silicon substrate 411 on the side of the light incident surface in the multi-layer wiring layer 432 so as to connect to the wiring layer 441E, the connection resistance can be reduced in a case of electrically connecting to the wiring layers 413 on the side of the silicon substrate 411.

Owing to the configuration in which the connection electrical conductor 454 of the through-silicon-via 400 is formed to extend to the depth reaching the fifth wiring layer 441E in the multi-layer wiring layer 432, which is deeper than the thickness of the silicon substrate 431, so as to electrically connect to the fifth wiring layer 441E, the wiring layer 441E as a connection target wiring layer of the through-silicon-via 400 can be separated from the silicon substrate 431 by a distance corresponding to a height (depth) 462 of the stack via-hole 457. For example, the distance between the silicon substrate 431 to the wiring layer 441E can be set to 1 μm or more. Accordingly, even in a case where the plane area of the wiring layer 441E is secured to be significantly larger than the plane area of the silicon through-hole 452 and the connection electrical conductor 454 to give the plane area of the wiring layer 441E a margin for position deviation of the through-silicon-via 400, the leak between the wiring layer 441E and the silicon substrate 431 can be suppressed.

Moreover, if a high voltage to break the insulation film is applied on the through-silicon-via 400, the insulation film 453 on the side wall of the silicon through-hole 452 is broken rather than the interlayer insulation film 442 between the wiring layer 441E and the silicon substrate 431 because the height 462 of the stack via-hole 457 is larger than a thickness 461 of the insulation film 453 formed on the side wall of the silicon through-hole 452. Therefore, by increasing the thickness 461 of the insulation film 453 formed on the side wall of the silicon through-hole 452, the withstand voltage of the through-silicon-via 400 can be improved.

It should be noted that although in the above-mentioned sixth structure example, the example in which the number of wiring layers 441′ of the stack via-hole 457 is four has been described, the number of wiring layers 441′ may be two, three, or five or more, not four. Alternatively, a single wiring layer 441′ may be provided. With the single wiring layer 441′, the via-holes 443′ electrically connects the wiring layer 441E and the connection electrical conductor 454 which are arranged in the upper and lower directions.

### <Manufacturing Method for Sixth Structure Example of Through-Silicon Via>

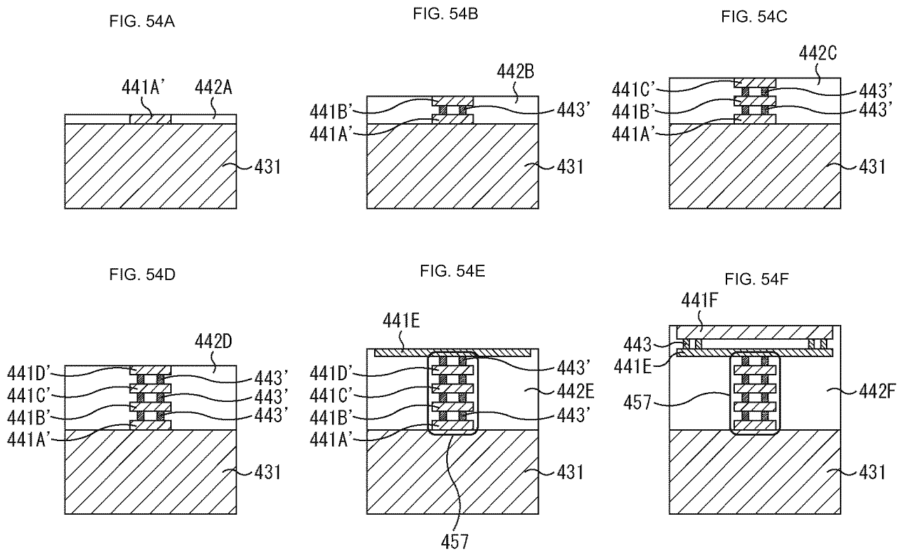

Next, a manufacturing method for the through-silicon-via 400 according to the sixth structure example will be described with reference to FIGS. 54 to 56.

First of all, as shown in A of FIG. 54, an interlayer insulation film 442A is deposited on entire one surface of the silicon substrate 431, and then the wiring layer 441A′ is formed in a predetermined region. The interlayer insulation film 442A can be formed of an SiON film, an SiO₂ film, an SiN film, an SiCN film, or the like by, for example, plasma CVD. The wiring layer 441A′ can be formed of copper by, for example, a damascene process at the same time as the other wiring layer 441A in the same layer.

Next, as shown in B of FIG. 54, an interlayer insulation film is further stacked on the interlayer insulation film 442A as an interlayer insulation film 442B, and then the plurality of via-holes 443′ and the wiring layer 441B′ are formed in predetermined regions above the wiring layer 441A′.

Next, as shown in C of FIG. 54, an interlayer insulation film is further stacked on the interlayer insulation film 442B as an interlayer insulation film 442C, and then the plurality of via-holes 443′ and the wiring layer 441C′ are formed in predetermined regions above the wiring layer 441B′.

Next, as shown in D of FIG. 54, an interlayer insulation film is further stacked on the interlayer insulation film 442C as an interlayer insulation film 442D, and then the plurality of via-holes 443′ and the wiring layer 441D′ are formed in predetermined regions above the wiring layer 441C′. The wiring layers 441B′ to 441D′ can be respectively formed at the same time as the other wiring layers 441B to 441D in the same layer.

Next, as shown in E of FIG. 54, an interlayer insulation film is further stacked on the interlayer insulation film 442D as an interlayer insulation film 442E, and then the plurality of via-holes 443′ and the wiring layer 441E including the extension region are formed in predetermined regions above the wiring layer 441D′. With the four wiring layers 441A′ to 441D′ and the via-holes 443′ described above, the stack via-hole 457 is completed.

Next, as shown in F of FIG. 54, an interlayer insulation film is further stacked on the interlayer insulation film 442E as an interlayer insulation film 442F, and then the plurality of via-holes 443 and the wiring layer 441F are formed in predetermined regions above the wiring layer 441E.

A forming method for the interlayer insulation films 442B to 442F is similar to the above-mentioned interlayer insulation film 442A. A forming method for the plurality of via-holes 443 and the wiring layers 441B′ to 441F are also similar to the wiring layer 441A′. The wiring layers 441A′ to 441F and the plurality of via-holes 443 may be all formed of the same metal films (in the sixth structure example, copper) or may be formed of different metal films depending on the layers.

In addition, although not shown in the figure, an interlayer insulation film is further stacked on the interlayer insulation film 442F and the wiring layer 441F as an interlayer insulation film 442 and the wiring layer 441G is formed to be connected to the multi-layer wiring layer 432 on the side of the silicon substrate 411 by metal junction.

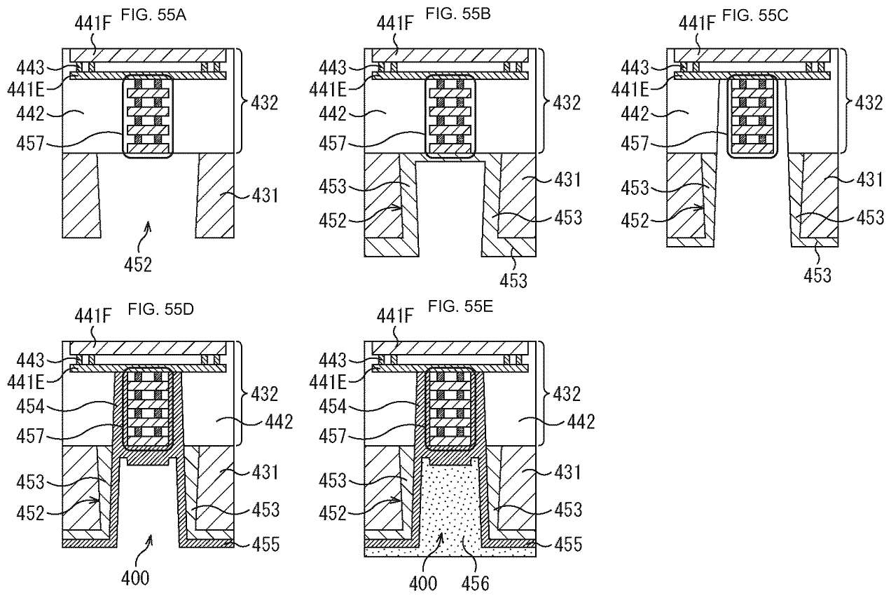

In the next step in A to E of FIG. 55, the junction substrate is inverted up and down and working is performed with the back surface of the silicon substrate 431 oriented upwards. However, the description will be given with the back surface of the silicon substrate 431 oriented downwards in FIG. 55 without changing the orientation.

Next, as shown in A of FIG. 55, the silicon through-hole 452 is formed from the side of the back surface (in FIG. 55, the lower surface) of the silicon substrate 431. As in the step described above with reference to A to C of FIG. 9, a photoresist is patterned and dry etching is performed, such that the silicon through-hole 452 can be formed. At this time, the silicon through-hole 452 is formed in an inverted tapered shape whose diameter on a top surface side of the silicon substrate 431, which is the side of the multi-layer wiring layer 432, is larger than the diameter on a back surface side of the silicon substrate 431.

Next, as shown in B of FIG. 55, the insulation film 453 is deposited on the entire upper surface of the silicon substrate 431 by, for example, plasma CVD. The insulation film 453 formed of, for example, an SiON film, an SiO₂ film, an SiN film, an SiCN film, or the like. Although the insulation film 453 is also deposited on the bottom surface and the side wall of the silicon through-hole 452, the film thickness of the insulation film 453 on the bottom surface of the silicon through-hole 452 is formed to be smaller than the film thickness of the upper surface of the silicon substrate 431.

Next, as shown in C of FIG. 55, the insulation film 453 is removed by etching back. Although the insulation film 453 on the bottom surface of the silicon through-hole 452 is completely removed excluding the side wall portion, a part of the insulation film 453 on the upper surface of the silicon substrate 431 remains due to its film thickness difference from the bottom surface of the silicon through-hole 452. Moreover, since the silicon through-hole 452 is formed in the inverted tapered shape, the insulation film 453 on the side wall of the silicon through-hole 452 is not removed because the film thickness on the side of the multi-layer wiring layer 432 is increased.

In addition, the interlayer insulation film 442 which is held in contact with the side wall surfaces of the four wiring layers 441A′ to 441D′ that constitute the stack via-hole 457 is removed to reach the wiring layer 441E by anisotropic dry etching. The interlayer insulation film 442 and the insulation film 453 may be films made of the same material or may be films made of different materials. The four wiring layers 441A′ to 441D′ of the stack via-hole 457 are not removed because the wiring layer 441A′ serves as an etching stopper film.

Next, as shown in D of FIG. 55, a barrier metal film and a Cu seed layer (both are not shown) are formed, and then copper (Cu) is embedded by electrolytic plating using the Cu seed layer as an electrode. As a result, the connection electrical conductor 454 is provided. This step is similar to the step described above with reference to B of FIG. 10 to C of FIG. 11 in the first structure example. For the material of the barrier metal film, tantalum (Ta), titanium (Ti), tungsten (W), zirconium (Zr), a nitride film or carbon film thereof, or the like can be used. In the sixth structure example, titanium is used as the barrier metal film. The connection electrical conductor 454 is also formed on the insulation film 453 on the upper surface of the silicon substrate 431. As a result, a rewiring 455 is provided. Accordingly, the through-silicon-via 400 including the connection electrical conductor 454 and the stack via-hole 457 is completed.

Last of all, as shown in E of FIG. 55, the solder mask 456 is embedded on the inner space surrounded by the connection electrical conductor 454 of the through-silicon-via 400 and the upper surface of the rewiring 455 on the upper surface of the silicon substrate 431 is covered with the solder mask 456.

In the above-mentioned manufacturing method, when forming the silicon through-hole 452 on the silicon substrate 431, the silicon through-hole 452 is formed in the inverted tapered shape whose diameter on the side of the multi-layer wiring layer 432 is larger. However, a method of forming the silicon through-hole 452 in a tapered shape easier for working control may be employed.

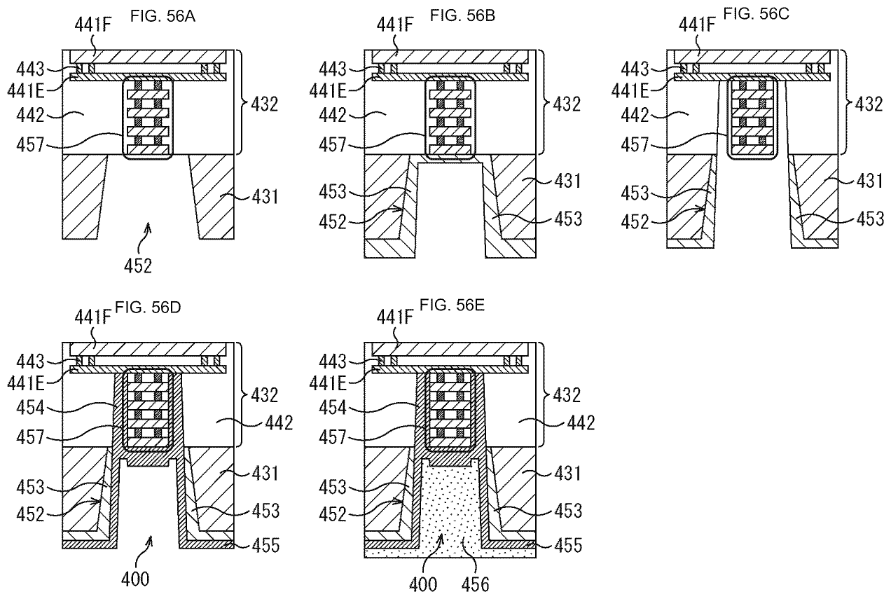

FIG. 56 is views describing the manufacturing method in a case of forming the silicon through-hole 452 in a tapered shape. The above-mentioned step in A to E of FIG. 55 is replaced by a step in A to E of FIG. 56.

As shown in A of FIG. 56, the silicon through-hole 452 is formed from the side of the back surface (in FIG. 56, a lower surface) of the silicon substrate 431. The silicon through-hole 452 is formed in a tapered shape whose diameter on the top surface side of the silicon substrate 431, which is the side of the multi-layer wiring layer 432, is smaller than the diameter on the back surface side of the silicon substrate 431.

Next, as shown in B of FIG. 56, an insulation film 453 is deposited on the entire upper surface of the silicon substrate 431 and the bottom surface and the side wall of the silicon through-hole 452. As to the film thickness of the insulation film 453 on the side wall of the silicon through-hole 452, the side of the multi-layer wiring layer 432 is thicker than the top surface side of the silicon substrate 431 in accordance with the shape of the silicon through-hole 452 in the tapered shape. It is similar to B of FIG. 55 in that the film thickness of the insulation film 453 on the bottom surface of the silicon through-hole 452 is formed to be smaller than the film thickness of the upper surface of the silicon substrate 431.

Next, as shown in C of FIG. 56, the insulation film 453 on the bottom surface of the silicon through-hole 452 is removed by etching back and the interlayer insulation film 442 which is held in contact with the side wall surfaces of the four wiring layers 441A′ to 441D′ that constitute the stack via-hole 457 is opened.

Next, as shown in D of FIG. 56, a barrier metal film and a Cu seed layer (both are not shown) are formed, and then copper is embedded by electrolytic plating and the connection electrical conductor 454 is formed. The connection electrical conductor 454 is also formed on the insulation film 453 on the upper surface of the silicon substrate 431. As a result, a rewiring 455 is provided. Accordingly, the through-silicon-via 400 including the connection electrical conductor 454 and the stack via-hole 457 is completed.

Last of all, as shown in E of FIG. 56, the solder mask 456 is embedded on the inner space surrounded by the connection electrical conductor 454 of the through-silicon-via 400 and the upper surface of the rewiring 455 on the upper surface of the silicon substrate 431 is covered with the solder mask 456.

As described above, the through-silicon-via 400 according to the sixth structure example can be produced.

### <Modified Example of Sixth Structure Example of Through-Silicon Via>

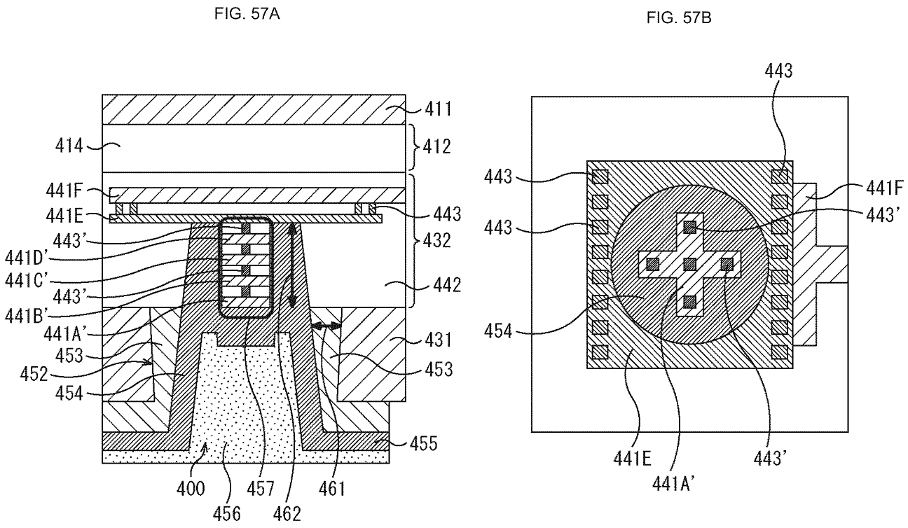

FIGS. 57 to 59 are modified examples of the sixth structure example of the through-silicon-via, and in particular, they show modified examples of the stack via-hole 457 of the through-silicon-via 400 according to the sixth structure example.

A first modified example of the sixth structure example shown in FIG. 57 shows an example in which the plane shape of each of the four wiring layers 441A′ to 441D′ constituting the stack via-hole 457 is changed into a cross shape. The via-holes 443′ that connect the four wiring layers 441A′ to 441D′ and the wiring layer 441E including the extension region are arranged at a total of five positions, four positions, i.e., the upper, lower, left, and right projection portions of the cross shape and one position of the central portion of the cross shape.

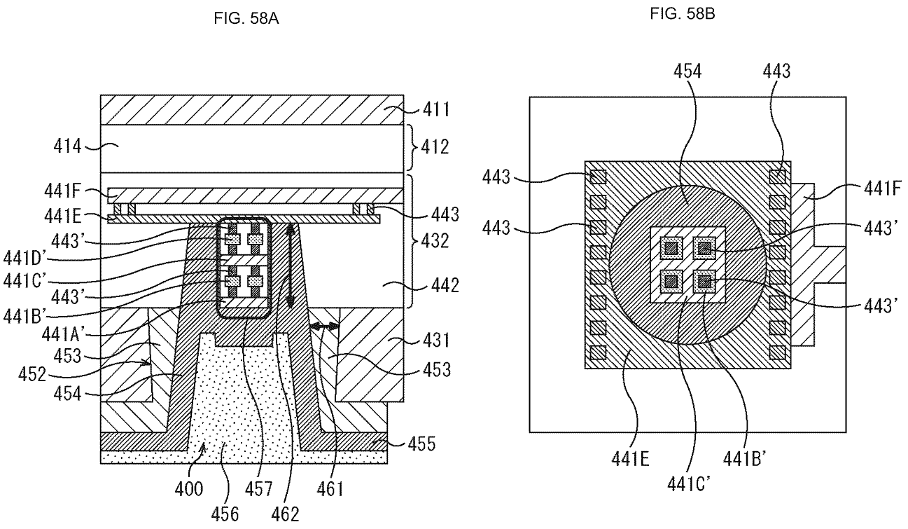

A second modified example of the sixth structure example shown in FIG. 58 shows an example in which the plane shape of each of the four wiring layers 441A′ to 441D′ constituting the stack via-hole 457 is deformed to differ in some layers. As in the basic structure shown in FIGS. 51 and 52, the wiring layers 441A′ and 441C′ are formed in one rectangular shape connected to four via-holes 443′, but the wiring layers 441B′ and 441D′ have rectangular shapes (island patterns) independently provided for each of the four via-holes 443′. In the example in FIG. 58, the number of via-holes 443′ is 2×2=4, and thus the wiring layers 441B′ and 441D′ are also configured in island patterns of 2×2. However, as to arrangement of the island patterns of the wiring layers 441B′ and 441D′, they are arranged in a mesh shape according to the number of via-holes 443′. For example, in a case where the number of via-holes 443′ is, for example, 3×3=9, island patterns of 3×3 are provided.

In the second modified example in FIG. 58, the plane shapes of the wiring layers 441A′ and 441C′ are the same and the plane shapes of the wiring layers 441B′ and 441D′ are the same. However, all the plane shapes of the wiring layers 441A′ to 441D′ may be configured to be different.

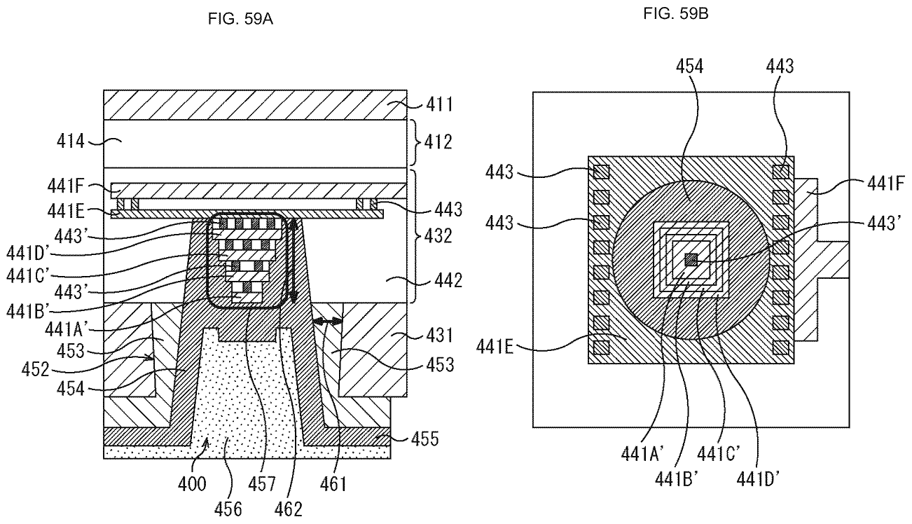

A third modified example of the sixth structure example shown in FIG. 59 shows an example in which the plane sizes of the four wiring layers 441A′ to 441D′ constituting the stack via-hole 457 differ depending on the layers and they are formed in a pyramid shape as a whole. Specifically, the plane sizes of the four wiring layers 441A′ to 441D′ are configured so that the wiring layer 441A′ is the smallest and gradually becomes larger in order of the wiring layers 441A′, 441B′, 441C′, and 441D′.

Although the modified examples of the through-silicon-via 400, in particular, the stack via-hole 457 have been above with reference to FIGS. 57 to 59, the stack via-hole 457 may have a structure other than the above-mentioned examples. In a case where the four wiring layers 441A′ to 441D′ are viewed as a stacked three-dimensional shape, any shape such as a prism shape, a cylindrical shape, a cross shape, a mesh shape, or a pyramid shape can be employed.

### <17. Summary of Sixth Structure Example of Through-Silicon Via>

As described above, the through-silicon-via 400 according to the sixth structure example includes the connection electrical conductor 454 via the insulation film 453 on the side wall of the silicon through-hole 452 formed in the silicon substrate 431. The connection electrical conductor 454 is also formed, embedded in the multi-layer wiring layer 432, and the stack via-hole 457 is provided inside the connection electrical conductor 454 (inside in the plane direction). Due to the provision of the stack via-hole 457, the connection reliability of the wirings can be improved. The distance between the silicon substrate 431 and the wiring layer 441E can be set to be a distance corresponding to the height 462 of the stack via-hole 457, and thus the leak between the wiring layer 441E and the silicon substrate 431 can be suppressed. Therefore, the withstand voltage of the through-silicon-via can be improved.

### (Combinations of First to Sixth Structure Examples)

A structure obtained by combining the stack via-hole 457 of through-silicon-via 400 according to the above-mentioned sixth structure example with at least one of the through-silicon-vias 120, 200, 240, 280, and 380 that are the first to fifth structure examples as appropriate may be employed. Accordingly, the effects of the sixth structure example such as the silicon substrate in which the through-silicon-via is formed, the suppression of the leak to the connection target wiring layer of the through-silicon-via, and the connection reliability of the wirings can be improved in addition to the effects of the first to fifth structure examples.

### <18. Seventh Structure Example of Through-Silicon Via>

Next, a seventh structure example of the through-silicon-via with the withstand voltage improved will be described.

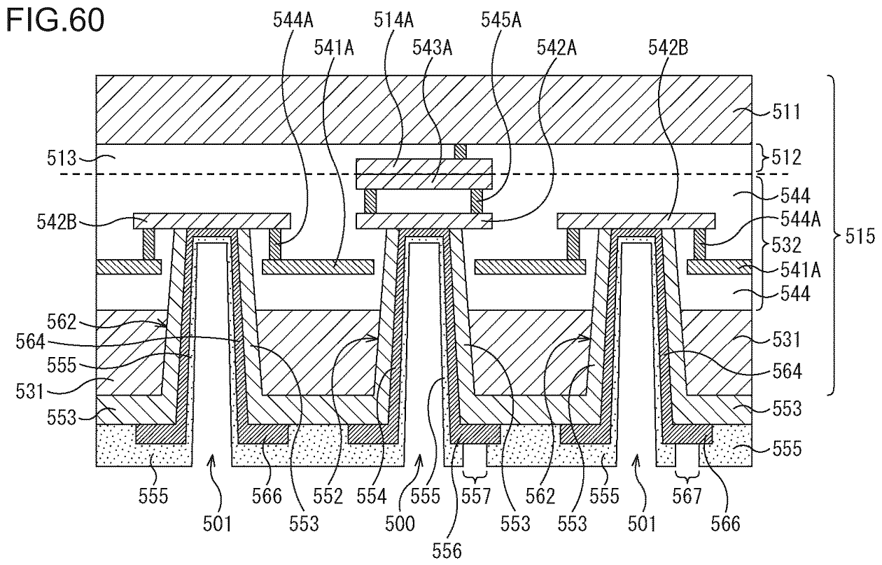

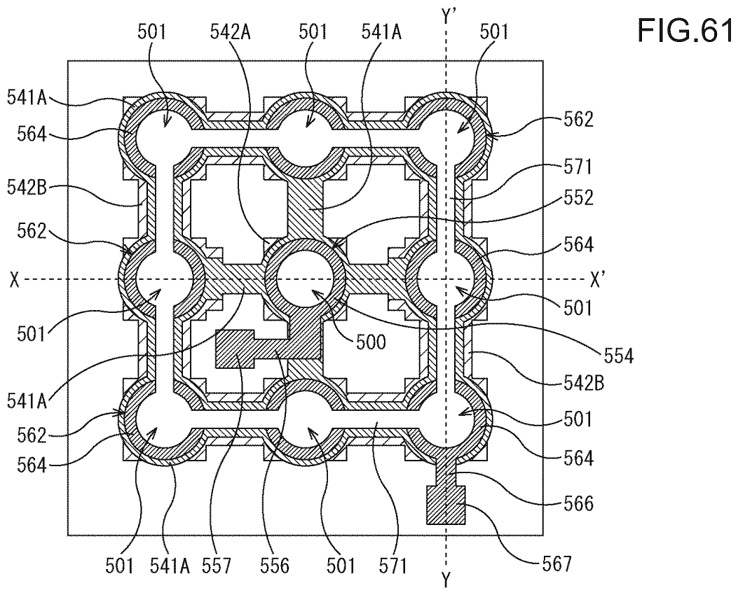

FIG. 60 is a cross-sectional view showing the seventh structure example of the through-silicon-via. This cross-sectional view corresponds to a cross-sectional view taken along the line X-X′ in FIG. 61 to be described later.

A through-silicon-via 500 that is the seventh structure example of the through-silicon-via is formed to penetrate a semiconductor substrate 531 which is one of a stack structure 515 in which a semiconductor substrate 511 and the semiconductor substrate 531 are stacked. Moreover, a plurality of through-silicon-vias 501 is formed adjacent to the through-silicon-via 500. Here, each of the semiconductor substrate 511 and the semiconductor substrate 531 is, for example, constituted by silicon (Si). In the following description, the semiconductor substrate 511 and the semiconductor substrate 531 will be referred to as a silicon substrate 511 and a silicon substrate 531, respectively.

The silicon substrate 511 on the upper side in FIG. 60 corresponds to the silicon substrate 101 of the pixel sensor substrate 12 in FIGS. 5 and 6 and the silicon substrate 531 on the lower side in FIG. 60 corresponds to the silicon substrate 101 of the logic substrate 11 in FIGS. 5 and 6. Therefore, although not shown in the figure, photodiodes as photoelectric conversion elements are provided on the silicon substrate 511 on the upper side, the photodiodes respectively corresponding to pixels arranged in a two-dimensional array as in FIG. 5.

A multi-layer wiring layer 512 is formed on the surface on a side opposite to the light incident surface of the one silicon substrate 511 which is the upper side in FIG. 60. This multi-layer wiring layer 512 is joined with a multi-layer wiring layer 532 formed on the other silicon substrate 531. The broken line in FIG. 60 shows a junction surface between the multi-layer wiring layer 512 and the multi-layer wiring layer 532.

The multi-layer wiring layer 512 includes a plurality of wiring layers 514 and an interlayer insulation film 513 formed therebetween. It should be noted that in FIG. 60, only one wiring layer 514 of the plurality of wiring layers 514, which is formed on the junction surface with the multi-layer wiring layer 532, is shown, and a wiring layer 514A that is the one wiring layer 514 is shown. The wiring layer 514A is connected to a wiring layer 543A on the side of the multi-layer wiring layer 532 by metal junction (Cu—Cu junction).

On the other hand, the multi-layer wiring layer 532 on the side of the silicon substrate 531 also includes a plurality of wiring layers 541 to 543 and an interlayer insulation film 544 formed therebetween. A wiring layer 541 (541A) of the plurality of wiring layers 541 to 543 is a wiring layer closest to the silicon substrate 531 and wiring layers 542 (542A, 542B) are wiring layers second closest to the silicon substrate 531, following the wiring layer 541. The wiring layer 543 (543A) is formed on the junction surface with the multi-layer wiring layer 512 and is a wiring layer for being connected to a wiring layer 514 on the side of the multi-layer wiring layer 512 by metal junction (Cu—Cu junction). In FIG. 60, the wiring layer 543A on the side of the multi-layer wiring layer 532 and the wiring layer 514A on the side of the multi-layer wiring layer 512 are electrically and physically connected to each other by metal junction (Cu—Cu junction).

The wiring layer 541A that is one of the wiring layers 541, which is closest to the silicon substrate 531, is electrically connected to the wiring layer 542B, which is one of the wiring layers 542 in the second layer, through via-holes 544A or the like. The wiring layer 542A that is the other of the wiring layers 542 in the second layer is electrically connected to the wiring layer 543A through via-holes 545A or the like.

The plurality of wiring layers 541 to 543 is, for example, formed with copper (Cu), aluminum (Al), tungsten (W), or the like and the interlayer insulation film 544 is formed of, for example, an SiO₂ film, an SiN film, an SiON film, or the like. Each of the plurality of wiring layers 541 to 543 and the interlayer insulation film 544 may be formed of the same material in all layers or two of the above-mentioned materials may be used depending on the layers. The same applies to the material and configuration of the wiring layer 514 and the interlayer insulation film 513 on the side of the multi-layer wiring layer 512.

It should be noted that the number of layers of the wiring layers 541 to 543 in the multi-layer wiring layer 532 and the number of layers of the wiring layer 514 in the multi-layer wiring layer 512 can be constituted by any number of layers.

The through-silicon-via 500 is formed by embedding a connection electrical conductor 554 via an insulation film 553 on an inner wall of a silicon through-hole 552 formed at a predetermined position in the silicon substrate 531. The insulation film 553 is formed of, for example, an SiO₂ film, an SiN film, an SiON film, or the like. The silicon through-hole 552 penetrates the silicon substrate 531 and is formed to extend to a depth of the wiring layer 542A in the multi-layer wiring layer 532. As a result, the connection electrical conductor 554 formed on the bottom portion of the silicon through-hole 552 is directly connected to the wiring layer 542A. The connection electrical conductor 554 is also formed on the upper surface on the back surface side of the silicon substrate 531 via the insulation film 553 and functions as a rewiring 556. The upper portion of the connection electrical conductor 554 formed on the side wall and the bottom portion of the silicon through-hole 552 is covered with a solder mask 555. The rewiring 556 on a back surface of the silicon substrate 531 is covered with the solder mask 555 excluding a portion constituting an electrode pad portion 557.

The through-silicon-via 501 adjacent to the through-silicon-via 500 is formed by embedding a connection electrical conductor 564 in an inner wall of a silicon through-hole 562 formed at a predetermined position in the silicon substrate 531 via the insulation film 553. The silicon through-hole 562 penetrates the silicon substrate 531 and is formed to extend to a depth of the wiring layer 542B in the multi-layer wiring layer 532. As a result, the connection electrical conductor 564 formed on the bottom portion of the silicon through-hole 562 is directly connected to the wiring layer 542B. The connection electrical conductor 564 is also formed on the upper surface on the back surface side of the silicon substrate 531 via the insulation film 553 and functions as a rewiring 566. An upper portion of the connection electrical conductor 564 formed on the side wall and the bottom portion of the silicon through-hole 562 is covered with the solder mask 555. The rewiring 566 on the back surface of the silicon substrate 531 is also covered with the solder mask 555 excluding a portion constituting an electrode pad portion 567.

The connection electrical conductor 554 of the through-silicon-via 500 is directly connected to the wiring layer 542A on the bottom portion of the silicon through-hole 552. When a first application voltage is applied from the electrode pad portion 557 of the through-silicon-via 500, the applied first application voltage is transmitted to the side of the silicon substrate 511 via the wiring layer 542A, the via-holes 545A, the wiring layer 543A, or the like.

The connection electrical conductor 564 of the through-silicon-via 501 is directly connected to the wiring layer 542B on the bottom portion of the silicon through-hole 562. When a second application voltage different from the first application voltage is applied from the electrode pad portion 567 of the through-silicon-via 501, the applied second application voltage is transmitted to the wiring layer 541A via the wiring layer 542B and the via-holes 544A.

In the following description, for easily distinguishing them, the through-silicon-via 500 on which the first application voltage is applied will be referred to as a first through-silicon-via 500 and the through-silicon-via 501 on which the second application voltage is applied will be referred to as a second through-silicon-via 501. Moreover, in the following description, the wiring layer 542A to which the first through-silicon-via 500 is electrically connected will be referred to as a first wiring layer 542A and the wiring layers 541A which are electrically connected to the second through-silicon-via 501 and are arranged closer to the silicon substrate 531 than the first wiring layer 542A will be referred to as second wiring layers 541A.

The first through-silicon-via 500 is not electrically connected to the second through-silicon-vias 501. More specifically, the connection electrical conductor 554 and the first wiring layer 542A for the first through-silicon-via 500 are not electrically connected to the connection electrical conductors 564 and the second wiring layers 541A for the second through-silicon-vias 501.

It should be noted that in the first through-silicon-via 500 shown in FIG. 60, the insulation film 553 and the connection electrical conductor 554 are deposited along the inner wall surface and the inner space is hollow with the solder mask 555 covering the connection electrical conductor 554 on the side wall. However, the entire opening of the silicon substrate 531 may be embedded with the connection electrical conductor 554 or the solder mask 555 depending on the inner diameter of the silicon through-hole 552. In other words, the inside of the opening in the silicon substrate 531 may be embedded with a conductor or solder mask or may be partially hollow. The same applies to the second through-silicon-via 501.

FIG. 61 is a plan view showing arrangement of the first through-silicon-via 500 and the plurality of second through-silicon-vias 501. In FIG. 61, plane arrangement of the connection electrical conductors 554 and 564, the second wiring layers 541A, the first wiring layer 542A and the wiring layers 542B, and the like is shown.

The plurality of second through-silicon-via 501 is arranged in the periphery of the first through-silicon-via 500. For example, as shown in FIG. 61, the eight second through-silicon-vias 501 are arranged with arrangement in a matrix form of 3×3, using the first through-silicon-via 500 as a center.

Moreover, a rectangular groove 571 is formed to connect the eight second through-silicon-vias 501 arranged to surround the first through-silicon-via 500 as a center.

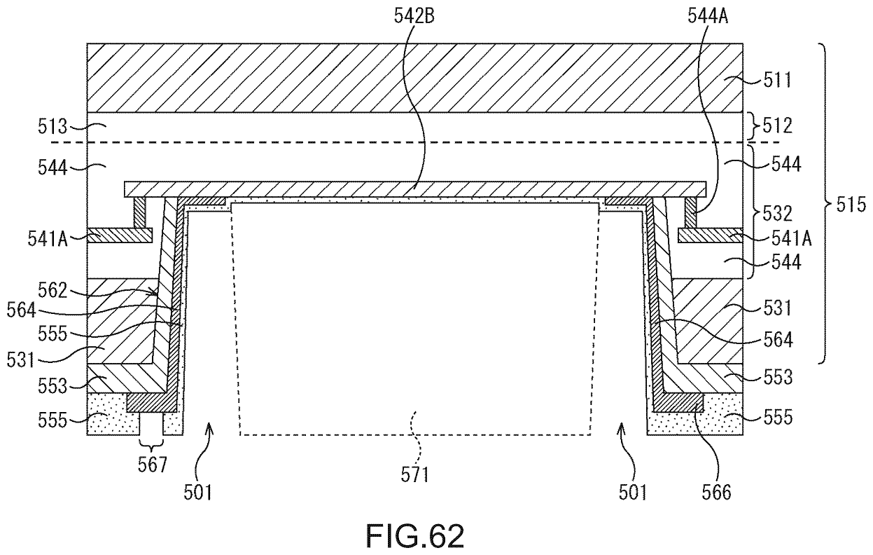

FIG. 62 shows a cross-sectional view taken along the line Y-Y′ in FIG. 61 which is a center line of the groove 571.

As shown in FIG. 62, the groove 571 is formed at the same depth as the silicon through-holes 562 of the second through-silicon-vias 501 from the side of the back surface (in FIG. 62, the lower surface) of the silicon substrate 531 and the second through-silicon-vias 501 adjacent to each other are connected to each other.

Referring back to FIG. 61, in the first through-silicon-via 500 at the center, the first application voltage applied on the electrode pad portion 557 is supplied to the connection electrical conductor 554 formed on the side wall and the bottom portion of the silicon through-hole 552 via the rewiring 556. The first application voltage supplied to the connection electrical conductor 554 is supplied to the first wiring layer 542A at the bottom portion of the silicon through-hole 552. It should be noted that as to the electrode pad portion 557 shown in FIG. 60, the electrode pad portion 557 provided in a location other than the line X-X′ as in FIG. 61 is shown for the sake of convenience.

In the plurality of second through-silicon-vias 501 in the periphery of the first through-silicon-via 500, the second application voltage applied on the electrode pad portion 567 is supplied to the connection electrical conductors 564 formed on the side walls and the bottom portions of the silicon through-holes 562 via the rewiring 566. The second application voltage supplied to the connection electrical conductor 564 is supplied to the wiring layers 542B at the bottom portions of the silicon through-holes 562. As to the electrode pad portion 567 shown in FIG. 60, as in FIG. 61, the electrode pad portion 567 provided in a location other than the line X-X′ is shown for the sake of convenience.

The wiring layers 542B connect the second through-silicon-vias 501 adjacent to each other in the vertical direction or the horizontal direction as shown in FIG. 61, thereby electrically connecting all the eight second through-silicon-vias 501 arranged in the rectangular shape. Moreover, as shown in the cross-sectional view in FIG. 60, the wiring layers 542B are also electrically connected to the second wiring layers 541A via the via-holes 544A.

The second wiring layer 541A is formed in the circular shape in the periphery of each second through-silicon-via 501. Moreover, the second wiring layer 541A extends in a straight line shape toward the first through-silicon-via 500 at the center from the periphery of the center second through-silicon-via 501 among the three second through-silicon-vias 501 on each side and is formed in a circular shape in the periphery of the connection electrical conductor 554 of the first through-silicon-via 500 to be formed integrally with the second wiring layers 541A of the surrounding eight second through-silicon-vias 501. It should be noted that as described above, the connection electrical conductor 554 and the first wiring layer 542A for the first through-silicon-via 500 are not electrically connected to the connection electrical conductors 564 and the second wiring layers 541A for the surrounding second through-silicon-vias 501.

The first through-silicon-via 500 and the second through-silicon-vias 501 in FIGS. 60 to 62 can be arranged in the solid-state image pickup apparatus 1 in place of the through-silicon-via 88 in FIG. 5 or 6 described above. The silicon substrate 531 corresponds to the silicon substrate 81 in FIG. 5 and the first wiring layer 542A corresponds to the wiring layer 83c in FIG. 5.

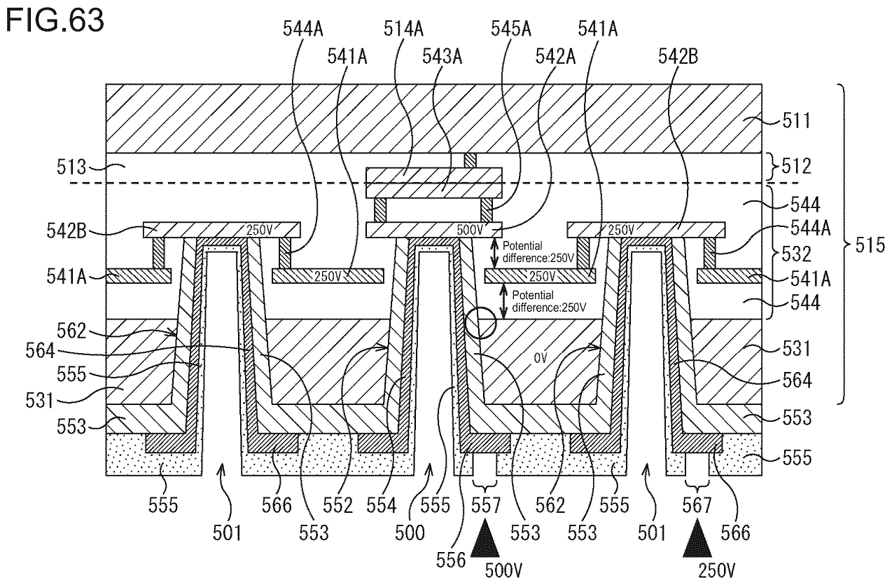

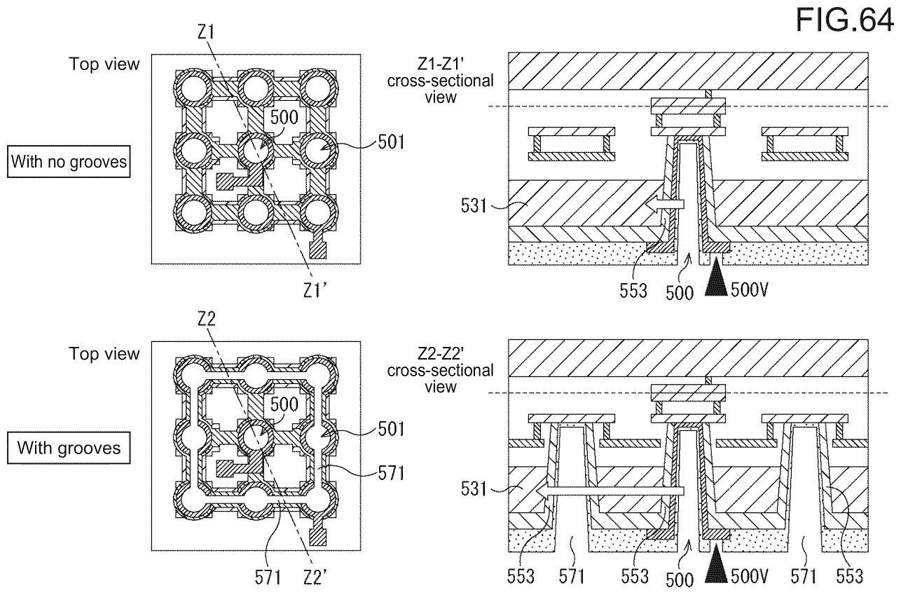

Effects of the structure of the seventh structure example of the through-silicon-via configured in the above-mentioned manner will be described with reference to FIGS. 63 and 64. In FIGS. 63 and 64, only the reference signs of main parts necessary for the description are shown.

A high voltage of 500V is applied on, for example, the first through-silicon-via 500 at the center from the electrode pad portion 557 as the first application voltage. Then, 500V is also applied on the first wiring layer 542A connected to the first through-silicon-via 500.

On the other hand, 250V lower than the first application voltage is applied on the surrounding second through-silicon-vias 501 as the second application voltage. Then, 250V is also applied on the wiring layers 542B connected to the second through-silicon-vias 501. Moreover, 250V is also applied on the second wiring layers 541A connected via the wiring layers 542B and the via-holes 544A.

It should be noted that the voltage of the silicon substrate 531 is, for example, 0V.

As described above, the first wiring layer 542A is not electrically connected to the second wiring layers 541A.

Therefore, the potential difference between the silicon substrate 531 and the second wiring layers 541A is 250V and the potential difference between the second wiring layers 541A and the first wiring layer 542A is 250V.

In a case where a high voltage of 500V is applied on the first through-silicon-via 500 at the center as the first application voltage, the potential difference between the silicon substrate 531 and the first wiring layer 542A is 500V if the plurality of second through-silicon-vias 501 arranged in the periphery is not present. In this case, the electric field concentrates at the corner portions of the silicon substrate 531 as shown in the circle in FIG. 63 and a significantly higher voltage than an actually applied voltage is applied. Therefore, the corner portions are easily broken.

In contrast, in the through-silicon-via structure according to the seventh structure example, voltage control to apply a voltage lower than the voltage applied on the first through-silicon-via 500 on the plurality of second through-silicon-vias 501 arranged in the periphery is performed as described above. Accordingly, stepwise electric field gradients are set as between the silicon substrate 531 and the second wiring layers 541A, between the second wiring layers 541A and the first wiring layer 542A. The electric field can be distributed between the silicon substrate 531 and the second wiring layers 541A, between the second wiring layers 541A and the first wiring layer 542A. Therefore, the withstand voltage between the silicon substrate 531 and the first wiring layer 542A can be improved.

Moreover, the second wiring layers 541A are arranged closer to the silicon substrate 531 than the first wiring layer 542A and are located as close to the vicinity of the first through-silicon-via 500 as possible to overlap the first wiring layer 542A in a planar view. As a result, the electric field that concentrates at the corner portions of the silicon substrate 531 can be reduced. This enables the first wiring layer 542A directly connected to the first through-silicon-via 500 to be located closer to the silicon substrate 531, and the thickness of the device (solid-state image pickup apparatus 1) can be reduced.

FIG. 64 is a view describing effects of the groove 571. In FIG. 64, the description will be given by comparing a case where the groove 571 is not formed, which is shown in the upper part, with a case where the groove 571 is formed, which is shown in the lower part.

As in the figure in the upper part, if the groove 571 is not formed, the first through-silicon-via 500 and the silicon substrate 531 are separated by an insulation film corresponding to one side wall, specifically, only by the insulation film 553 formed on a side wall of the first through-silicon-via 500.

In contrast, as in the figure in the lower part, in a case where the groove 571 is formed, the first through-silicon-via 500 and the silicon substrate 531 can be separated by an insulation film corresponding to three side walls, specifically, by the side wall of the first through-silicon-via 500, the insulation film 553 on both sides of the groove 571, and the groove 571. Accordingly, the insulation in the horizontal direction denoted as the white arrow in the cross-sectional view can be improved.

### <Manufacturing Method for Seventh Structure Example of Through-Silicon Via>

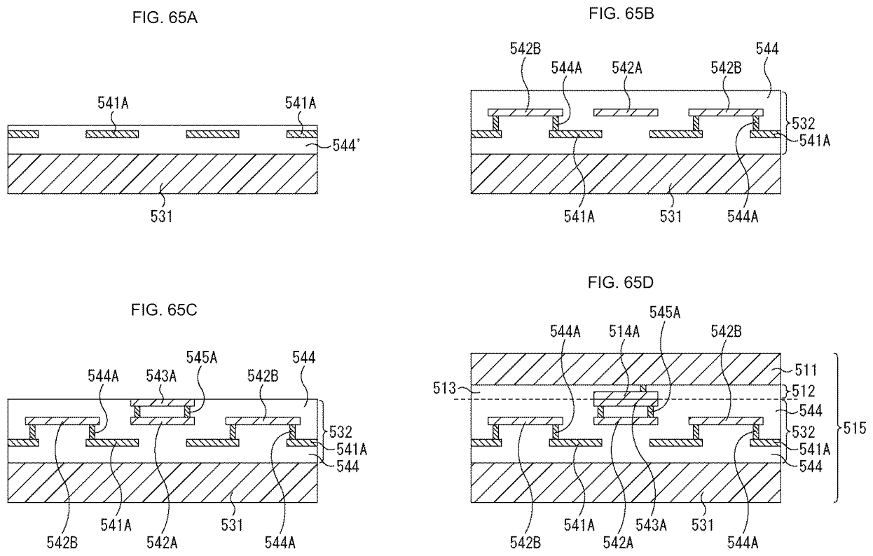

Next, a manufacturing method for the first through-silicon-via 500 and the second through-silicon-vias 501 according to the seventh structure example will be described with reference to FIGS. 65 to 67.

First of all, as shown in A of FIG. 65, an interlayer insulation film 544′ is deposited on entire one surface of the silicon substrate 531, and then the second wiring layers 541A are formed in predetermined regions. The interlayer insulation film 544′ can be formed of an SiON film, an SiO₂ film, an SiN film, an SiCN film, or the like by, for example, plasma CVD. The wiring layer 454A can be formed of copper by, for example, a damascene process.

Next, as shown in B of FIG. 65, the interlayer insulation film is further stacked on the interlayer insulation film 544′. As a result, an interlayer insulation film 544 is provided, and the via-holes 544A connected to the second wiring layers 541A, the wiring layers 542B connected to the via-holes 544A, and the first wiring layer 542A are formed.

Next, as shown in C of FIG. 65, the via-holes 545A connected to the first wiring layer 542A and the wiring layer 543A connected to the via-holes 545A are formed. In the above-mentioned manner, the multi-layer wiring layer 532 on the side of the silicon substrate 531 is completed.

Next, as shown in D of FIG. 65, the multi-layer wiring layer 512 on the silicon substrate 511 additionally produced and the multi-layer wiring layer 532 on the silicon substrate 531 are joined with each other by, for example, plasma junction. The wiring layer 514A of the multi-layer wiring layer 512 and the wiring layer 543A of the multi-layer wiring layer 532 are electrically connected to each other by metal junction (Cu—Cu junction).

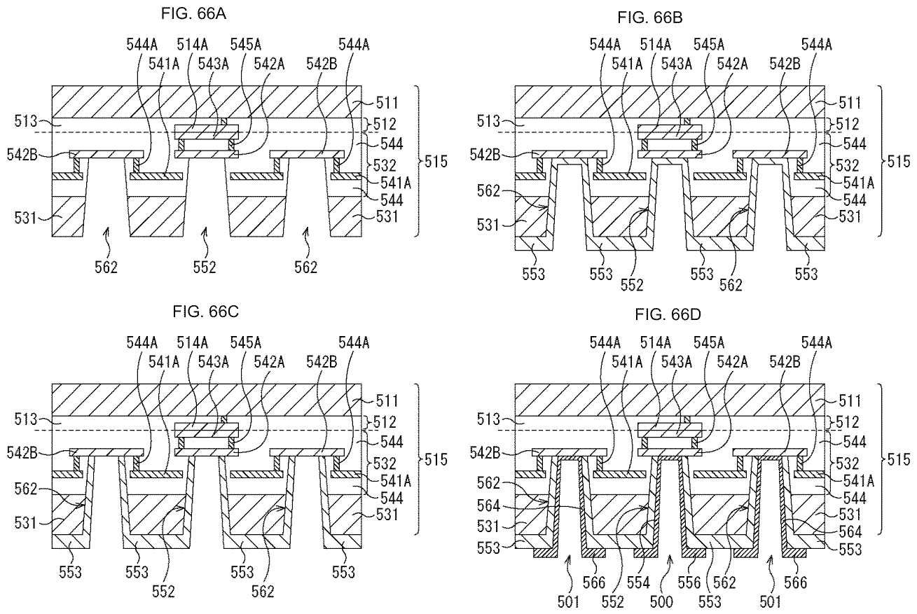

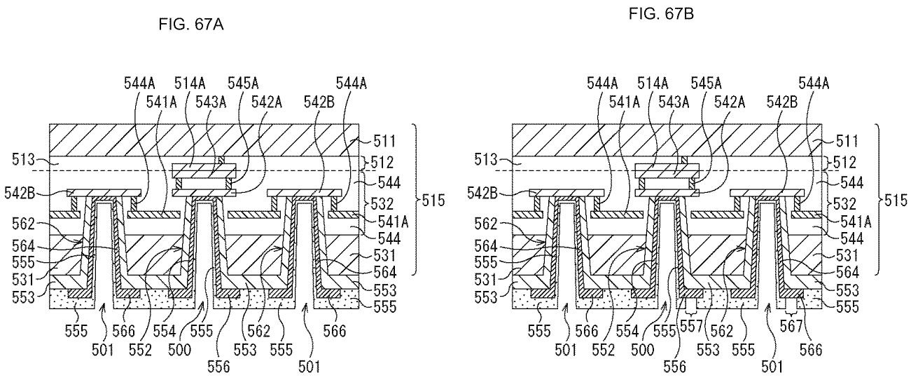

In the respective next steps in FIGS. 66 and 67, the junction substrate is inverted up and down and working is performed with the back surface of the silicon substrate 531 oriented upwards. However, as in FIG. 65, the description will be given with the back surface of the silicon substrate 531 oriented downwards in FIGS. 66 and 67 without changing the orientation.

Next, as shown in A of FIG. 66, silicon through-holes 552 and 562 are formed from the side of the back surface (in FIG. 66, the lower surface) of the silicon substrate 531. Moreover, although it is a region not shown in the figure, the groove 571 that connects the second through-silicon-via 501 to each other is also formed at the same time as the silicon through-holes 552 and 562. As in the steps described above with reference to A to C of FIG. 9, a photoresist is patterned and dry etching is performed, such that the silicon through-holes 552 and 562 can be formed.

Next, as shown in B of FIG. 66, the insulation film 553 is deposited on an entire upper surface of the silicon substrate 531 by, for example, plasma CVD. The insulation film 553 formed of, for example, an SiON film, an SiO₂ film, an SiN film, an SiCN film, or the like. Although the insulation film 553 is also deposited on the bottom surfaces and the side walls of the silicon through-holes 552 and 562, the film thickness of the insulation film 553 on the bottom surface of the silicon through-hole is formed to be thinner than the film thickness of the upper surface of the silicon substrate 531.

Next, as shown in C of FIG. 66, the insulation film 553 is removed by etching back. Although the insulation film 553 on the bottom surface of the silicon through-hole is completely removed, a part of the insulation film 553 on the upper surface of the silicon substrate 531 remains due to its film thickness difference from the bottom surface of the silicon through-hole.

Next, as shown in D of FIG. 66, a barrier metal film and a Cu seed layer (both are not shown) are formed, and then copper (Cu) is embedded by electrolytic plating using the Cu seed layer as an electrode. As a result, the connection electrical conductors 554 and 564 is formed. This step is similar to the steps described above with reference to B of FIG. 10 to C of FIG. 11 in the first structure example. For the material of the barrier metal film, tantalum (Ta), titanium (Ti), tungsten (W), zirconium (Zr), a nitride film or carbon film thereof, or the like can be used. In the seventh structure example, titanium is used as the barrier metal film. The connection electrical conductors 554 and 564 are also formed on the insulation film 553 on the upper surface of the silicon substrate 531. The connection electrical conductor 554 on the upper surface of the silicon substrate 531 formed at the same time as a side wall of the silicon through-hole 552 is configured as the rewiring 556 and the connection electrical conductor 564 on the upper surface of the silicon substrate 531 formed at the same time as a side wall of the silicon through-hole 562 is configured as the rewiring 566. Accordingly, the first through-silicon-via 500 and the second through-silicon-vias 501 are completed.

Next, as shown in A of FIG. 67, the solder mask 555 is formed to cover the connection electrical conductors 556 and 566 on the upper surface of the silicon substrate 531 and the insulation film 553. The connection electrical conductor 554 of the first through-silicon-via 500 on the side wall and the connection electrical conductors 564 on the side walls of the second through-silicon-vias 501 are also covered with the solder mask 555.

Last of all, as shown in B of FIG. 67, a partial region of the solder mask 555 formed on the rewiring 556 of the first through-silicon-via 500 is opened, such that the electrode pad portion 557 is formed. Moreover, a partial region of the solder mask 555 formed on the rewiring 566 of the second through-silicon-via 501 is opened, such that an electrode pad portion 567 is formed.

In the above-mentioned manner, the through-silicon-via structure according to the seventh structure example shown in FIG. 60 is completed.

In the through-silicon-via structure according to the seventh structure example, the first through-silicon-via 500 and the second through-silicon-vias 501 can be formed at the same time because they are at the same depth. For example, as compared to a case where the first through-silicon-via 500 and the second through-silicon-vias 501 are formed at different depths, the manufacturing process can be simplified.

### <Modified Example of Seventh Structure Example of Through-Silicon Via>

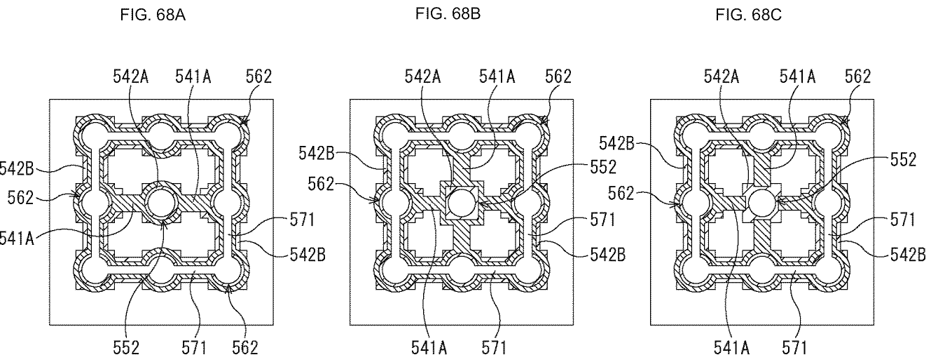

A modified example of a seventh structure example of the through-silicon-via will be described with reference to FIG. 68.

FIG. 68 is plan views showing modified examples of the plane shapes of the first wiring layer 542A, the wiring layers 542B, and the second wiring layers 541A.

In the basic structure according to the seventh structure example shown in FIG. 61, the second wiring layers 541A are formed in the circular shape in the periphery of the first through-silicon-via 500 at the center and extend in a cross shape extending in the vertical direction and the horizontal direction to be connected to the second wiring layers 541A formed in the peripheries of the surrounding second through-silicon-vias 501.

In contrast, although it is similar to the second wiring layers 541A in A of FIG. 68 in that the second wiring layers 541A are each formed in a circular shape in the periphery of the first through-silicon-via 500 at the center, the second wiring layers 541A are connected to the circular second wiring layers 541A in the peripheries of the surrounding second through-silicon-vias 501 only in the horizontal direction, not in the cross shape extending in the vertical direction and the horizontal direction.

Moreover, in the basic structure according to the seventh structure example shown in FIG. 61, the second wiring layers 541A are formed in the circular shape in the periphery of the first through-silicon-via 500 at the center. In contrast, the second wiring layers 541A in B of FIG. 68 are formed in a rectangular shape in the periphery of the first through-silicon-via 500 at the center. As a matter of course, not limited to the rectangular shape, a polygonal shape such as a hexagonal shape or an elliptical shape may be employed.

In addition, the second wiring layers 541A in C of FIG. 68 are arranged so that the second wiring layers 541A are not connected in the periphery of the first through-silicon-via 500 at the center. It should be noted that the second wiring layers 541A are similar to the basic structure shown in FIG. 62 in that the second wiring layers 541A are arranged to be located as close to the vicinity of the first through-silicon-via 500 as possible to at least partially overlap the first wiring layer 542A in a planar view.

As described above, the plane shapes of the second wiring layers 541A, in particular, the plane shapes of the second wiring layers 541A formed in the periphery of the first through-silicon-via 500 can have various shapes.

### <19. Summary of Seventh Structure Example of Through-Silicon Via>

As described above, the through-silicon-via structure according to the seventh structure example has a structure in which the first through-silicon-via 500 that applies the first application voltage as a high voltage is arranged at the center and the plurality of second through-silicon-vias 501 is arranged in the periphery thereof. The second application voltage lower than the voltage applied on the first through-silicon-via 500 is applied on the plurality of second through-silicon-vias 501.

The second wiring layers 541A electrically connected to the connection electrical conductor 564 of the plurality of second through-silicon-vias 501 are arranged between the first wiring layer 542A to which the connection electrical conductor 554 of the first through-silicon-via 500 is directly connected and the silicon substrate 531. The second wiring layers 541A are not electrically connected to the first wiring layer 542A and are arranged to be located as close to the vicinity of the first through-silicon-via 500 as possible to at least partially overlap the first wiring layer 542A in a planar view.

Accordingly, the electric field can be distributed between the silicon substrate 531 and the second wiring layers 541A, between the second wiring layers 541A and the first wiring layer 542A. Therefore, a withstand voltage between the silicon substrate 531 and the first wiring layer 542A can be improved. Therefore, the withstand voltage of the through-silicon-via can be improved.

### (Combinations of First to Seventh Structure Examples)

A structure obtained by combining the structure of the first through-silicon-via 500 and the plurality of second through-silicon-vias 501 according to the seventh structure example with at least one of the through-silicon-vias 120, 200, 240, 280, 380, and 400 that are the first to sixth structure examples as appropriate may be employed. For example, the stress suppression film 205 according to the second structure example can be added to the first through-silicon-via 500 and the plurality of second through-silicon-vias 501 according to the seventh structure example. In accordance with a combination of the first to sixth structure examples with the seventh structure example, the effect of the seventh structure example of improving the withstand voltage of the through-silicon-via can also be provided in addition to the effects of the first to sixth structure examples.

### <20. Application Example to Electronic Apparatus>

The technology of the present disclosure is not limited to the application to the solid-state image pickup apparatus. That is, the technology of the present disclosure can be applied to general electronic apparatuses using the solid-state image pickup apparatus as an image capture unit (photoelectric conversion unit) including an image pickup apparatus such as a digital still camera or a video camera, a portable terminal apparatus (smartphone) with an image-pick up function, a copying machine using the solid-state image pickup apparatus as an image scanner, and the like. The solid-state image pickup apparatus may be in the form of one chip or may be in the form of a module with an image-pick up function in which an image pickup unit and a signal processing unit or an optical system are packed together.

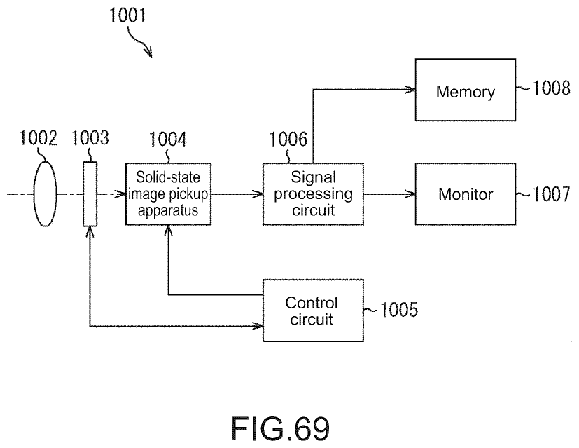

FIG. 69 is a block diagram showing a configuration example of an image pickup apparatus serving as an electronic apparatus to which the present disclosure is applied.

An image pickup apparatus 1001 shown in FIG. 69 includes an optical system 1002, a shutter apparatus 1003, a solid-state image pickup apparatus 1004, a control circuit 1005, a signal processing circuit 1006, a monitor 1007, and a memory 1008 and is capable of capturing still images and moving images.

The optical system 1002 includes one or more lenses. The optical system 1002 guides light (incident light) from an object to be imaged to the solid-state image pickup apparatus 1004 for forming an image on a light-receiving surface of the solid-state image pickup apparatus 1004.

The shutter apparatus 1003 is arranged between the optical system 1002 and the solid-state image pickup apparatus 1004 and controls a light-emitting period and a light-shielding period to the solid-state image pickup apparatus 1004 in accordance with the control of the control circuit 1005.

The solid-state image pickup apparatus 1004 is constituted by the solid-state image pickup apparatus 1 in FIG. 1. The solid-state image pickup apparatus 1004 accumulates signal electric charges for a constant period in accordance with light formed as an image on the light-receiving surface via the optical system 1002 and the shutter apparatus 1003. The signal electric charges accumulated in the solid-state image pickup apparatus 1004 are transferred in accordance with a driving signal (timing signal) supplied from the control circuit 1005.

The control circuit 1005 outputs driving signals to control a transfer operation of the solid-state image pickup apparatus 1004 and a shutter operation of the shutter apparatus 1003 for driving the solid-state image pickup apparatus 1004 and the shutter apparatus 1003.

The signal processing circuit 1006 performs various types of signal processing on signal electric charges output from the solid-state image pickup apparatus 1004. The image (image data) obtained by the signal processing circuit 1006 performing signal processing is supplied and displayed on the monitor 1007 or supplied and stored (recorded) in the memory 1008.

Also in the image pickup apparatus 1001 configured in the above-mentioned manner, by applying the solid-state image pickup apparatus 1 in FIG. 1 as the solid-state image pickup apparatus 1004, the film stress generated due to heat treatment can be reduced and the withstand voltage can be improved. Accordingly, a high-quality captured image can be obtained.

<Usage example of Image Sensor>

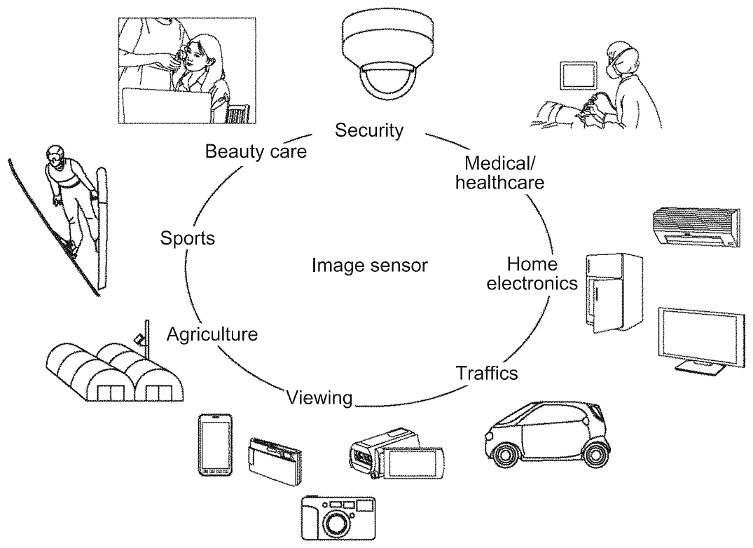

FIG. 70 is a diagram showing a usage example that uses an image sensor using the above-mentioned solid-state image pickup apparatus 1.

The image sensor using the above-mentioned solid-state image pickup apparatus 1 can be used in various cases of sensing light such as visible light, infrared light, ultraviolet light, and X-rays as follows.
An apparatus for photographing images to be viewed, such as a digital camera and a camera-equipped mobile apparatus
An apparatus used for traffic purposes, such as a car-mounted camera that photographs front/rear/periphery/inside of an automobile, a surveillance camera that monitors running vehicles and roads, and a distance measurement sensor that measures distances among vehicles, for safe driving including automatic stop, recognition of a driver's state, and the like
An apparatus used in home electronics such as a TV, a refrigerator, and an air conditioner, for photographing gestures of users and executing apparatus operations according to the gestures
An apparatus used for medical and healthcare purposes, such as an endoscope and an apparatus that performs blood vessel photographing by receiving infrared light
An apparatus used for security purposes, such as a surveillance camera for crime-prevention purposes and a camera for person authentication purposes
An apparatus used for beauty care purposes, such as a skin measurement apparatus that photographs skins and a microscope that photographs scalps
An apparatus used for sports purposes, such as an action camera and a wearable camera for sports purposes
An apparatus for agriculture purposes, such as a camera for monitoring a state of fields and crops

Moreover, the technology of the present disclosure is not limited to the solid-state image pickup apparatus and the technology of the present disclosure can be applied to other general semiconductor devices with a semiconductor integrated circuit.

Embodiments of the present disclosure are not limited to the above-mentioned embodiments and various changes can be made without departing from the gist of the technology according to the present disclosure.

For example, a mode on which some of the above-mentioned first to seventh structure examples of the through-silicon-via are selected and combined as appropriate can be employed.

It should be noted that the effects described in this specification are merely exemplary and not limitative and other effects than the effects described in this specification may be provided.

It should be noted that the technology of the present disclosure can take the following configurations.

(1) A semiconductor device, including
a through-via on which a connection electrical conductor is formed via an insulation film, the through-via being provided on a side wall of a through-hole formed in a semiconductor substrate, in which
the connection electrical conductor includes a thin film portion with a smaller film thickness and a thick film portion with a larger film thickness.

(2) The semiconductor device according to (1), in which
a plane shape of the connection electrical conductor is a shape in which projection portions or depression portions are provided at one or more positions in a part of a predetermined plane shape.

(3) The semiconductor device according to (2), in which
the predetermined plane shape is any one of a circular shape, an elliptical shape, or a polygonal shape.

(4) The semiconductor device according to (3), in which
the predetermined plane shape is the polygonal shape whose corner portions are rounded.

(5) The semiconductor device according to any one of (2) to (4), in which
the plane shape of the connection electrical conductor is a shape in which the projection portions are provided at one or more positions outside the predetermined plane shape.

(6) The semiconductor device according to any one of (2) to (4), in which
the plane shape of the connection electrical conductor is a shape in which the projection portions are provided at one or more positions inside the predetermined plane shape.

(7) The semiconductor device according to (5) or (6), in which
the plane shape of the projection portion is any one of a rectangular shape, a semi-circular shape, a semi-elliptical shape, or a triangular shape.

(8) The semiconductor device according to (7), in which
the plane shape of the projection portion is the rectangular shape whose corner portions are rounded.

(9) The semiconductor device according to (1), in which
the connection electrical conductor has a plane shape whose film thickness continuously changes in a circumferential direction.

(10) The semiconductor device according to (2) or (3), in which
the plane shape of the connection electrical conductor is a shape in which the depression portions are provided at one or more positions inside the predetermined plane shape.

(11) The semiconductor device according to (2) or (3), in which
the plane shape of the connection electrical conductor is a shape in which the projection portions are provided at one or more positions both outside and inside the predetermined plane shape.

(12) The semiconductor device according to (11), in which
the plane shape of the projection portion is any one of a rectangular shape, a semi-circular shape, a semi-elliptical shape, or a triangular shape.

(13) The semiconductor device according to any one of (1) to (12), in which
the through-via further includes, on an upper surface of the connection electrical conductor formed on the side wall, a stress suppression film that suppresses stress of the connection electrical conductor.

(14) The semiconductor device according to any one of (1) to (13), in which
the through-via further includes at least one buffer layer between the connection electrical conductor formed on the side wall and the semiconductor substrate, the at least one buffer layer having a Young's modulus lower than a Young's modulus of the insulation film.
   (15) The semiconductor device according to any one of (1) to (14), in which
the through-via further includes, on a bottom portion of the through-hole, an electrical conductor formed to be thicker than another film formed on the side wall of the through-hole.
   (16) The semiconductor device according to any one of (1) to (15), in which
the connection electrical conductor is connected to a wiring layer closest to the semiconductor substrate inside a multi-layer wiring layer, and
an air gap is formed in side surfaces of end portions of the wiring layer in a plane direction and in an upper surface of the wiring layer, the upper surface being located on a side of the semiconductor substrate.
   (17) The semiconductor device according to any one of (1) to (16), in which
the connection electrical conductor is formed, embedded also in a multi-layer wiring layer, and
the through-via includes a stack via-hole inside the connection electrical conductor inside the multi-layer wiring layer.

(18) The semiconductor device according to any one of (1) to (17), in which
the through-via formed on the semiconductor substrate is set as a first through-via,
further including a plurality of second through-vias formed on the semiconductor substrate and arranged in a periphery of the first through-via, in which
a second application voltage lower than a first application voltage applied on the first through-via is applied on the second through-via,
a second wiring layer electrically connected to a connection electrical conductor of the second through-via is arranged between a first wiring layer to which a connection electrical conductor of the first through-via is directly connected and the semiconductor substrate, and
the second wiring layer is configured to not be electrically connected to the first wiring layer.

(19) A manufacturing method for a semiconductor device, including
forming a connection electrical conductor via an insulation film on a side wall of a through-hole formed in a semiconductor substrate to form a through-via, in which
the connection electrical conductor is formed including a thin film portion with a smaller film thickness and a thick film portion with a larger film thickness.

(20) An electronic apparatus, including
a semiconductor device including
   a through-via on which a connection electrical conductor is formed via an insulation film on a side wall of a through-hole formed in a semiconductor substrate, in which
the connection electrical conductor includes a thin film portion with a smaller film thickness and a thick film portion with a larger film thickness.

(B2) A semiconductor device, including
a through-via on which a connection electrical conductor is formed via an insulation film on a side wall of a through-hole formed in a semiconductor substrate, in which
the through-via includes, on an upper surface of the connection electrical conductor formed on the side wall, a stress suppression film that suppresses stress of the connection electrical conductor.

(B3) A semiconductor device, including
a through-via on which a connection electrical conductor is formed via an insulation film on a side wall of a through-hole formed in a semiconductor substrate, in which
the through-via includes at least one buffer layer between the connection electrical conductor formed on the side wall and the semiconductor substrate, the at least one buffer layer having a Young's modulus lower than a Young's modulus of the insulation film.

(B4) A semiconductor device, including
a through-via on which a connection electrical conductor is formed via an insulation film on a side wall of a through-hole formed in a semiconductor substrate, in which
the through-via includes, on the side wall of the through-hole, two sets of three layers including the insulation film, a barrier metal film, and a seed layer of the connection electrical conductor and includes, on a bottom portion of the through-hole, an electrical conductor formed to be thicker than these films.

(B5) A semiconductor device, including
a through-via on which a connection electrical conductor is formed via an insulation film on a side wall of a through-hole formed in a semiconductor substrate, in which
the connection electrical conductor is connected to a wiring layer closest to the semiconductor substrate inside a multi-layer wiring layer, and
an air gap is formed in side surfaces of end portions of the wiring layer in a plane direction and in an upper surface of the wiring layer, the upper surface being located on a side of the semiconductor substrate.

(B6) A semiconductor device, including
a through-via on which a connection electrical conductor is formed via an insulation film on a side wall of a through-hole formed in a semiconductor substrate, in which
the connection electrical conductor is formed, embedded also in a multi-layer wiring layer, and
the through-via includes a stack via-hole inside the connection electrical conductor inside the multi-layer wiring layer.

(B7) A semiconductor device, including:
a first through-via formed on the semiconductor substrate; and
a plurality of second through-vias formed on the semiconductor substrate and arranged in a periphery of the first through-via, in which
a second application voltage lower than a first application voltage applied on the first through-via is applied on the second through-via,
a second wiring layer electrically connected to a connection electrical conductor of the second through-via is arranged between a first wiring layer to which a connection electrical conductor of the first through-via is directly connected and the semiconductor substrate, and
the second wiring layer is configured to not be electrically connected to the first wiring layer.

### REFERENCE SIGNS LIST

1 solid-state image pickup apparatus
11 logic substrate (lower substrate)
12 pixel sensor substrate (upper substrate)
13 stack substrate
14 solder ball
15 color filter
16 ON chip lens
120 through-silicon-via
121 silicon substrate
122 silicon through-hole
131A thin film portion
131B thick film portion
200 through-silicon-via
201 silicon substrate
202 silicon through-hole
203 insulation film
204 connection electrical conductor
205 stress suppression film
205′ organic film
240 through-silicon-via
241 silicon substrate
242 silicon through-hole
243 insulation film
244 (244A, 244B) buffer layer
245 connection electrical conductor
246 interlayer insulation film
247 wiring layer
280 through-silicon-via
281 silicon substrate
282 silicon through-hole
283 (283A, 283B) insulation film
284 (284A, 284B) barrier metal film
285 (285A, 285B) Cu seed layer
286 electrical conductor
287 connection electrical conductor
288 solder mask
289 interlayer insulation film
290 wiring layer
380 through-silicon-via
381 silicon substrate
382 silicon through-hole
383 insulation film
384 connection electrical conductor
384A Cu seed layer
385 multi-layer wiring layer
386 interlayer insulation film
387 wiring layer
388 air gap
389 insulation film
400 through-silicon-via
411 semiconductor substrate (silicon substrate)
412 multi-layer wiring layer
413 wiring layer
414 interlayer insulation film
431 semiconductor substrate (silicon substrate)
452 silicon through-hole
453 insulation film
454 connection electrical conductor
457 stack via-hole
500 through-silicon-via (first through-silicon-via)
501 through-silicon-via (second through-silicon-via)
511 semiconductor substrate (silicon substrate)
571 groove
1001 image pickup apparatus
1004 solid-state image pickup apparatus

1. A semiconductor device, comprising
a through-via on which a connection electrical conductor is formed via an insulation film, the through-via being provided on a side wall of a through-hole formed in a semiconductor substrate, wherein
the connection electrical conductor includes a thin film portion with a smaller film thickness and a thick film portion with a larger film thickness.

2. The semiconductor device according to claim 1, wherein
a plane shape of the connection electrical conductor is a shape in which projection portions or depression portions are provided at one or more positions in a part of a predetermined plane shape.

3. The semiconductor device according to claim 2, wherein
the predetermined plane shape is any one of a circular shape, an elliptical shape, or a polygonal shape.

4. The semiconductor device according to claim 3, wherein
the predetermined plane shape is the polygonal shape whose corner portions are rounded.

5. The semiconductor device according to claim 2, wherein
the plane shape of the connection electrical conductor is a shape in which the projection portions are provided at one or more positions outside the predetermined plane shape.

6. The semiconductor device according to claim 2, wherein
the plane shape of the connection electrical conductor is a shape in which the projection portions are provided at one or more positions inside the predetermined plane shape.

7. The semiconductor device according to claim 5, wherein
the plane shape of the projection portion is any one of a rectangular shape, a semi-circular shape, a semi-elliptical shape, or a triangular shape.

8. The semiconductor device according to claim 7, wherein
the plane shape of the projection portion is the rectangular shape whose corner portions are rounded.

9. The semiconductor device according to claim 1, wherein
the connection electrical conductor has a plane shape whose film thickness continuously changes in a circumferential direction.

10. The semiconductor device according to claim 2, wherein
the plane shape of the connection electrical conductor is a shape in which the depression portions are provided at one or more positions inside the predetermined plane shape.

11. The semiconductor device according to claim 2, wherein
the plane shape of the connection electrical conductor is a shape in which the projection portions are provided at one or more positions both outside and inside the predetermined plane shape.

12. The semiconductor device according to claim 11, wherein
the plane shape of the projection portion is any one of a rectangular shape, a semi-circular shape, a semi-elliptical shape, or a triangular shape.

13. The semiconductor device according to claim 1, wherein
the through-via further includes, on an upper surface of the connection electrical conductor formed on the side wall, a stress suppression film that suppresses stress of the connection electrical conductor.

14. The semiconductor device according to claim 1, wherein
the through-via further includes at least one buffer layer between the connection electrical conductor formed on the side wall and the semiconductor substrate, the at least one buffer layer having a Young's modulus lower than a Young's modulus of the insulation film.

15. The semiconductor device according to claim 1, wherein
the through-via further includes, on a bottom portion of the through-hole, an electrical conductor formed to be thicker than another film formed on the side wall of the through-hole.

16. The semiconductor device according to claim 1, wherein
the connection electrical conductor is connected to a wiring layer closest to the semiconductor substrate inside a multi-layer wiring layer, and
an air gap is formed in side surfaces of end portions of the wiring layer in a plane direction and in an upper surface of the wiring layer, the upper surface being located on a side of the semiconductor substrate.

17. The semiconductor device according to claim 1, wherein
the connection electrical conductor is formed, embedded also in a multi-layer wiring layer, and
the through-via includes a stack via-hole inside the connection electrical conductor inside the multi-layer wiring layer.

18. The semiconductor device according to claim 1, wherein
the through-via formed on the semiconductor substrate is set as a first through-via,
further comprising a plurality of second through-vias formed on the semiconductor substrate and arranged in a periphery of the first through-via, wherein
a second application voltage lower than a first application voltage applied on the first through-via is applied on the second through-via,
a second wiring layer electrically connected to a connection electrical conductor of the second through-via is arranged between a first wiring layer to which a connection electrical conductor of the first through-via is directly connected and the semiconductor substrate, and
the second wiring layer is configured to not be electrically connected to the first wiring layer.

19. A manufacturing method for a semiconductor device, comprising
forming a connection electrical conductor via an insulation film on a side wall of a through-hole formed in a semiconductor substrate to form a through-via, wherein
the connection electrical conductor is formed including a thin film portion with a smaller film thickness and a thick film portion with a larger film thickness.

20. An electronic apparatus, comprising
a semiconductor device including
a through-via on which a connection electrical conductor is formed via an insulation film on a side wall of a through-hole formed in a semiconductor substrate, wherein
the connection electrical conductor includes a thin film portion with a smaller film thickness and a thick film portion with a larger film thickness.
